(19) United States
(12) Patent Application Publication
(10) Pub. No.: US 2012/0003590 A1
(43) Pub. Date: Jan. 5, 2012

(54) ACTINIC RAY-SENSITIVE OR RADIATION-SENSITIVE RESIN COMPOSITION, AND RESIST FILM AND PATTERN FORMING METHOD USING THE SAME

(75) Inventors: Shuji HIRANO, Shizuoka (JP); Hidenori TAKAHASHI, Shizuoka (JP); Tomotaka TSUCHIMURA, Shizuoka (JP); Takeshi KAWABATA, Shizuoka (JP); Hideaki TSUBAKI, Shizuoka (JP)

(73) Assignee: FUJIFILM CORPORATION, Tokyo (JP)

(21) Appl. No.: 13/033,079

(22) Filed: Feb. 23, 2011

(30) Foreign Application Priority Data
Jul. 1, 2010 (JP) 2010-151500
Feb. 8, 2011 (JP) 2011-025505

(51) Int. Cl. G03F 7/20; C08F 214/18

(52) U.S. Cl. 430/325; 526/243

(57) ABSTRACT

An actinic ray-sensitive or radiation-sensitive resin composition containing a resin having (A) a repeating unit represented by a specific formula (I) and (B) a repeating unit capable of generating an acid upon irradiation with an actinic ray or radiation.

### BACKGROUND OF THE INVENTION

1. Field of the Invention

The present invention relates to an actinic ray-sensitive or radiation-sensitive resin composition, and a resist film and a pattern forming method each using the same. More specifically, the present invention relates to a composition suitably used for the ultramicrolithography process applicable to the production process of VLSI and a high-capacity microchip, the preparation process of a nanoimprint mold, the production process of a high-density information recording medium, and the like, and for other photofabrication processes, and a pattern forming method using the same.

2. Description of the Related Art

In the production process of a semiconductor device such as IC and LSI, microfabrication by lithography using a photoresist composition is performed. The recent increase in the integration degree of an integrated circuit requires formation of an ultrafine pattern in the sub-micron or quarter-micron region and in turn, the exposure wavelength also tends to become shorter, for example, from g-line to i-line or further to KrF excimer laser light. At present, other than the excimer laser light, development of lithography using electron beam, X-ray, EUV light or the like is proceeding.

Due to requirement for formation of an ultrafine pattern in the sub-micron or quarter-micron region caused by the recent increase in the integration degree of an integrated circuit, the film thickness must be reduced. However, reduction in the film thickness involves a problem of deterioration in the dry etching resistance, and the things are not satisfied enough.

The formation of an ultrafine pattern is also associated with a decrease in the adherence to a substrate and gives rise to a problem of reduction in the resolution of an isolated pattern, and it is required to enhance the resolution of an isolated pattern, but the efforts are not sufficiently rewarded.

Above all, the electron beam lithography is positioned as a next-generation or next-next-generation pattern formation technique, and a high-sensitivity and high-resolution positive resist is being demanded. In particular, the elevation of sensitivity is a very important task for shortening the wafer processing time but in the positive resist for electron beam, when elevation of sensitivity is sought for, not only reduction of the resolution but also worsening of the line edge roughness are brought about, and development of a resist satisfying these properties at the same time is strongly demanded. The line edge roughness as used herein means that the edge at the interface between the resist pattern and the substrate irregularly fluctuates in the direction perpendicular to the line direction due to the resist property and when the pattern is viewed from right above, the edge gives an uneven appearance. This unevenness is transferred by the etching step using the resist as a mask and causes deterioration of electric characteristics, leading to a decrease in the yield. Particularly, in an ultrafine region of 0.25 μm or less, the improvement of line edge roughness is a very important task. The high sensitivity is in a trade-off relationship with high resolution, good pattern profile and improved line edge roughness, and it is very important how satisfy all of these properties at the same time.

Also in the lithography using X-ray, EUV light or the like, it is similarly an important task to satisfy all of high sensitivity, good pattern profile, improved line edge roughness, resolution of an isolated pattern, and dry etching resistance at the same time, and this task needs to be solved.

Use of a resin having, in the main or side chain, a moiety capable of generating an acid upon irradiation with light (sometimes referred to as a photo-acid generating group) is being studied (see, for example, JP-A-9-325497 (the term “JP-A” as used herein means an “unexamined published Japanese patent application”), JP-A-10-221852, JP-A-2006-178317, JP-A-2007-197718, International Publication No. 06/121096 and U.S. Patent Application Publication No. 2006/121390), but success in adequately satisfying all of high sensitivity, good pattern profile, improved line edge roughness and dry etching resistance at the same time is not achieved at present.

In particular, a resin containing, in the same molecule, a photo-acid generating group and a group capable of increasing the solubility in an alkali developer by acid decomposition is disclosed in JP-A-10-221852, JP-A-2006-178317, JP-A-2007-197718, International Publication No. 06/121096 and U.S. Patent Application Publication No. 2006/121390, but this resin cannot be said to have sufficient sensitivity for electron beam, X-ray or EUV light.

By any combination of related arts known so far, it is impossible at present to satisfy all of high sensitivity, high resolution, good pattern profile, improved line edge roughness and the like at the same time in the lithography using electron beam, X-ray or EUV light.

### SUMMARY OF THE INVENTION

An object of the present invention is to provide an actinic ray-sensitive or radiation-sensitive resin composition enabling excellent performance in terms of sensitivity, roughness characteristics, resolution of an isolated pattern and dry etching resistance and enabling formation of a pattern having a good profile, and a resist film and a pattern forming method each using the composition.

[1] An actinic ray-sensitive or radiation-sensitive resin composition contains a resin having (A) a repeating unit represented by the following formula (I) and (B) a repeating unit capable of generating an acid upon irradiation with an actinic ray or radiation:

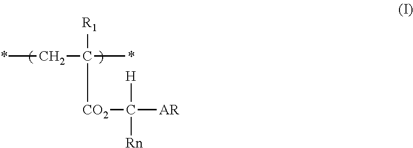

wherein AR represents an aryl group, Rn represents an alkyl group, a cycloalkyl group or an aryl group, Rn and AR may combine with each other to form a non-aromatic ring, and

R₁ represents a hydrogen atom, an alkyl group, a cycloalkyl group, a halogen atom, a cyano group or an alkyloxycarbonyl group.

[2] In the actinic ray-sensitive or radiation-sensitive resin composition as described in [1] above, in formula (I), Rn and AR are combined with each other to form a non-aromatic ring.
[3] In the actinic ray-sensitive or radiation-sensitive resin composition as described in [1] or [2] above, the repeating unit (A) represented by formula (I) contains two or more aromatic rings.
[4] In the actinic ray-sensitive or radiation-sensitive resin composition as described in any one of [1] to [3] above, AR in formula (I) contains two or more aromatic rings.
[5] In the actinic ray-sensitive or radiation-sensitive resin composition as described in any of [1] to [4] above, the repeating unit (B) is at least one selected from the group consisting of repeating units represented by the following formulae (B1), (B2) and (B3):

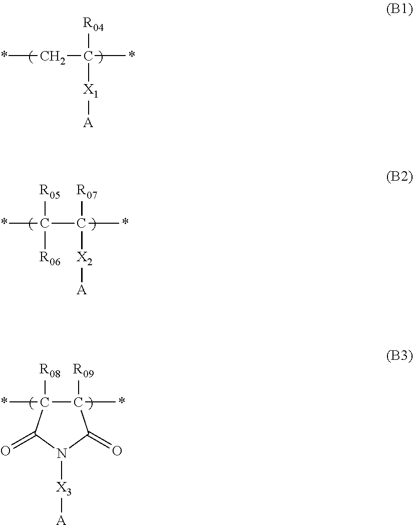

wherein A represents a structural moiety capable of decomposing upon irradiation with an actinic ray or radiation to generate an acid anion,

each of R₀₄, R₀₅ and R₀₇ to R₀₉ independently represents a hydrogen atom, an alkyl group, a cycloalkyl group, a cyano group or an alkoxycarbonyl group,

R₀₆ represents a cyano group, a carboxy group, —CO—OR₂₅ or —CO—N(R₂₆)(R₂₇), R₂₅ represents an alkyl group, a cycloalkyl group, an alkenyl group, a cycloalkenyl group, an aryl group or an aralkyl group, R₂₆ and R₂₇ may combine with each other to form a ring together with the nitrogen atom, each of R₂₆ and R₂₇ independently represents a hydrogen atom, an alkyl group, a cycloalkyl group, an alkenyl group, a cycloalkenyl group, an aryl group or an aralkyl group,

each of X₁ to X₃ independently represents a single bond, an arylene group, an alkylene group, a cycloalkylene group, —O—, —SO₂—, —CO—, —N(R₃₃)— or a divalent linking group formed by combining a plurality of these members, and R₃₃ represents a hydrogen atom, an alkyl group, a cycloalkyl group, an alkenyl group, a cycloakenyl group, an aryl group or an aralkyl group.

[6] In the actinic ray-sensitive or radiation-sensitive resin composition as described in
[5] above, the A is an ionic structural moiety having a sulfonium salt structure or an iodonium salt structure.
[7] In the actinic ray-sensitive or radiation-sensitive resin composition as described in any of [1] to [6], the resin further contains at least either one of a repeating unit represented by the following formula (A1) and a repeating unit represented by formula (A2):

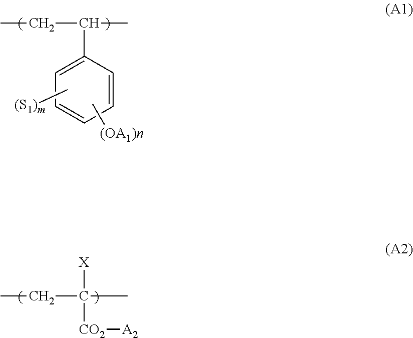

wherein in formula (A 1),

m represents an integer of 0 to 4,

n represents an integer of 1 to 5 satisfying the relationship of m+m≦15,

S₁ represents a substituent (excluding hydrogen atom) and when m≧2, each S₁ may be the same as or different from every other S₁, and

A₁ represents a hydrogen atom or a group capable of leaving by the action of an acid and when n≧2, each A₁ may be the same as or different from every other A₁; and

in formula (A2),

X represents a hydrogen atom, an alkyl group, a hydroxyl group, an alkoxy group, a halogen atom, a cyano group, a nitro group, an acyl group, an acyloxy group, a cycloalkyl group, a cycloalkyloxy group, an aryl group, a carboxy group, an alkyloxycarbonyl group, an alkylcarbonyloxy group or an aralkyl group, and

A₂ represents a group capable of leaving by the action of an acid.

[8] In the actinic ray-sensitive or radiation-sensitive resin composition as described in any one of [1] to [7] above, the actinic ray-sensitive or radiation-sensitive resin composition is for a KrF excimer laser, an electron beam, an X-ray or EUV light.
[9] A resist film is formed using the actinic ray-sensitive or radiation-sensitive resin composition described in any of [1] to [8] above.
[10] A pattern forming method comprises exposing and developing the resist film described in [9] above.

The present invention preferably further includes the following configurations.

[11] In the actinic ray-sensitive or radiation-sensitive resin composition as described in any one of [1] to [8] above, the weight average molecular weight of the resin is from 1,000 to 200,000.
[12] In the actinic ray-sensitive or radiation-sensitive resin composition as described in any one of [1] to [8] and [11] above, the weight average molecular weight of the resin is from 1,000 to 100,000.
[13] In the actinic ray-sensitive or radiation-sensitive resin composition as described in any one of [1] to [8], [11] and [12] above, the weight average molecular weight of the resin is from 1,000 to 50,000.
[14] In the actinic ray-sensitive or radiation-sensitive resin composition as described in any one of [1] to [8] and [11] to [13] above, the weight average molecular weight of the resin is from 1,000 to 25,000.
[15] In the actinic ray-sensitive or radiation-sensitive resin composition as described in any one of [1] to [8] and [11] to [14] above, the actinic ray-sensitive or radiation-sensitive resin composition further contains a basic compound.
[16] In the actinic ray-sensitive or radiation-sensitive resin composition as described in [15] above, wherein the basic compound is a compound having a proton acceptor functional group and undergoing decomposition upon irradiation with an actinic ray or radiation to generate a compound reduced in or deprived of the proton acceptor property or changed to be acidic from being proton acceptor-functioning.
[17] In the actinic ray-sensitive or radiation-sensitive resin composition as described in any one of [1] to [8] and [11] to [16] above, the basic compound is a compound represented by the following formula (BS-1):

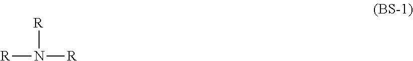

wherein each R independently represents a hydrogen atom or an organic group, provided that at least one of three R's is an organic group.

[18] In the actinic ray-sensitive or radiation-sensitive resin composition as described in [17] above, at least one of three R's is an alkyl group having a hydrophilic group.
[19] In the actinic ray-sensitive or radiation-sensitive resin composition as described in [1] to [8] and [11] to [18] above, wherein the basic compound is a guanidine compound.
[20] In the actinic ray-sensitive or radiation-sensitive resin composition as described in [1] to [8] and [11] to [19] above, the actinic ray-sensitive or radiation-sensitive resin composition further contains a surfactant.
[21] In the actinic ray-sensitive or radiation-sensitive resin composition as described in [1] to [8] and [11] to [20] above, the actinic ray-sensitive or radiation-sensitive resin composition further contains a solvent.
[22] In the actinic ray-sensitive or radiation-sensitive resin composition as described in [21] above, the solvent contains propylene glycol monomethyl ether acetate.
[23] In the actinic ray-sensitive or radiation-sensitive resin composition as described in [22] above, the solvent further contains propylene glycol monomethyl ether.
[24] A resin has (A) a repeating unit represented by the following formula (I) and (B) a repeating unit capable of generating an acid upon irradiation with an actinic ray or radiation:

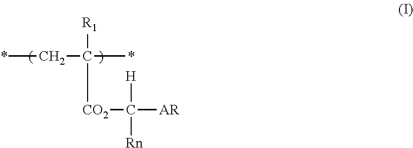

wherein AR represents an aryl group, Rn represents an alkyl group, a cycloalkyl group or an aryl group, Rn and AR may combine with each other to form a non-aromatic ring, and

R₁ represents a hydrogen atom, an alkyl group, a cycloalkyl group, a halogen atom, a cyano group or an alkyloxycarbonyl group.

According to the present invention, an actinic ray-sensitive or radiation-sensitive resin composition enabling excellent performance in terms of sensitivity, roughness characteristics, resolution of an isolated pattern and dry etching resistance and enabling formation of a pattern having a good profile, and a resist film and a pattern forming method each using the composition, can be provided.

### DETAILED DESCRIPTION OF THE INVENTION

The mode for carrying out the present invention is described below.

Incidentally, in the description of the present invention, when a group (atomic group) is denoted without specifying whether substituted or unsubstituted, the group includes both a group having no substituent and a group having a substituent. For example, “an alkyl group” without the expression “substituted or unsubstituted” includes not only an alkyl group having no substituent (unsubstituted alkyl group) but also an alkyl group having a substituent (substituted alkyl group).

In the description of the present invention, the term “actinic ray” or “radiation” indicates, for example, a bright line spectrum of mercury lamp, a far ultraviolet ray typified by excimer laser, an extreme-ultraviolet (EUV) ray, an X-ray or an electron beam (EB). Also, in the present invention, the “light” means an actinic ray or radiation.

In the present invention, unless otherwise indicated, the “exposure” includes not only exposure to a mercury lamp, a far ultraviolet ray typified by excimer laser, an X-ray, EUV light or the like but also lithography with a particle beam such as electron beam and ion beam.

The actinic ray-sensitive or radiation-sensitive resin composition of the present invention contains the resin described below.

Thanks to this resin, sensitivity, roughness characteristics, resolution of an isolated pattern and dry etching resistance are excellent, and a pattern having a good profile can be formed.

It is considered that the repeating unit (B) capable of generating an acid upon irradiation with an actinic ray or radiation contributes to improving the sensitivity and roughness characteristics and the specific repeating unit (A) having an aromatic group, represented by the following formula (I), contributes to enhancing the dry etching resistance, but detailed reasons why when the resin contains the repeating unit (A) and the repeating unit (B), all of the effects above can be obtained excellently on a high level and the resolution of an isolated pattern can be enhanced, are not clearly known.

The actinic ray-sensitive or radiation-sensitive resin composition of the present invention is, for example, a positive composition and is typically a positive resist composition. The configuration of this composition is described below.

### (Resin)

The actinic ray-sensitive or radiation-sensitive resin composition of the present invention contains a resin having (A) a repeating unit represented by the following formula (I) and (B) a repeating unit capable of generating an acid upon irradiation with an actinic ray or radiation. Here, the repeating unit (A) is a group capable of decomposing by the action of an acid to generate an alkali-soluble group (hereinafter, sometimes referred to as an “acid-decomposable group”). More specifically, the repeating unit (A) represented by the following formula (I) is a repeating unit in which an ester group in the side chain and a group represented by —C(Rn)(AR)H bonded to the ester bond are cleaved by the action of an acid and a carboxylic acid is generated as an alkali-soluble group.

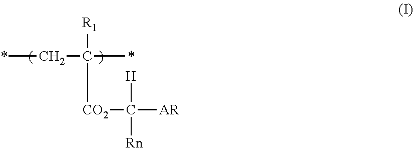

In formula (I), AR represents an aryl group, Rn represents an alkyl group, a cycloalkyl group or an aryl group, and Rn and AR may combine with each other to form a non-aromatic ring.

R₁ represents a hydrogen atom, an alkyl group, a cycloalkyl group, a halogen atom, a cyano group or an alkyloxycarbonyl group.

The aryl group of AR is preferably an aryl group having a carbon number of 6 to 20, such as phenyl group, naphthyl group, anthryl group and fluorene group, more preferably an aryl group having a carbon number of 6 to 15.

In the case where AR is a naphthyl group, an anthryl group or a fluorene group, the bonding site between AR and the carbon atom to which Rn is bonded is not particularly limited. For example, when AR is a naphthyl group, the carbon atom may be bonded to the α-position or the β-position of the naphthyl group, or when AR is an anthryl group, the carbon atom may be bonded to the 1-position, the 2-position or the 9-position of the anthryl group.

The aryl group as AR each may have one or more substituents. Specific examples of the substituent include a linear or branched alky group having a carbon number of 1 to 20, such as methyl group, ethyl group, propyl group, isopropyl group, n-butyl group, isobutyl group, tert-butyl group, pentyl group, hexyl group, octyl group and dodecyl group, an alkoxy group containing such an alkyl group moiety, a cycloalkyl group such as cyclopentyl group and cyclohexyl group, a cycloalkoxy group containing such a cycloalkyl group moiety, a hydroxyl group, a halogen atom, an aryl group, a cyano group, a nitro group, an acyl group, an acyloxy group, an acylamino group, a sulfonylamino group, an alkylthio group, an arylthio group, an aralkylthio group, a thiophenecarbonyloxy group, a thiophenemethylcarbonyloxy group, and a heterocyclic residue such as pyrrolidone residue. The substituent is preferably a linear or branched alkyl group having a carbon number of 1 to 5 or an alkoxy group containing such an alkyl group moiety, more preferably a para-methyl group or a para-methoxy group.

In the case where the aryl group as AR has a plurality of substituents, at least two members out of the plurality of substituents may combine with each other to form a ring. The ring is preferably a 5- to 8-membered ring, more preferably a 5- or 6-membered ring. The ring may be also a heterocyclic ring containing a heteroatom such as oxygen atom, nitrogen atom and sulfur atom in the ring members.

Furthermore, this ring may have a substituent. Examples of the substituent are the same as those described later for the further substituent which Rn may have.

In view of the roughness performance, the repeating unit (A) represented by formula (I) preferably contains two or more aromatic rings. Usually, the number of aromatic rings contained in the repeating unit (A) is preferably 5 or less, more preferably 3 or less.

Also, in view of the roughness performance, AR in the repeating unit (A) represented by formula (I) preferably contains two or more aromatic rings, and AR is more preferably a naphthyl group or a biphenyl group. Usually, the number of aromatic rings contained in AR is preferably 5 or less, more preferably 3 or less.

As described above, Rn represents an alkyl group, a cycloalkyl group or an aryl group.

The alkyl group of Rn may be a linear alkyl group or a branched alkyl group. The alkyl group is preferably an alky group having a carbon number of 1 to 20, such as methyl group, ethyl group, propyl group, isopropyl group, n-butyl group, isobutyl group, tert-butyl group, pentyl group, hexyl group, cyclohexyl group, octyl group and dodecyl group. The alkyl group of Rn is preferably an alkyl group having a carbon number of 1 to 5, more preferably an alkyl group having a carbon number of 1 to 3.

The cycloalkyl group of Rn includes, for example, a cycloalkyl group having a carbon number of 3 to 15, such as cyclopentyl group and cyclohexyl group.

The aryl group of Rn is preferably, for example, an aryl group having a carbon number of 6 to 14, such as phenyl group, xylyl group, toluoyl group, cumenyl group, naphthyl group and anthryl group.

Each of the alkyl group, cycloalkyl group, aryl group as Rn may further has a substituent. Examples of the substituent include an alkoxy group, a hydroxyl group, a halogen atom, a nitro group, an acyl group, an acyloxy group, an acylamino group, a sulfonylamino group, a dialkylamino group, an alkylthio group, an arylthio group, an aralkylthio group, a thiophenecarbonyloxy group, a thiophenemethylcarbonyloxy group, and a heterocyclic residue such as pyrrolidone residue. Among these, an alkoxy group, a hydroxyl group, a halogen atom, a nitro group, an acyl group, an acyloxy group, an acylamino group and a sulfonylamino group are preferred.

As described above, R₁ represents a hydrogen atom, an alkyl group, a cycloalkyl group, a halogen atom, a cyano group or an alkyloxycarbonyl group.

Examples of the alkyl group and cycloalkyl group of R₁ are the same as those described above for Rn. Each of these alkyl group and cycloalkyl group may have a substituent. Examples of this substituent are the same as those described above for Rn.

In the case where R₁ is an alkyl or cycloalkyl group having a substituent, particularly preferred examples of R₁ include a trifluoromethyl group, an alkyloxycarbonyl methyl group, an alkylcarbonyloxymethyl group, a hydroxymethyl group and an alkoxymethyl group.

The halogen atom of R₁ includes fluorine atom, chlorine atom, bromine atom and iodine atom, with fluorine atom being preferred.

As the alkyl group moiety contained in the alkyloxycarbonyl group or R₁, for example, the configuration described above as the alkyl group of R₁ may be employed.

Rn and AR preferably combine with each other to form a non-aromatic ring and in this case, particularly the roughness performance can be more improved.

The non-aromatic ring which may be formed by combining Rn and AR with each other is preferably a 5- to 8-membered ring, more preferably a 5- or 6-membered ring.

The non-aromatic ring may be an aliphatic ring or a heterocyclic ring containing a heteroatom such as oxygen atom, nitrogen atom and sulfur atom, as a ring member.

The non-aromatic ring may have a substituent. Examples of the substituent are the same as those described above for the further substituent which Rn may have.

Specific examples of the repeating unit (A) are illustrated below, but the present invention is not limited thereto.

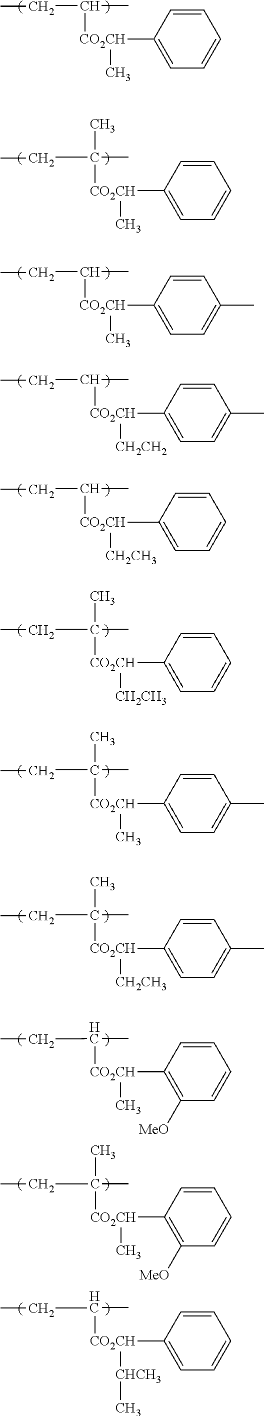

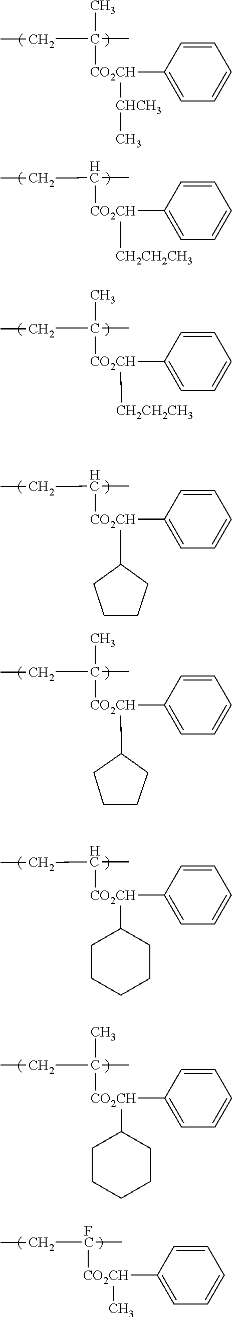

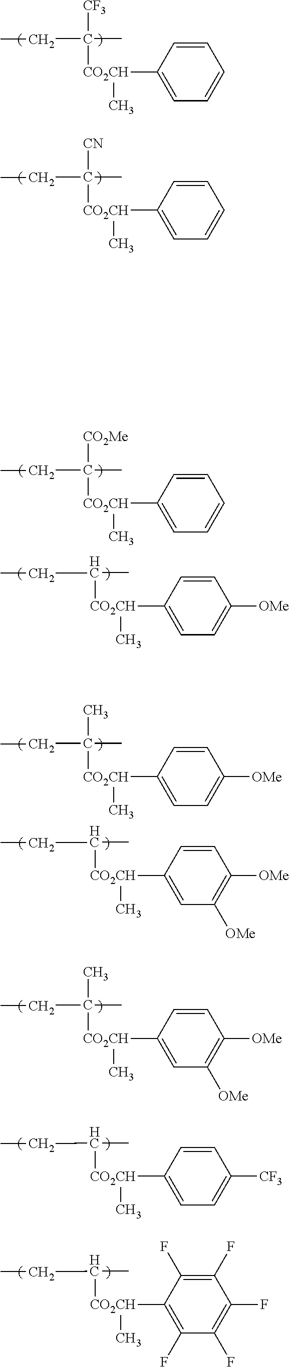

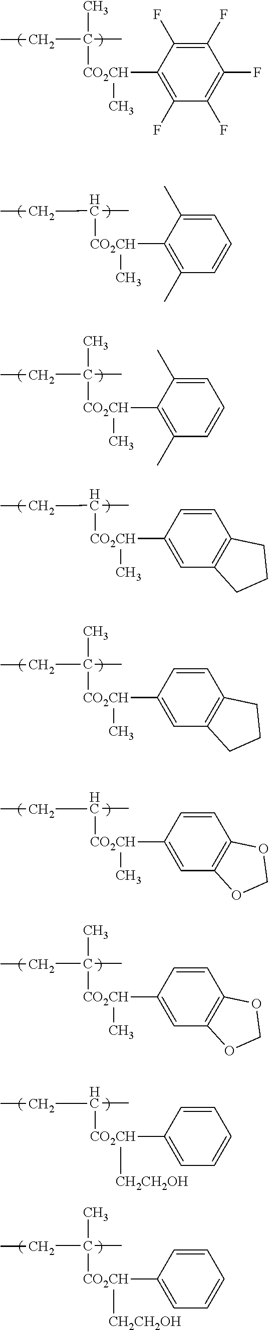

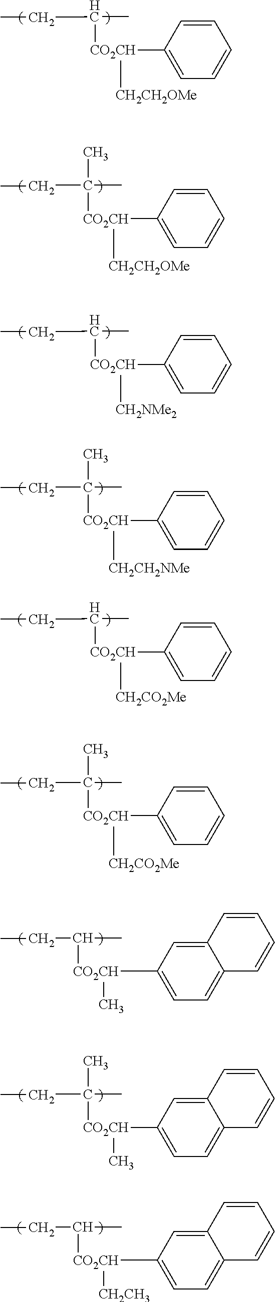

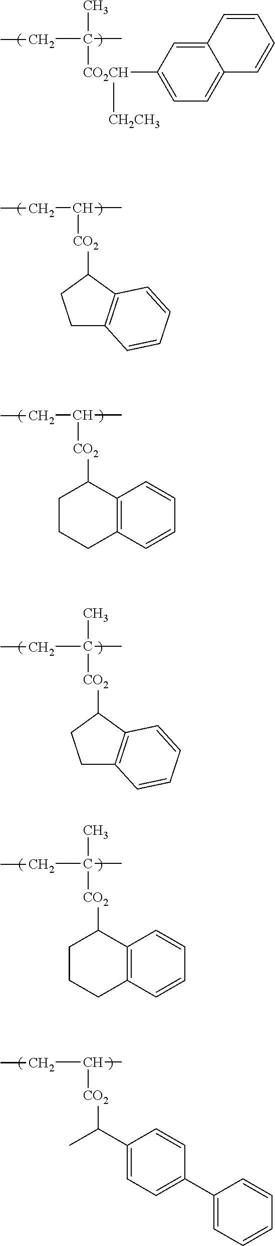

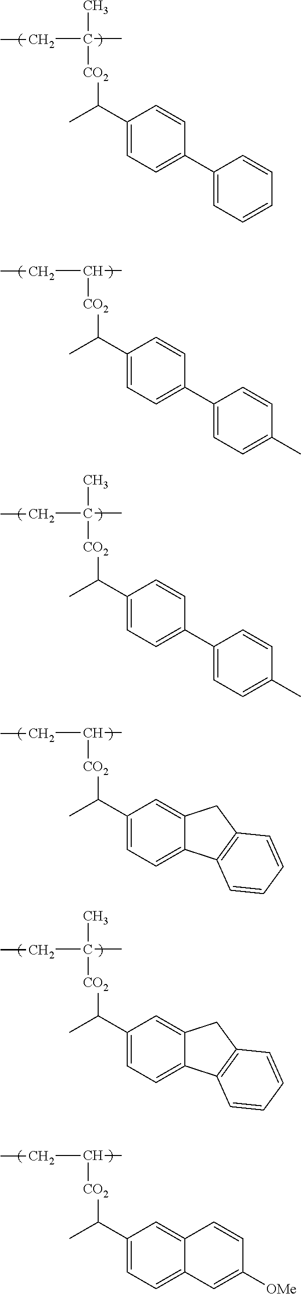

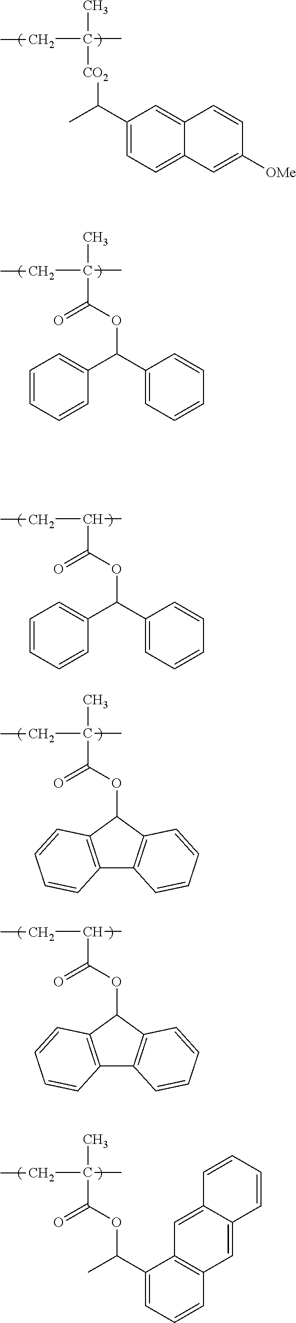

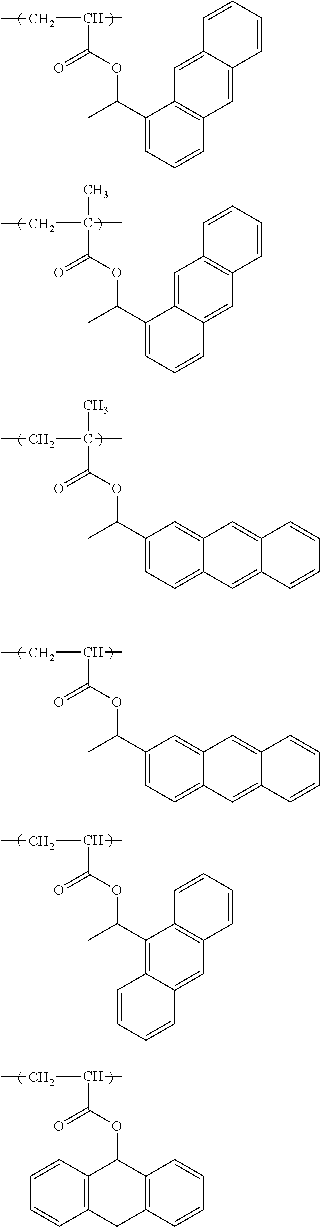

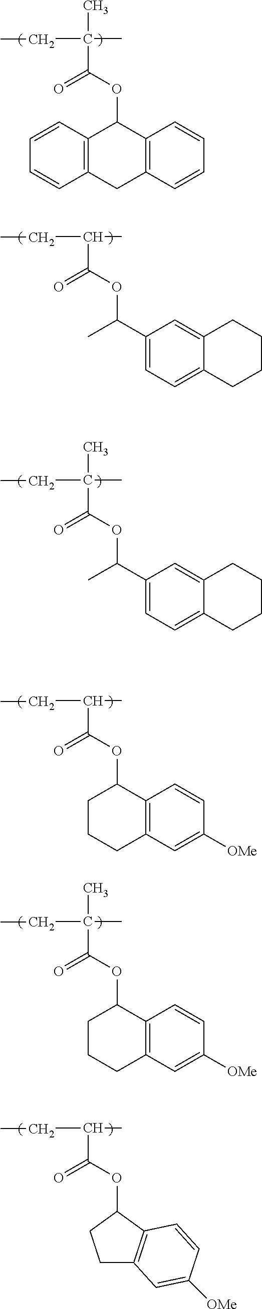

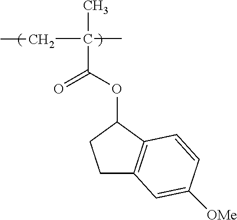

Among these, the following repeating units are preferred.

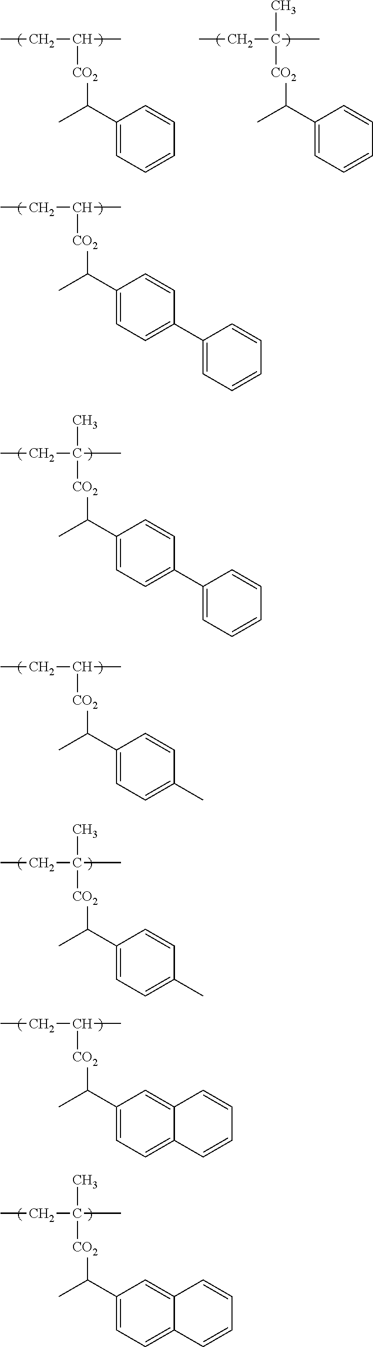

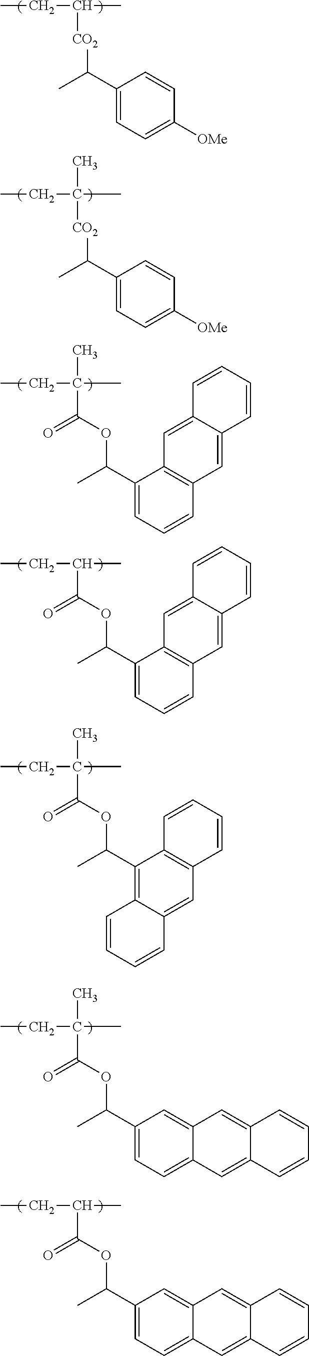

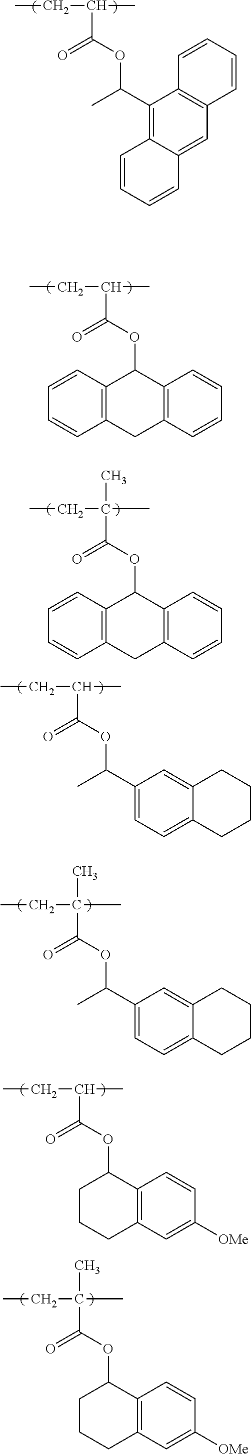

As described above, the composition of the present invention contains (B) a repeating unit capable of generating an acid upon irradiation with an actinic ray or radiation.

The repeating unit (B) is preferably at least one member selected from the group consisting of repeating units represented by the following formulae (B1), (B2) and (B3). Among these, a repeating unit represented by the following formula (B1) or (B3) is more preferred, and a repeating unit represented by the following formula (B1) is still more preferred.

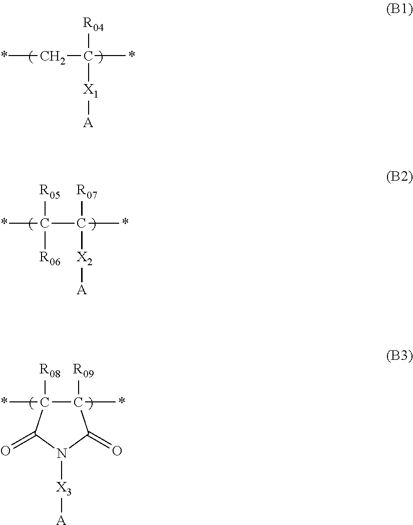

In the formulae, A represents a structural moiety capable of decomposing upon irradiation with an actinic ray or radiation to produce an acid anion.

Each of R₀₄, R₀₅ and R₀₇ to R₀₉ independently represents a hydrogen atom, an alkyl group, a cycloalkyl group, a halogen atom, a cyano group or an alkoxycarbonyl group.

R₀₆ represents a cyano group, a carboxyl group, —CO—OR₂₅ or —CO—N(R₂₆)(R₂₇). R₂₅ represents an alkyl group, a cycloalkyl group, an alkenyl group, a cycloalkenyl group, an aryl group or an aralkyl group. R₂₆ and R₂₇ may combine with each other to form a ring together with the nitrogen atom. Each of R₂₆ and R₂₇ independently represents a hydrogen atom, an alkyl group, a cycloalkyl group, an alkenyl group, a cycloalkenyl group, an aryl group or an aralkyl group.

Each of X₁ to X₃ independently represents a single bond, an arylene group, an alkylene group, a cycloalkylene group, —O—, —SO₂—, —CO—, —N(R₃₃)— or a divalent linking group formed by combining a plurality of these members. Each of X₁ to X₃ independently represents preferably an arylene group, an alkylene group, —O—, —SO₂—, —CO—, or a divalent linking group formed by combining a plurality of these members.

R₃₃ represents a hydrogen atom, an alkyl group, a cycloalkyl group, an alkenyl group, a cycloalkenyl group, an aryl group or an aralkyl group. R₃₃ is preferably a hydrogen atom or an alkyl group.

The alkyl group of R₀₄, R₀₅ and R₀₇ to R₀₉ is preferably an alkyl group having a carbon number of 20 or less, more preferably an alkyl group having a carbon number of 8 or less. Examples of such an alkyl group include a methyl group, an ethyl group, a propyl group, an isopropyl group, an n-butyl group, a sec-butyl group, a hexyl group, a 2-ethylhexyl group, an octyl group and a dodecyl group. These alkyl groups may further have a substituent.

The cycloalkyl group of R₀₄, R₀₅ and R₀₇ to R₀₉ may be monocyclic or polycyclic. This cycloalkyl group is preferably a cycloalkyl group having a carbon number of 3 to 8, and examples of such a cycloalkyl group include a cyclopropyl group, a cyclopentyl group and a cyclohexyl group.

The halogen atom of R₀₄, R₀₅ and R₀₇ to R₀₉ includes fluorine atom, chlorine atom, bromine atom and iodine atom, with fluorine atom being preferred.

As the alkyl group contained in the alkoxycarbonyl group of R₀₄, R₀₅ and R₀₇ to R₀₉, for example, those described above as the alkyl group of R₀₄, R₀₅ and R₀₇ to R₀₉ are preferred.

As the alkyl group of R₂₅ to R₂₇ and R₃₃, those described above as the alkyl group of R₀₄, R₀₅ and R₀₇ to R₀₉ are preferred.

As the cycloalkyl group of R₂₅ to R₂₇ and R₃₃, those described above as the cycloalkyl group of R₀₄, R₀₅ and R₀₇ to R₀₉ are preferred.

The alkenyl group of R₂₅ to R₂₇ and R₃₃ is preferably an alkenyl group having a carbon number of 2 to 6. Examples of such an alkenyl group include a vinyl group, a propenyl group, an allyl group, a butenyl group, a pentenyl group and a hexenyl group.

The cycloalkenyl group of R₂₅ to R₂₇ and R₃₃ is preferably a cycloalkenyl group having a carbon number of 3 to 6. Examples of such a cycloalkenyl group include a cyclohexenyl group.

The aryl group of R₂₅ to R₂₇ and R₃₃ may be a monocyclic aromatic group or a polycyclic aromatic group. The aryl group is preferably an aryl group having a carbon number of 6 to 14. This aryl group may further have a substituent. Also, the aryl groups may combine with each other to form a double ring. Examples of the aryl group of R₂₅ to R₂₇ and R₃₃ include a phenyl group, a tolyl group, a chlorophenyl group, a methoxyphenyl group and a naphthyl group.

The aralkyl group of R₂₅ to R₂₇ and R₃₃ is preferably an aralkyl group having a carbon number of 7 to 15. This aralkyl group may have a substituent. Examples of the aralkyl group of R₂₅ to R₂₇ and R₃₃ include a benzyl group, a phenethyl group and a cumyl group.

The ring formed together with the nitrogen atom by combining R₂₆ and R₂₇ is preferably a 5- to 8-membered ring, and specific examples thereof include pyrrolidine, piperidine and piperazine.

The arylene group of X₁ to X₃ is preferably an arylene group having a carbon number of 6 to 14. Examples of such an arylene group include a phenylene group, a tolylene group and a naphthylene group. These arylene groups may further have a substituent.

The alkylene group of X₁ to X₃ is preferably an alkylene group having a carbon number of 1 to 8. Examples of such an alkylene group include a methylene group, an ethylene group, a propylene group, a butylene group, a hexylene group and an octylene group. These alkylene groups may further have a substituent.

The cycloalkylene group of X₁ to X₃ is preferably a cycloalkylene group having a carbon number of 5 to 8. Examples of such a cycloalkylene group include a cyclopentylene group and a cyclohexylene group. These cycloalkylene groups may further have a substituent

Preferred examples of the substituent which each of the groups in formulae (B1) to (B3) may have include a hydroxyl group; a halogen atom (e.g., fluorine, chlorine, bromine, iodine); a nitro group; a cyano group; an amido group; a sulfonamido group; the alkyl group described above as R₀₄, R₀₅ and R₀₇ to R₀₉; an alkoxy group such as methoxy group, ethoxy group, hydroxyethoxy group, propoxy group, hydroxypropoxy group and butoxy group; an alkoxycarbonyl group such as methoxycarbonyl group and ethoxycarbonyl group; an acyl group such as formyl group, acetyl group and benzoyl group; an acyloxy group such as acetoxy group and butyryloxy group; and a carboxy group. The carbon number of such a substituent is preferably 8 or less.

A represents a structural moiety capable of decomposing upon irradiation with an actinic ray or radiation to produce an acid anion, and specific examples thereof include structural moieties contained in a photo-initiator for cationic photopolymerization, a photo-initiator for radical photopolymerization, a photodecoloring agent for dyes, a photodiscoloring agent, and known compounds capable of generating an acid by light, which are used for microresist and the like.

A is preferably an ionic structural moiety containing a sulfonium or iodonium salt structure. More specifically, A is preferably a group represented by the following formula (ZI) or (ZII):

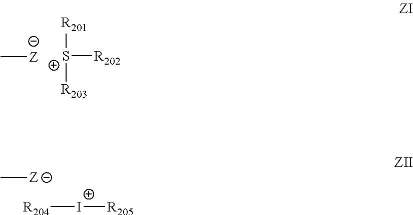

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20. Also, two members out of R₂₀₁ to R₂₀₃ may combine to form a ring structure, and the ring may contain an oxygen atom, a sulfur atom, an ester bond, an amide bond or a carbonyl group therein. Examples of the group formed by combining two members out of R₂₀₁ to R₂₀₃ include an alkylene group such as butylene group and pentylene group.

Z⁻ represents an acid anion that is generated by decomposition upon irradiation with an actinic ray or radiation. Z⁻ is preferably a non-nucleophilic anion. Examples of the non-nucleophilic anion include sulfonate anion, carboxylate anion, sulfonylimide anion, bis(alkylsulfonyl)imide anion and tris(alkylsulfonyl)methyl anion.

The non-nucleophilic anion is an anion having an extremely low ability of causing a nucleophilic reaction. When a non-nucleophilic anion is used, the decomposition with aging due to intramolecular nucleophilic reaction can be suppressed. In turn, the aging stability of the resin and the composition can be enhanced.

The organic group of R₂₀₁, R₂₀₂ and R₂₀₃ includes, for example, corresponding groups in the later-described groups represented by formulae (ZI-1), (ZI-2) and (ZI-3).

As the group represented by (ZI), the (ZI-1), (ZI-2), (ZI-3) and (ZI-4) groups described below are more preferred.

The (ZI-1) group is a group having an arylsulfonium as the cation, where at least one of R₂₀₁ to R₂₀₃ in formula (ZI) is an aryl group.

All of R₂₀₁ to R₂₀₃ may be an aryl group or a part of R₂₀₁ to R₂₀₃ may be an aryl group with the remaining being an alkyl group or a cycloalkyl group.

Examples of the (ZI-1) group include groups corresponding to triarylsulfonium, diarylalkylsulfonium, aryldialkylsulfonium, diarylcycloalkylsulfonium and aryldicycloalkylsulfonium, respectively.

The aryl group in the arylsulfonium is preferably a phenyl group or a naphthyl group, more preferably a phenyl group. The aryl group may have a heterocyclic structure containing a heteroatom such as oxygen atom, nitrogen atom and sulfur atom. Examples of the heterocyclic structure include pyrrole, furan, thiophene, indole, benzofuran and benzothiophene. In the case where the arylsulfonium has two or more aryl groups, each aryl group may be the same as or different from every other aryl groups.

The alkyl or cycloalkyl group which is present, if desired, in the arylsulfonium is preferably a linear or branched alkyl group having a carbon number of 1 to 15 or a cycloalkyl group having a carbon number of 3 to 15. Examples of such an alkyl or cycloalkyl group include a methyl group, an ethyl group, a propyl group, an n-butyl group, a sec-butyl group, a tert-butyl group, a cyclopropyl group, a cyclobutyl group and a cyclohexyl group.

The aryl group, alkyl group and cycloalkyl group of R₂₀₁ to R₂₀₃ may have, as a substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group.

Preferred examples of the substituent include a linear or branched alkyl group having a carbon number of 1 to 12, a cycloalkyl group having a carbon number of 3 to 12, and a linear, branched or cyclic alkoxy group having a carbon number of 1 to 12. More preferred examples of the substituent include an alkyl group having a carbon number of 1 to 4, and an alkoxy group having a carbon number of 1 to 4. The substituent may be substituted on any one of three members R₂₀₁ to R₂₀₃ or may be substituted on two or more of these members. In the case where R₂₀₁ to R₂₀₃ are a phenyl group, the substituent is preferably substituted at the p-position of the phenyl group.

The (ZI-2) group is described below.

The (ZI-2) group is a group where each of R₂₀₁ to R₂₀₃ in formula (ZI) independently represents an aromatic ring-free organic group. The aromatic ring as used herein includes a heterocyclic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ is independently, preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10 (e.g., methyl group, ethyl group, propyl group, butyl group, pentyl group), and a cycloalkyl group having a carbon number of 3 to 10 (e.g., cyclopentyl group, cyclohexyl group, norbornyl group). This alkyl group is more preferably a 2-oxoalkyl group or an alkoxycarbonylmethyl group, and the cycloalkyl group is more preferably a 2-oxocycloalkyl group.

The 2-oxoalkyl group may be either linear or branched. The 2-oxoalkyl group is preferably a group having >C═O at the 2-position of the above-described alkyl group. The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5 (e.g., methoxy group, ethoxy group, propoxy group, butoxy group, pentoxy group).

R₂₀₁ to R₂₀₃ may be further substituted, for example, with a halogen atom, an alkoxy group (for example, having a carbon number of 1 to 5), a hydroxyl group, a cyano group or a nitro group.

The (ZI-3) group is described below.

The (ZI-3) group is a group represented by the following formula (ZI-3), and this is a group having a phenacylsulfonium salt structure.

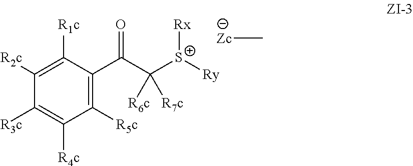

In formula (ZI-3), each of R_{1c} to R_{5c} independently represents a hydrogen atom, an alkyl group, a cycloalkyl group, an alkoxy group or a halogen atom.

Each of R_{6c} and R_{7c} independently represents a hydrogen atom, an alkyl group or a cycloalkyl group.

Each of Rₓ and R_{y} independently represents an alkyl group, a cycloalkyl group, an allyl group or a vinyl group.

Two or more members out of R_{1c} to R_{5c}, the pair of R_{6c} and R_{7c}, or the pair of Rₓ and R_{y} may combine with each other to form a ring structure. The ring structure may contain an oxygen atom, a sulfur atom, an ester bond and/or an amide bond. Examples of the group formed by combining these with each other include a butylene group and a pentylene group.

Zc⁻ represents a non-nucleophilic anion, and examples thereof are the same as those of Z⁻ in formula (ZI).

As for specific structures of the cation moiety of formula (ZI-3), please refer to cation moiety structures of the acid generators illustrated in paragraphs 0047 and 0048 of JP-A-2004-233661 and paragraphs 0040 to 0046 of JP-A-2003-35948.

The (ZI-4) group is described below.

The (ZI-4) group is a group represented by the following formula (ZI-4). This group is effective to suppress outgassing.

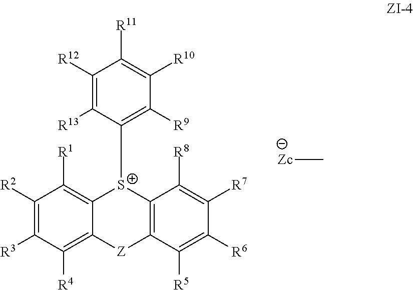

In formula (ZI-4), each of R′ to R¹³ independently represents a hydrogen atom or a substituent, and at least one of R¹ to R¹³ is preferably a substituent containing an alcoholic hydroxyl group. The term “alcoholic hydroxyl group” as used herein means a hydroxyl group bonded to a carbon atom of an alkyl group.

Z represents a single bond or a divalent linking group.

Zc⁻ represents a non-nucleophilic anion, and examples thereof are the same as those of Z⁻ in formula (ZI).

In the case where R¹ to R¹³ are a substituent containing an alcoholic hydroxyl group, each of R¹ to R¹³ is preferably a group represented by —(W—Y), wherein Y is an alkyl group substituted with a hydroxyl group and W is a single bond or a divalent linking group.

Preferred examples of the alkyl group represented by Y include an ethyl group, a propyl group and an isopropyl group. In particular, Y preferably contains a structure represented by —CH₂CH₂OH.

The divalent linking group represented by W is not particularly limited but is preferably a single bond or a divalent group formed by substituting a single bond for an arbitrary hydrogen atom of an alkoxy group, an acyloxy group, an acylamino group, an alkyl- or aryl-sulfonylamino group, an alkylthio group, an alkylsulfonyl group, an acyl group, an alkoxycarbonyl group or a carbamoyl group, more preferably a single bond or a divalent group formed by substituting a single bond for an arbitrary hydrogen atom of an acyloxy group, an alkylsulfonyl group, an acyl group or an alkoxycarbonyl group.

In the case where R¹ to R¹³ are a substituent containing an alcoholic hydroxyl group, the number of carbons contained therein is preferably from 2 to 10, more preferably from 2 to 6, still more preferably from 2 to 4.

The alcoholic hydroxyl group-containing substituent as R¹ to R¹³ may have two or more alcoholic hydroxyl groups. The number of alcoholic hydroxyl groups in the alcoholic hydroxyl group-containing substituent as R¹ to R¹³ is from 1 to 6, preferably from 1 to 3, more preferably 1.

The number of alcoholic hydroxyl groups contained in the (ZI-4) group is, in total of all of R¹ to R¹³, from 1 to 10, preferably from 1 to 6, more preferably from 1 to 3.

In the case where R¹ to R¹³ contain no alcoholic hydroxyl group, examples of R¹ to R¹³ include a hydrogen atom, a halogen atom, an alkyl group, a cycloalkyl group, an alkenyl group, a cycloalkenyl group, an alkynyl group, an aryl group, a heterocyclic group, a cyano group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl- or aryl-sulfonylamino group, a mercapto group, an alkylthio group, an arylthio group, a heterocyclic thio group, a sulfamoyl group, a sulfo group, an alkyl- or aryl-sulfinyl group, an alkyl- or aryl-sulfonyl group, an acyl group, an aryloxycarbonyl group, an alkoxycarbonyl group, a carbamoyl group, an aryl- or heterocyclic azo group, an imido group, a phosphino group, a phosphinyl group, a phosphinyloxy group, a phosphinylamino group, a phosphono group, a silyl group, a hydrazino group, a ureido group, a boronic acid group [—B(OH)₂], a phosphato group [—OPO(OH)₂], a sulfato group (—OSO₃H), and other known substituents.

In the case where R¹ to R¹³ contain no alcoholic hydroxyl group, each of R¹ to R¹³ is preferably a hydrogen atom, a halogen atom, an alkyl group, a cycloalkyl group, a cyano group, an alkoxy group, an acyloxy group, an acylamino group, an aminocarbonylamino group, an alkoxycarbonylamino group, an alkyl- or aryl-sulfonylamino group, an alkylthio group, a sulfamoyl group, an alkyl- or aryl-sulfonyl group, an alkoxycarbonyl group or a carbamoyl group.

In the case where R¹ to R¹³ contain no alcoholic hydroxyl group, each of R¹ to R¹³ is more preferably a hydrogen atom, an alkyl group, a cycloalkyl group, a halogen atom or an alkoxy group.

Two adjacent members out of R¹ to R¹³ may combine with each other to form a ring structure. This ring structure includes an aromatic or non-aromatic hydrocarbon ring and a heterocyclic ring. These ring structures may further combine to form a condensed ring.

The (ZI-4) group preferably has a structure where at least one of R¹ to R¹³ contains an alcoholic hydroxyl group, more preferably a structure where at least one of R⁹ to R¹³ contains an alcoholic hydroxyl group.

Z represents, as described above, a single bond or a divalent linking group. Examples of the divalent linking group include an alkylene group, an arylene group, a carbonyl group, a sulfonyl group, a carbonyloxy group, a carbonylamino group, a sulfonylamido group, an ether bond, a thioether bond, an amino group, a disulfide group, an acyl group, an alkylsulfonyl group, —CH═CH—, an aminocarbonylamino group and an aminosulfonylamino group.

The divalent linking group may have a substituent. Examples of the substituent thereof are the same as those enumerated above for R¹ to R¹³.

Z is preferably a single bond, an ether bond or a thioether more, more preferably a single bond.

Formula (ZII) is described below.

In formula (ZII), each of R₂₀₄ and R₂₀₅ independently represents an aryl group, an alkyl group or a cycloalkyl group.

Specific examples, preferred embodiments and the like of the aryl group, alkyl group and cycloalkyl group of R₂₀₄ and R₂₀₅ are the same as those described above for R₂₀₁ to R₂₀₃ in the compound (ZI-1).

The aryl group, alkyl group and cycloalkyl group of R₂₀₄ and R₂₀₅ may have a substituent. Examples of the substituent are also the same as those described for R₂₀₁ to R₂₀₃ in the compound (ZI-1).

Z⁻ represents an acid anion that is generated by decomposition upon irradiation with an actinic ray or radiation and is preferably a non-nucleophilic anion. Examples thereof are the same as those of Z⁻ in formula (ZI).

Preferred examples of A also include groups represented by the following formulae (ZCI) and (ZCII):

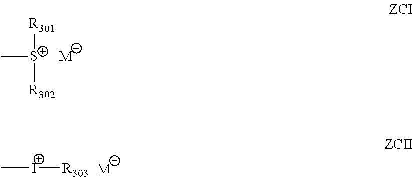

In formulae (ZCI) and (ZCII), each of R₃₀₁ and R₃₀₂ independently represents an organic group. The carbon number of the organic group is generally from 1 to 30, preferably from 1 to 20. R₃₀₁ and R₃₀₂ may combine with each other to form a ring structure, and the ring structure may contain at least one of an oxygen atom, a sulfur atom, an ester bond, an amide bond and a carbonyl group in the ring. The group which may be formed by combining R₃₀₁ and R₃₀₂ with each other includes an alkylene group such as butylene group and pentylene group.

Examples of the organic group of R₃₀₁ and R₃₀₂ include the aryl groups, alkyl groups and cycloalkyl groups described as examples of R₂₀₁ to R₂₀₃ in formula (ZI).

M⁻ represents an atomic group for forming an acid by accepting a proton. More specifically, the atomic group is a structure represented by any of formulae AN1 to AN3 described later. Above all, a structure represented by formula AN1 is preferred.

R₃₀₃ represents an organic group. The carbon number of the organic group as R₃₀₃ is generally from 1 to 30, preferably from 1 to 20. Specific examples of the organic group of R₃₀₃ include the aryl groups, alkyl groups and cycloalkyl groups descried above as specific examples of R₂₀₄ and R₂₀₅ in formula (ZII).

The structural moiety capable of generating an acid upon irradiation with an actinic ray or radiation includes, for example, a structural moiety working out to a sulfonic acid precursor contained in the following photo-acid generator. Examples of the photo-acid generator include the compounds of the following (1) to (3):

(1) compounds capable of undergoing a photolysis to generate a sulfonic acid, typified by iminosulfonate and the like, described in M. TUNOOKA et al., Polymer Preprints Japan, 35 (8), G. Berner et al., J. Rad. Curing, 13 (4); W. J. Mijs et al., Coating Technol., 55 (697), 45 (1983), H. Adachi et al., Polymer Preprints, Japan, 37 (3), European Patents 0,199,672, 84,515, 199,672, 044,115 and 0,101,122, U.S. Pat. Nos. 618,564, 4,371,605 and 4,431,774, JP-A-64-18143, JP-A-2-245756 and JP-A-4-365048; (2) disulfone compounds described in JP-A-61-166544; and (3) compounds capable of generating an acid by light described in V.N.R. Pillai, Synthesis, (1), 1 (1980), A. Abad et al., Tetrahedron Lett., (47), 4555 (1971), D. H. R. Barton et al., J. Chem. Soc., (C), 329 (1970), U.S. Pat. No. 3,779,778 and European Patent 126,712.

The repeating unit (B) preferably has a structural moiety capable of being converted into an acid anion upon irradiation with an actinic ray or radiation. For example, A in formulae (B1) to (B3) is preferably a structural moiety capable of being converted into an acid anion upon irradiation with an actinic ray or radiation.

That is, the repeating unit (B) is more preferably a structure capable of generating an acid anion in the side chain of the resin upon irradiation with an actinic ray or radiation. When such a structure is employed, diffusion of the generated acid anion is suppressed, and the resolution, roughness characteristics and the like can be more improved.

Each of the moiety —X₁-A in formula (B1), the moiety —X₂-A in formula (B2) and the moiety —X₃-A in formula (B3) is preferably represented by any of the following formulae (L1), (L2) and (L3):

—X₁₁-L₁₁-X₁₂—Ar₁—X₁₃-L₁₂-Z₁ (L1)

—Ar₂—X₂₁-L₂₁-X₂₂-L₂₂-Z₂ (L2)

—X₃₁-L₃₁-X₃₂-L₃₂-Z₃ (L3)

The moiety represented by formula (L1) is described below.

X₁₁ represents —O—, —S—, —CO—, —SO₂—, —NR— (R is a hydrogen atom or an alkyl group), a divalent nitrogen-containing non-aromatic heterocyclic group, or a group formed by a combination thereof.

Each of X₁₂ and X₁₃ independently represents a single bond, —O—, —S—, —CO—, —SO₂—, —NR— (R is a hydrogen atom or an alkyl group), a divalent nitrogen-containing non-aromatic heterocyclic group or a group formed by a combination thereof.

The alkyl group of R may be linear or branched. Also, the alkyl group of R may further have a substituent. The alkyl group preferably has a carbon number of 20 or less, more preferably 8 or less, still more preferably 3 or less. Examples of such an alkyl group include a methyl group, an ethyl group, a propyl group and an isopropyl group. In particular, R is preferably a hydrogen atom, a methyl group or an ethyl group.

Incidentally, the divalent nitrogen-containing non-aromatic heterocyclic group means preferably a 3- to 8-membered non-aromatic heterocyclic group having at least one nitrogen atom.

X₁₁ is preferably —O—, —CO—, —NR— (R is a hydrogen atom or an alkyl group), or a group formed by a combination thereof, more preferably —COO— or —CONR— (R is a hydrogen atom or an alkyl group).

L₁₁ represents an alkylene group, an alkenylene group, a divalent aliphatic hydrocarbon ring group, or a group formed by a combination of two or more thereof. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

The alkylene group of L₁₁ may be linear or branched. The alkylene group is preferably an alkylene having a carbon number of 1 to 8, more preferably an alkylene group having a carbon number of 1 to 6, still more preferably an alkylene group having a carbon number of 1 to 4.

The alkenylene group of L₁₁ includes, for example, a group having a double bond at an arbitrary position of the above-described alkylene group.

The divalent aliphatic hydrocarbon ring group as L₁₁ may be either monocyclic or polycyclic. The divalent aliphatic hydrocarbon ring group is preferably a divalent aliphatic hydrocarbon ring group having a carbon number of 5 to 12, more preferably a divalent aliphatic hydrocarbon ring group having a carbon number of 6 to 10.

The divalent aromatic ring group as the linking group may be an arylene group or a heteroarylene group. The aromatic ring group preferably has a carbon number of 6 to 14. This aromatic ring group may further have a substituent.

Examples of —NR— and divalent nitrogen-containing non-aromatic heterocyclic group as the linking group are the same as those of respective groups in X₁₁ above.

L₁₁ is preferably an alkylene group, a divalent aliphatic hydrocarbon ring group, or a group formed by combining an alkylene group and a divalent aliphatic hydrocarbon ring group through —OCO—, —O— or —CONH— (for example, -alkylene group-O-alkylene group-, -alkylene group-OCO-alkylene group-, or -divalent aliphatic hydrocarbon ring group-O-alkylene group-, or -alkylene group-CONH-alkylene group-).

Specific examples of —NR— and divalent nitrogen-containing non-aromatic heterocyclic group in X₁₂ and X₁₃ are the same as those of respective groups in X₁₁ above, and preferred examples are also the same.

X₁₂ is preferably a single bond, —S—, —O—, —CO—, —SO₂— or a group formed by a combination thereof, more preferably a single bond, —S—, —OCO— or —OSO₂—.

X₁₃ is preferably —O—, —CO—, —SO₂— or a group formed by a combination thereof, more preferably −OSO₂—.

Ar₁ represents a divalent aromatic ring. The divalent aromatic ring group may be an arylene group or a heteroarylene group. This divalent aromatic ring group may further have a substituent. Examples of the substituent include an alkyl group, an alkoxy group and an aryl group.

Ar₁ is preferably an arylene group having a carbon number of 6 to 18, which may have a substituent, or an aralkylene group formed by combining an arylene group having a carbon number of 6 to 18 and an alkylene group having a carbon number of 1 to 4, more preferably a phenylene group, a naphthylene group, a biphenylene group, or a phenylene group substituted with a phenyl group.

L₁₂ represents an alkylene group, an alkenylene group, a divalent aliphatic hydrocarbon ring group, a divalent aromatic ring group, or a group formed by a combination of two or more thereof, and in these groups, hydrogen atoms are partially or entirely substituted for by a substituent selected from a fluorine atom, an alkyl fluoride group, a nitro group and a cyano group. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

L₁₂ is preferably an alkylene group or divalent aromatic ring group with hydrogen atoms being partially or entirely substituted for by a fluorine atom or an alkyl fluoride group (more preferably a perfluoroalkyl group), or a group formed by a combination thereof, more preferably an alkylene group or divalent aromatic ring group with hydrogen atoms being partially or entirely substituted for by a fluorine atom. L₁₂ is still more preferably an alkylene group or divalent aromatic ring group where from 30 to 100% by number of hydrogen atoms are substituted for by a fluorine atom.

The alkylene group of L₁₂ may be linear or branched. This alkylene group preferably has a carbon number of 1 to 6, more preferably from 1 to 4.

Examples of the alkenylene group of L₁₂ include a group having a double bond at an arbitrary position of the above-described alkylene group.

The divalent aliphatic hydrocarbon ring group of L₁₂ may be monocyclic or polycyclic. This divalent aliphatic hydrocarbon ring group is preferably a divalent aliphatic hydrocarbon ring group having a carbon number of 3 to 17.

Examples of the divalent aromatic ring group as L₁₂ are the same as those described above as the linking group in L₁₁.

Specific examples of —NR— and divalent nitrogen-containing non-aromatic heterocyclic group as the linking group in L₁₂ are the same as those of respective groups in X₁₁ above, and preferred examples are also the same.

Z₁ represents a moiety working out to a sulfonic acid group upon irradiation with an actinic ray or radiation, and specific examples thereof include a structure represented by formula (ZI).

The moiety represented by formula (L2) is described below.

Ar₂ represents a divalent aromatic ring group. The divalent aromatic ring group may be an arylene group or a heteroarylene group. The divalent aromatic ring group preferably has a carbon number of 6 to 18. This divalent aromatic ring group may further have a substituent.

X₂₁ represents —O—, —S—, —CO—, —SO₂—, —NR— (R is a hydrogen atom or an alkyl group), a divalent nitrogen-containing non-aromatic heterocyclic group, or a group formed by a combination thereof.

Examples of —NR— and divalent nitrogen-containing non-aromatic heterocyclic group in X₂₁ are the same as those described above for X₁₁.

X₂₁ is preferably —O—, —S—, —CO—, —SO₂— or a group formed by a combination thereof, more preferably —O—, —OCO— or —OSO₂—.

X₂₂ represents a single bond, —O—, —S—, —CO—, —SO₂—, —NR— (R is a hydrogen atom or an alkyl group), a divalent nitrogen-containing non-aromatic heterocyclic group, or a group formed by a combination thereof. Examples of —NR— and divalent nitrogen-containing non-aromatic heterocyclic group in X₂₂ are the same as those described above for X₁₁.

X₂₂ is preferably —O—, —S—, —CO—, —SO₂— or a group formed by a combination thereof, more preferably —O—, —OCO— or —OSO₂—.

L₂₁ represents a single bond, an alkylene group, an alkenylene group, a divalent aliphatic hydrocarbon ring group, a divalent aromatic ring group, or a group formed by a combination of two or more thereof. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

Examples of the alkylene group, alkenylene group and divalent aliphatic hydrocarbon ring group of L₂₁ are the same as those described above for respective groups in L₁₁.

The divalent aromatic ring group of L₂₁ may be an arylene group or a heteroarylene group. This divalent aromatic ring group preferably has a carbon number of 6 to 14.

Examples of —NR— and divalent nitrogen-containing non-aromatic heterocyclic group in L₂₁ are the same as those described above for X₁₁.

L₂₁ is preferably a single bond, an alkylene group, a divalent aliphatic hydrocarbon ring group, a divalent aromatic ring group, or a group formed by a combination of two or more thereof (for example, -alkylene group-divalent aromatic ring group- or -divalent aliphatic hydrocarbon ring group-alkylene group-), or a group formed by combining two or more of these groups through a linking group such as —OCO—, —COO—, —O— and —S-(for example, -alkylene group-OCO-divalent aromatic ring group-, -alkylene group-5-divalent aromatic ring group-, or -alkylene group-O-alkylene group-divalent aromatic ring group).

L₂₂ represents an alkylene group, an alkenylene group, a divalent aliphatic hydrocarbon ring group, a divalent aromatic ring group, or a group formed by a combination of two or more thereof, and in these groups, hydrogen atoms may be partially or entirely substituted for by a substituent selected from a fluorine atom, an alkyl fluoride group, a nitro group and a cyano group. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

L₂₂ is preferably an alkylene group or divalent aromatic ring group with hydrogen atoms being partially or entirely substituted for by a fluorine atom or an alkyl fluoride group (more preferably a perfluoroalkyl group), or a group formed by a combination thereof, more preferably an alkylene group or divalent aromatic ring group with hydrogen atoms being partially or entirely substituted for by a fluorine atom.

Specific examples of the alkylene group, alkenylene group, aliphatic hydrocarbon ring group, divalent aromatic ring group and group formed by a combination of two or more thereof, represented by L₂₂, are the same as the groups exemplified above as L₁₂ in formula (L1).

Specific examples of —NR— and divalent nitrogen-containing non-aromatic heterocyclic group as the linking group in L₂₂ are the same as those of respective groups in X₁₁ above, and preferred examples are also the same.

Z₂ represents a moiety working out to a sulfonic acid group upon irradiation with an actinic ray or radiation. Specific examples of Z₂ are the same described above for Z₁.

The moiety represented by formula (L3) is described below.

Each of X₃₁ and X₃₂ independently represents a single bond, —O—, —S—, —CO—, —SO₂—, —NR— (R is a hydrogen atom or an alkyl group), a divalent nitrogen-containing non-aromatic heterocyclic group, or a group formed by a combination thereof.

Examples of —NR— and divalent nitrogen-containing non-aromatic heterocyclic group in each of X₃₁ and X₃₂ are the same as those described above for X₁₁.

X₃₁ is preferably a single bond, —O—, —CO—, —NR— (R is a hydrogen atom or an alkyl group) or a group formed by a combination thereof, more preferably a single bond, —COO— or —CONR— (R is a hydrogen atom or an alkyl group).

X₃₂ is preferably —O—, —S—, —CO—, —SO₂—, a divalent nitrogen-containing non-aromatic heterocyclic group or a group formed by a combination thereof, more preferably —O—, —OCO— or —OSO₂—.

L₃₁ represents a single bond, an alkylene group, an alkenylene group, a divalent aliphatic hydrocarbon ring group, a divalent aromatic ring group, or a group formed by a combination of two or more thereof. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

Examples of the alkylene group, alkenylene group, divalent aliphatic hydrocarbon ring group and divalent aromatic ring group of L₃₁ are the same as those described above for L₂₁.

Specific examples of —NR— and divalent nitrogen-containing non-aromatic heterocyclic group as the linking group in L₃₁ are the same as those of respective groups in X₁₁ above, and preferred examples are also the same.

L₃₂ represents an alkylene group, an alkenylene group, a divalent aliphatic hydrocarbon ring group, a divalent aromatic ring group, or a group formed by a combination of two or more thereof. In the group formed by a combination, two or more groups combined may be the same as or different from each other. Also, these groups may be connected through —O—, —S—, —CO—, —SO₂—, —NR— (R is a hydrogen atom or an alkyl group), a divalent nitrogen-containing non-aromatic heterocyclic group, a divalent aromatic ring group, or a group formed by a combination thereof.

In the alkylene group, alkenylene group, divalent aliphatic hydrocarbon ring group, divalent aromatic ring group and group formed by a combination of two or more thereof, represented by L₃₂, part or all of hydrogen atoms are preferably substituted for by a substituent selected from a fluorine atom, an alkyl fluoride group, a nitro group and a cyano group.

L₃₂ is preferably an alkylene group or divalent aromatic ring group with hydrogen atoms being partially or entirely substituted for by a fluorine atom or an alkyl fluoride group (more preferably a perfluoroalkyl group), or a group formed by a combination thereof, more preferably an alkylene group or divalent aromatic ring group with hydrogen atoms being partially or entirely substituted for by a fluorine atom.

Examples of the alkylene group, alkenylene group, divalent aliphatic hydrocarbon ring group and divalent aromatic ring group and group formed by a combination of two or more thereof, represented by L₃₂, are the same as those described above for L₁₂. Specific examples of —NR— and divalent nitrogen-containing non-aromatic heterocyclic group as the linking group in L₃₂ are the same as those of respective groups in X₁₁ above, and preferred examples are also the same.

In the case where X₃ is a single bond and L₃₁ is an aromatic ring group, when R₃₂ and the aromatic ring group of L₃₁ form a ring, the alkylene group represented by R₃₂ is preferably an alkylene group having a carbon number of 1 to 8, more preferably an alkylene group having a carbon number of 1 to 4, still more preferably an alkylene group having a carbon number of 1 to 2.

Z₃ represents an onium salt working out to an imide acid group or a methide acid group upon irradiation with an actinic ray or radiation. The onium salt represented by Z₃ is preferably a sulfonium salt or an iodonium salt and is preferably a structure represented by the following formula (ZIII) or (ZIV):

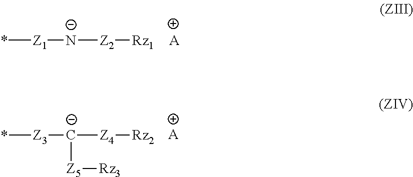

In formulae (ZIII) and (ZIV), each of Z₁, Z₂, Z₃, Z₄ and Z₅ independently represents —CO— or —SO₂—, preferably —SO₂—.

Each of Rz₁, Rz₂ and Rz₃ independently represents an alkyl group, a monovalent aliphatic hydrocarbon ring group, an aryl group or an aralkyl group. An embodiment where a part or all of hydrogen atoms are substituted for by a fluorine atom or a fluoroalkyl group (more preferably a perfluoroalkyl group), is preferred.

The alkyl group of Rz₁, Rz₂ and Rz₃ may be linear or branched. This alkyl group preferably has a carbon number of 1 to 8, more preferably from 1 to 6, still more preferably from 1 to 4.

The monovalent aliphatic hydrocarbon ring group of Rz₁, Rz₂ and Rz₃ preferably has a carbon number of 3 to 10, more preferably from 3 to 6.

The aryl group of Rz₁, Rz₂ and Rz₃ preferably has a carbon number of 6 to 18, more preferably from 6 to 10. In particular, this aryl group is preferably a phenyl group.

Preferred examples of the aralkyl group of Rz₁, Rz₂ and Rz₃ include a group formed by combining an alkylene group having a carbon number of 1 to 8 and the above-described aryl group. An aralkyl group formed by combining an alkylene group having a carbon number of 1 to 6 and the above-described aryl group is more preferred, and an aralkyl group formed by combining an alkylene group having a carbon number of 1 to 4 and the above-described aryl group is still more preferred,

A⁺ represents a sulfonium cation or an iodonium cation. Preferred examples of A⁺ include a sulfonium cation in formula (ZI) and an iodonium cation structure in formula (ZII).

Specific examples of the repeating unit (B) are illustrated below, but the scope of the present invention is not limited thereto.

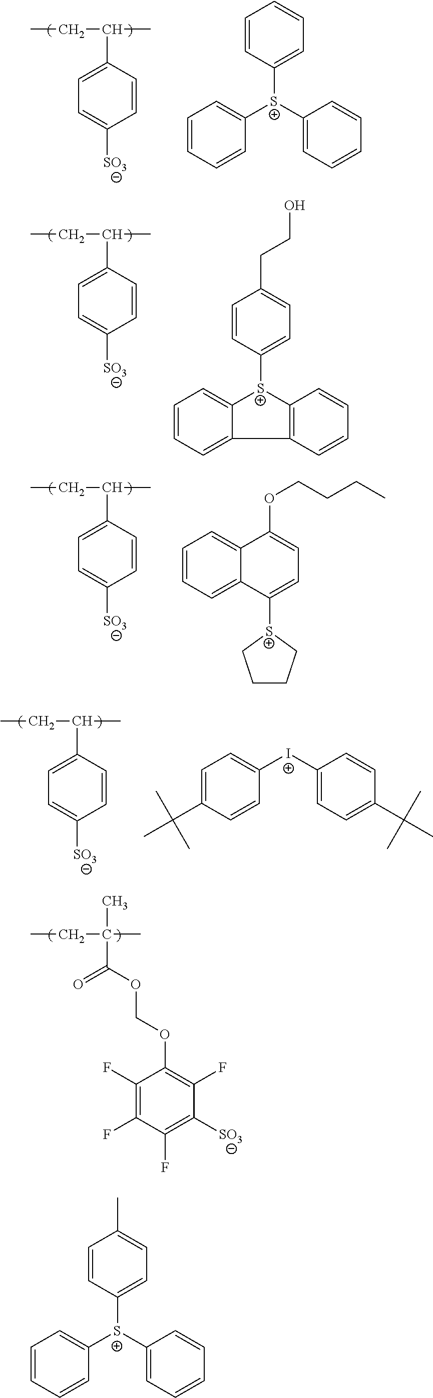

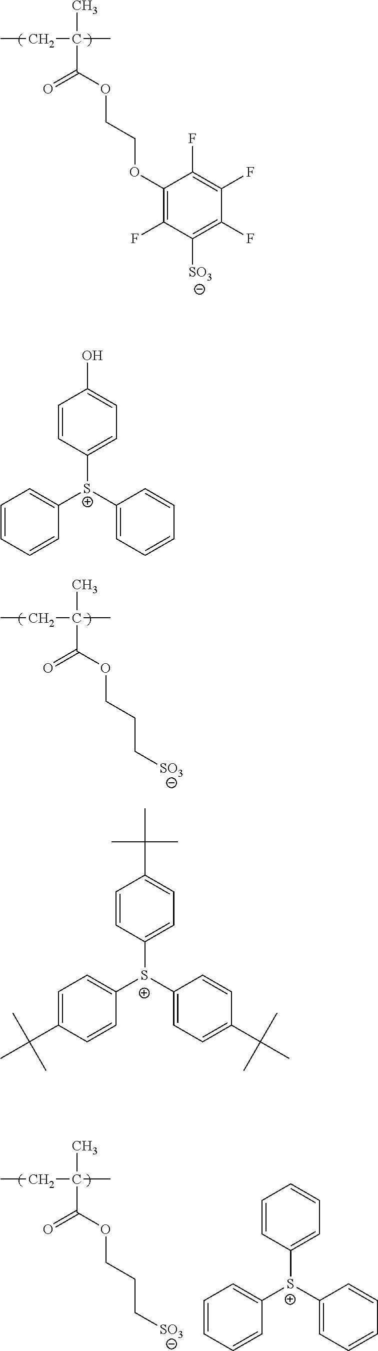

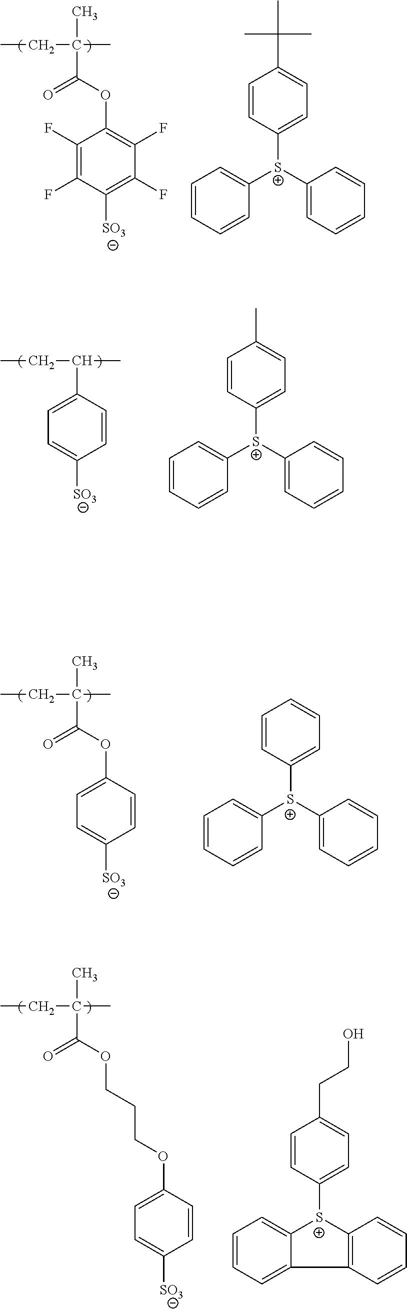

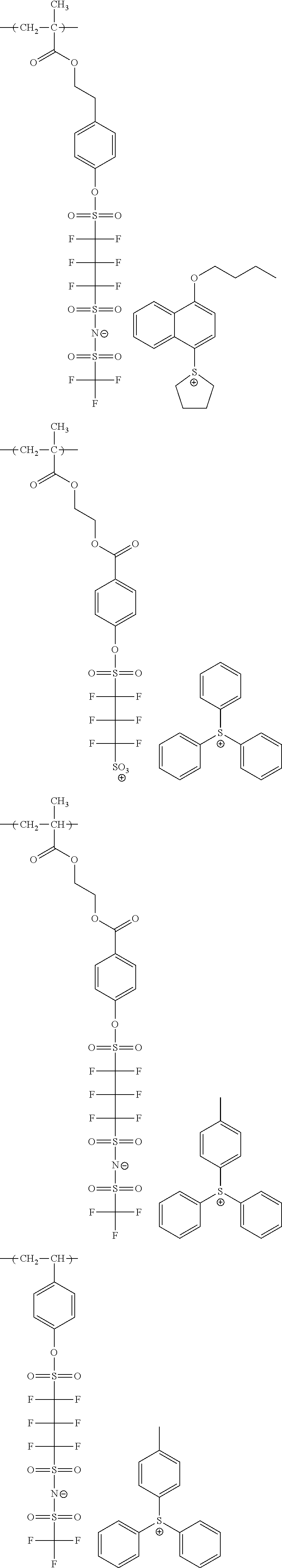

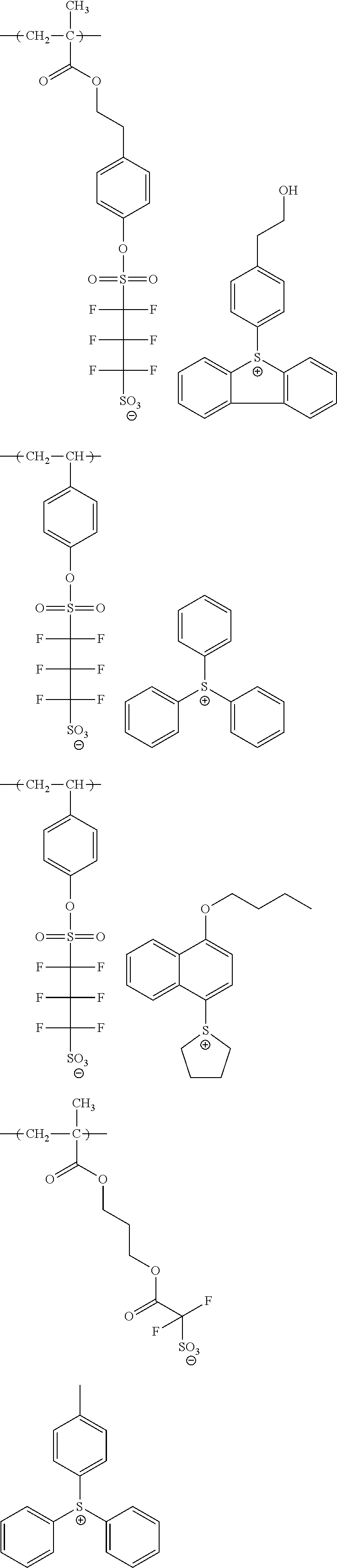

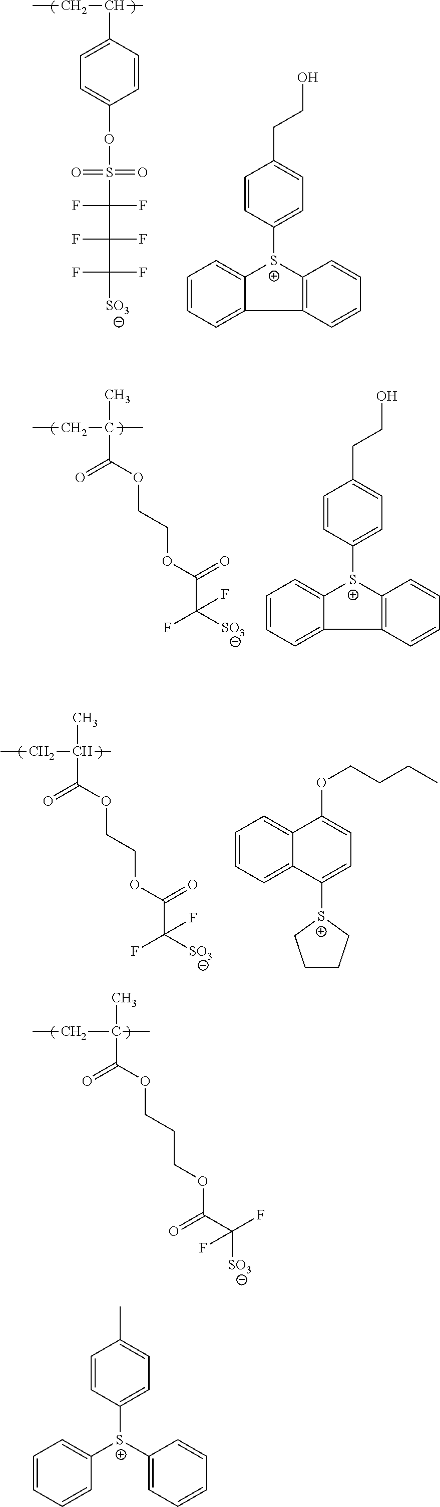

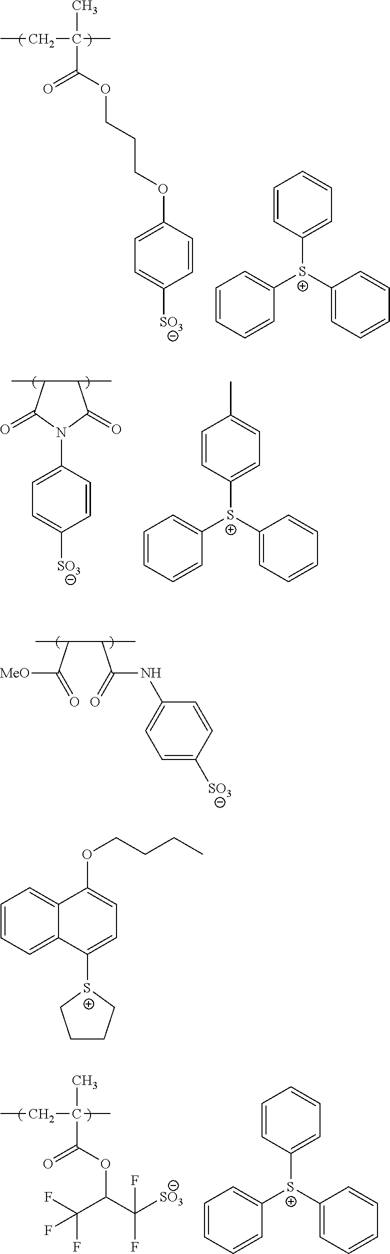

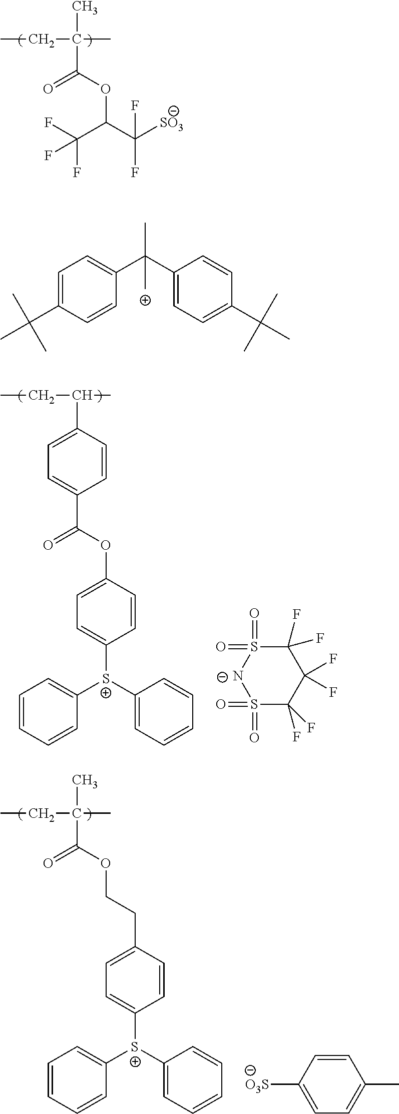

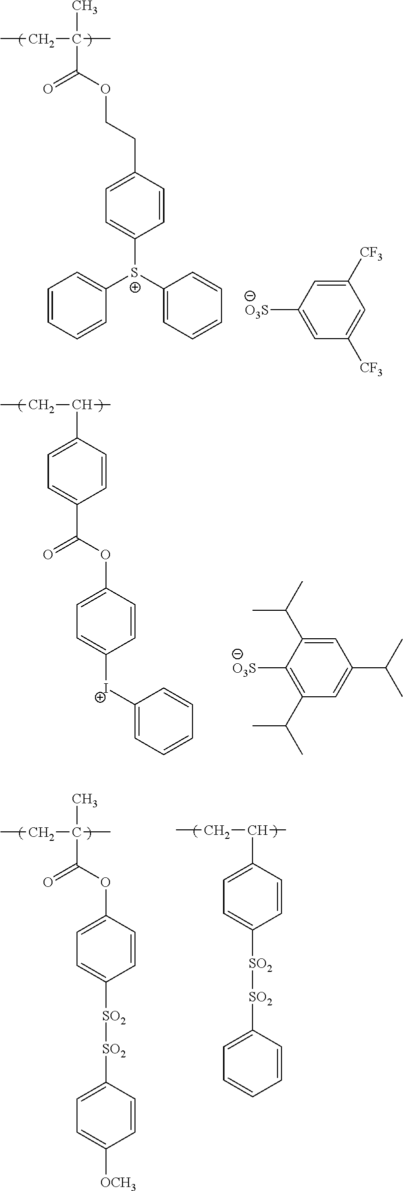

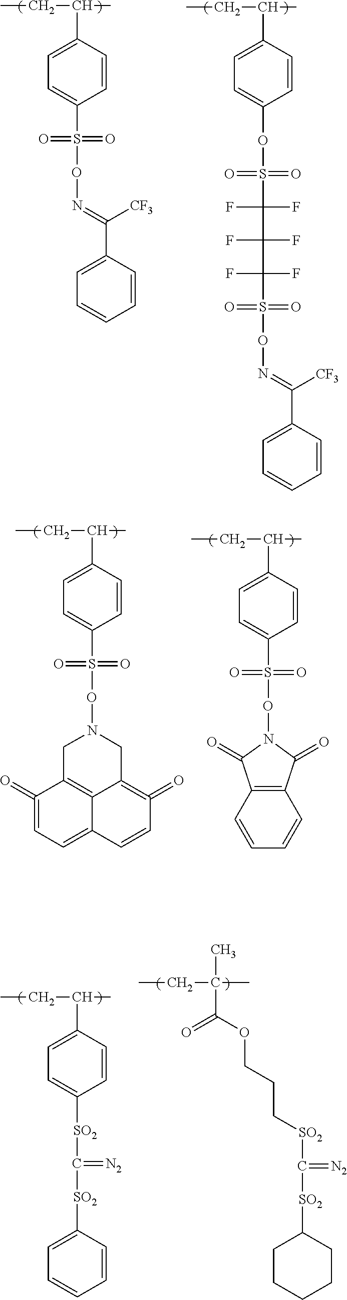

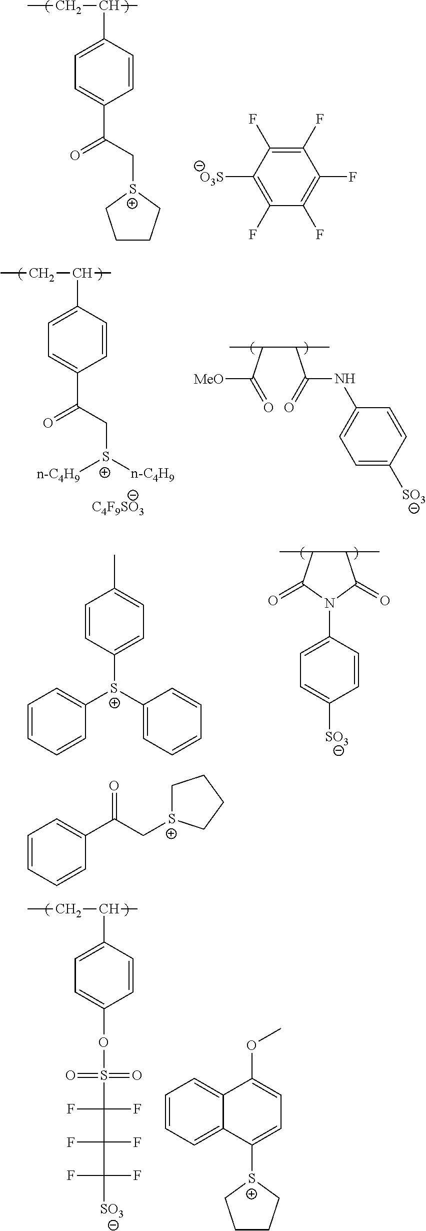

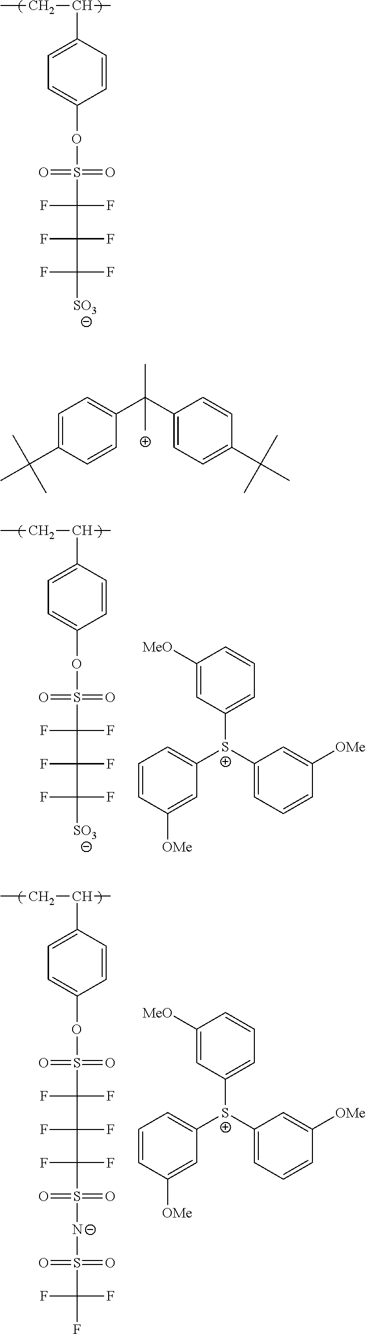

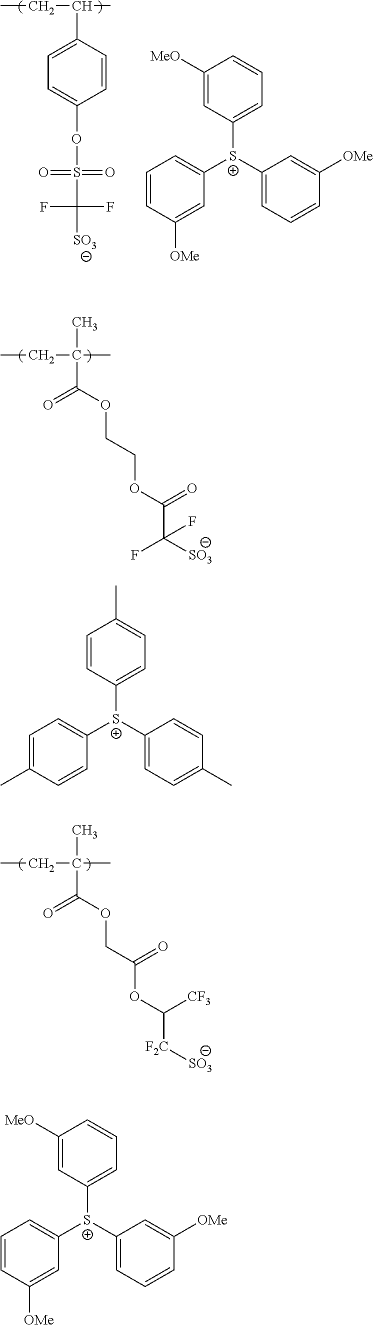

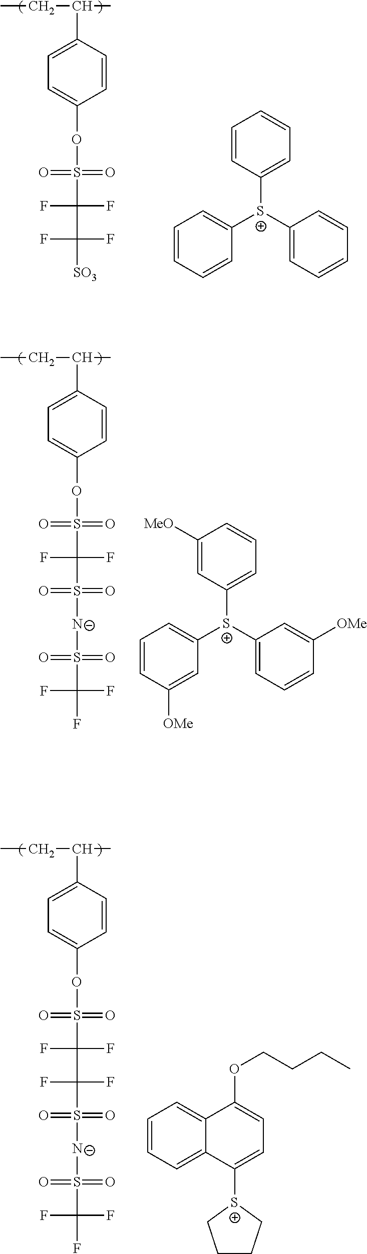

The resin above preferably further contains at least one of a repeating unit represented by the following formula (A1) and a repeating unit represented by the following formula (A2). Here, the repeating unit represented by formula (A2) is a repeating unit other than the repeating unit (A).

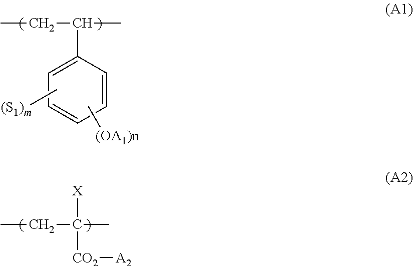

In formula (A1), m represents an integer of 0 to 4. n represents an integer of 1 to 5 satisfying the relationship of m+n≦5. S₁ represents a substituent (excluding hydrogen atom) and when m≧2, each S₁ may be the same as or different from every other S₁. A₁ represents a hydrogen atom or a group capable of leaving by the action of an acid and when n≧2, each A₁ may be the same as or different from every other A₁.

In formula (A2), X represents a hydrogen atom, an alkyl group, a hydroxyl group, an alkoxy group, a halogen atom, a cyano group, a nitro group, an acyl group, an acyloxy group, a cycloalkyl group, a cycloalkyloxy group, an aryl group, a carboxy group, an alkyloxycarbonyl group, an alkylcarbonyloxy group or an aralkyl group. A₂ represents a group capable of leaving by the action of an acid.

The repeating unit represented by formula (A1) is described below.

m represents, as described above, an integer of 0 to 4. m is preferably from 0 to 2, more preferably 0 or 1, still more preferably 0.

n represents, as described above, an integer of 1 to 5 satisfying the relationship of m+n≦5. n is preferably 1 or 2, more preferably 1.

S₁ represents, as described above, a substituent (excluding hydrogen atom). Examples of the substituent are the same as those of the substituent which AR in formula (I) may have.

A₁ represents, as described above, a hydrogen atom or a group capable of leaving by the action of an acid. In the case where A₁ is a group capable of leaving by the action of an acid, the repeating unit represented by formula (A1) is a repeating unit containing an acid-decomposable group. In the case where A₁ is a hydrogen atom, the repeating unit is a repeating unit containing no acid-decomposable group.

Examples of the group capable of leaving by the action of an acid include a tertiary alkyl group such as tert-butyl group and tert-amyl group, a tert-butoxycarbonyl group, a tert-butoxycarbonylmethyl group, and an acetal group represented by —C(L₁)(L₂)—O—Z².

The acetal group represented by —C(L₁)(L₂)—O—Z² is described below. In the formula, each of L₁ and L₂ independently represents a hydrogen atom, an alkyl group, a cycloalkyl group or an aralkyl group. Z² represents an alkyl group, a cycloalkyl group or an aralkyl group. Z² and L₁ may combine with each other to form a 5- or 6-membered ring.

The alkyl group may be a linear alkyl group or a branched alkyl group.

The linear alkyl group is preferably an alkyl group having a carbon number of 1 to 30, more preferably an alkyl group having a carbon number of 1 to 20. Examples of such a linear alkyl group include a methyl group, an ethyl group, an n-propyl group, an n-butyl group, a sec-butyl group, a tert-butyl group, an n-pentyl group, an n-hexyl group, an n-heptyl group, an n-octyl group, an n-nonyl group and an n-decanyl group.

The branched alkyl group is preferably an alkyl group having a carbon number of 3 to 30, more preferably an alkyl group having a carbon number of 3 to 20. Examples of such a branched alkyl group include an i-propyl group, an i-butyl group, a tert-butyl group, an i-pentyl group, a tert-pentyl group, an i-hexyl group, a tert-hexyl group, an i-heptyl group, a tert-heptyl group, an i-octyl group, a tert-octyl group, an i-nonyl group and a tert-decanoyl group.

These alkyl groups may further have a substituent, and examples of the substituent include a hydroxyl group; a halogen atom such as fluorine atom, chlorine atom, bromine atom and iodine atom; a nitro group; a cyano group; an amido group; a sulfonamido group; an alkyl group such as methyl group, ethyl group, propyl group, isopropyl group, n-butyl group, sec-butyl group, hexyl group, 2-ethylhexyl group, octyl group and dodecyl group; an alkoxy group such as methoxy group, ethoxy group, hydroxyethoxy group, propoxy group, hydroxypropoxy group and butoxy group; an alkoxycarbonyl group such as methoxycarbonyl group and ethoxycarbonyl group; an acyl group such as formyl group, acetyl group and benzoyl group; an acyloxy group such as acetoxy group and butyryloxy group; and a carboxy group.

The alkyl group is preferably an ethyl group, an isopropyl group, an isobutyl group, a cyclohexylethyl group, a phenylmethyl group or a phenylethyl group.

The cycloalkyl group may be monocyclic or polycyclic. In the latter case, the cycloalkyl group may be a crosslinked cycloalkyl group. That is, in this case, the cycloalkyl group may have a bridged structure. Incidentally, a part of carbon atoms in the cycloalkyl group may be substituted with a heteroatom such as oxygen atom.

The monocyclic cycloalkyl group is preferably a cycloalkyl group having a carbon number of 3 to 8. Examples of such a cycloalkyl group include a cyclopropyl group, a cyclopentyl group, a cyclohexyl group, a cyclobutyl group and a cyclooctyl group.

The polycyclic cycloalkyl group includes, for example, a group having a bicyclo, tricyclo or tetracyclo structure. The polycyclic cycloalkyl group is preferably a cycloalkyl group having a carbon number of 6 to 20. Examples of such a polycyclic cycloalkyl group include an adamantyl group, a norbornyl group, an isoboronyl group, a camphanyl group, a dicyclopentyl group, an α-pinel group, a tricyclodecanyl group, a tetracyclododecyl group and an androstanyl group.

The aralkyl group in L₁, L₂ and Z² includes, for example, an aralkyl group having a carbon number of 7 to 15, such as benzyl group and phenethyl group.

These aralkyl groups may further have a substituent. Preferred substituents include an alkoxyl group, a hydroxyl group, a halogen atom, a nitro group, an acyl group, an acylamino group, a sulfonylamino group, an alkylthio group, an arylthio group and an aralkylthio group. Examples of the aralkyl group having a substituent include an alkoxybenzyl group, a hydroxybenzyl group and a phenylthiophenethyl group. The carbon number of the substituent which these aralkyl groups may have is preferably 12 or less.

The 5- or 6-membered ring which may be formed by combining Z² and L₁ with each other includes, for example, a tetrahydropyran ring and a tetrahydrofuran ring. Among these, a tetrahydropyran ring is preferred.

Z² is preferably a linear or branched alkyl group. Thanks to this configuration, the effects of the invention are more successfully brought out.

Specific examples of the repeating unit represented by formula (A1) are illustrated blow, but the present invention is not limited thereto.

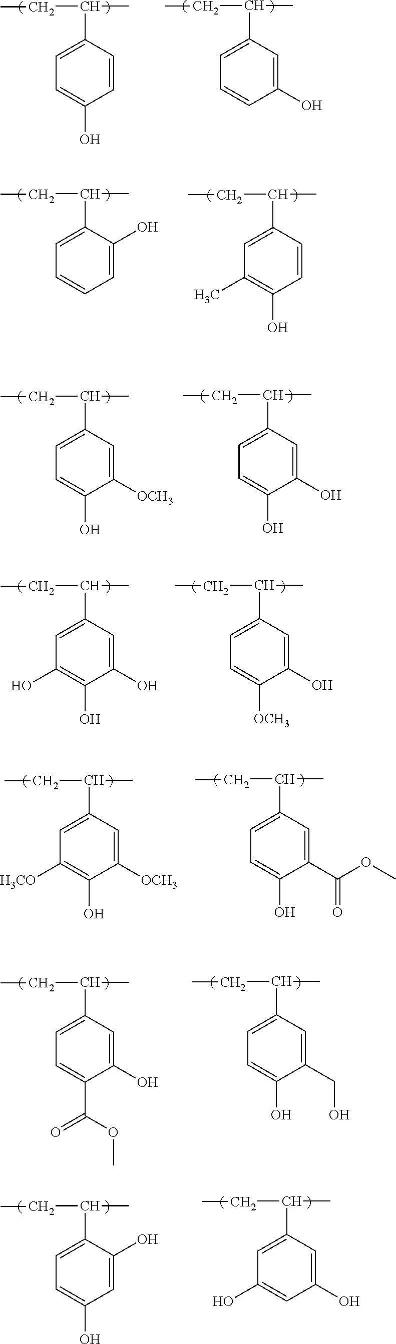

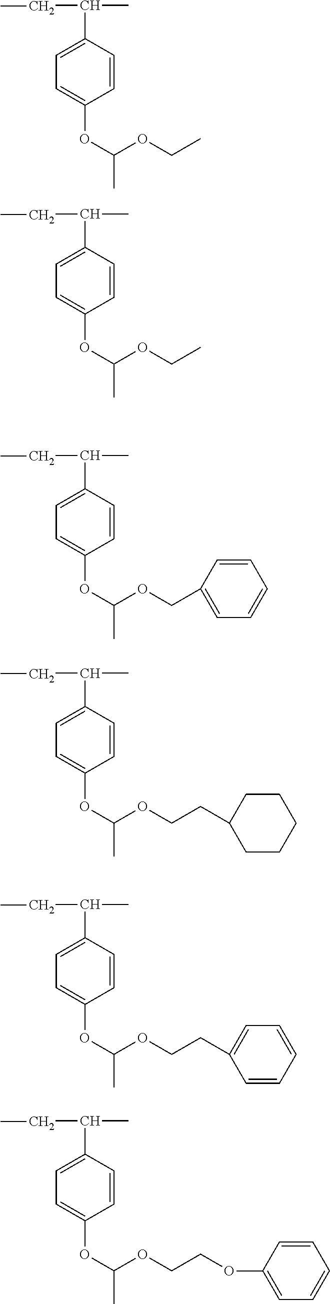

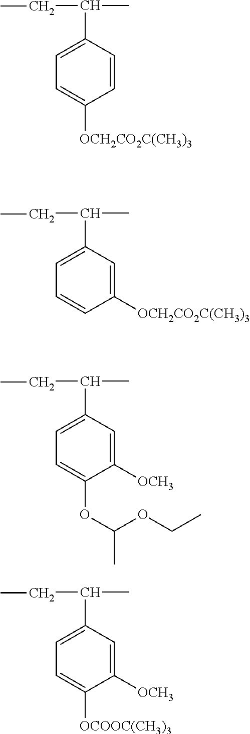

The repeating unit represented by formula (A2) is described below. This repeating unit has, as described later, an acid-decomposable group.

X represents, as described above, a hydrogen atom, an alkyl group, a hydroxyl group, an alkoxy group, a halogen atom, a cyano group, a nitro group, an acyl group, an acyloxy group, a cycloalkyl group, a cycloalkyloxy group, an aryl group, a carboxy group, an alkyloxycarbonyl group, an alkylcarbonyloxy group or an aralkyl group. Specific examples of these groups or atoms are the same as those described above for R₁ in formula (I).

A₂ represents, as described above, a group capable of leaving by the action of an acid. That is, the repeating unit represented by (A2) has a group represented by “—COOA₂” as an acid-decomposable group. Examples of A₂ are the same as those described above for A₁ in formula (A1).

Specific examples of the monomer corresponding to the repeating unit represented by formula (A2) are illustrated below, but the present invention is not limited thereto.

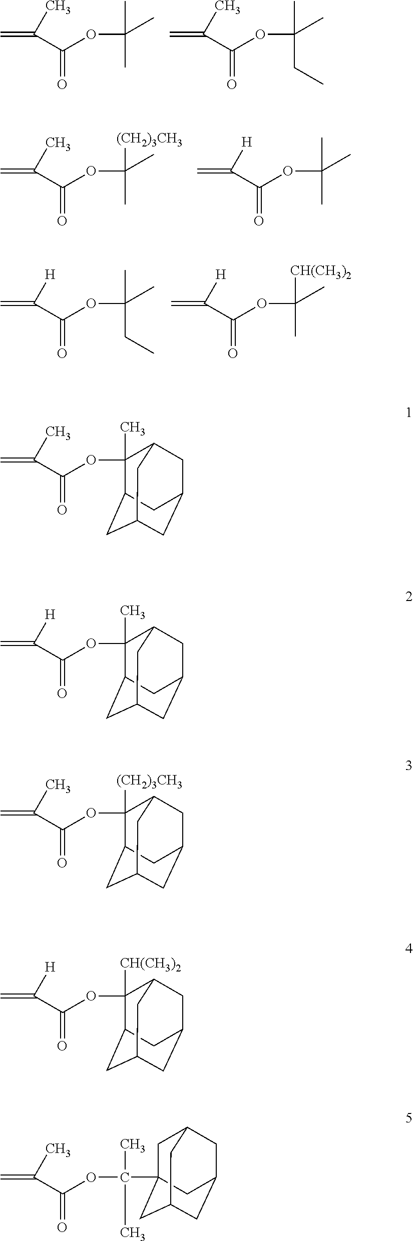

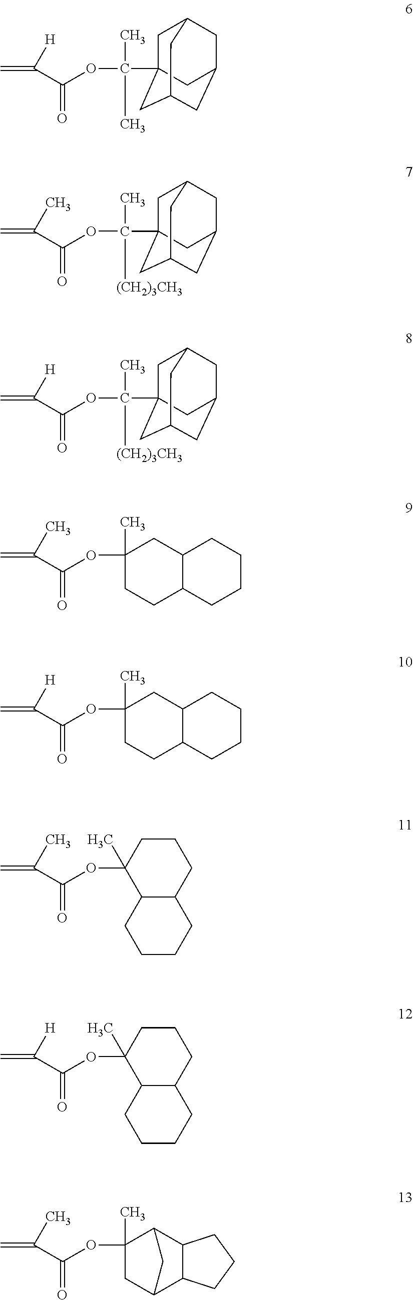

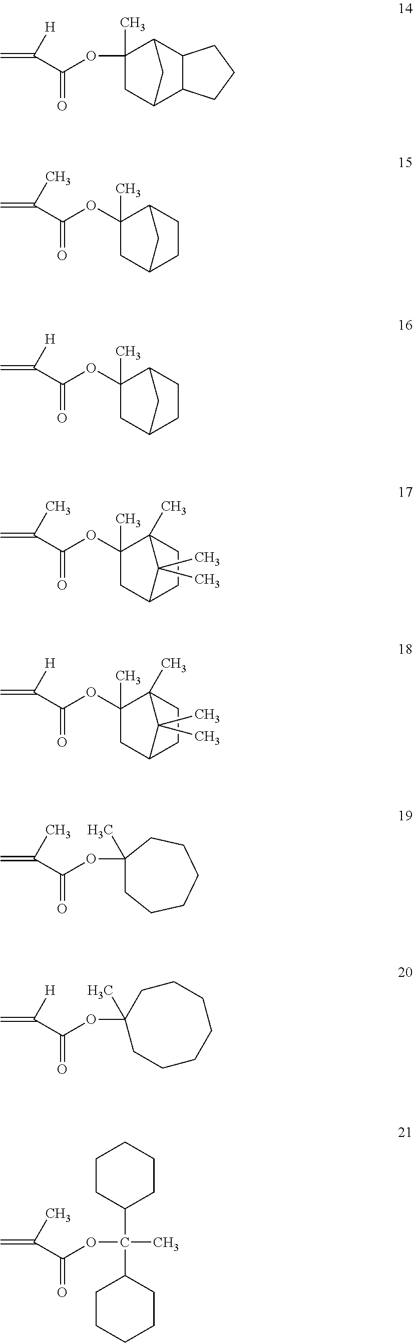

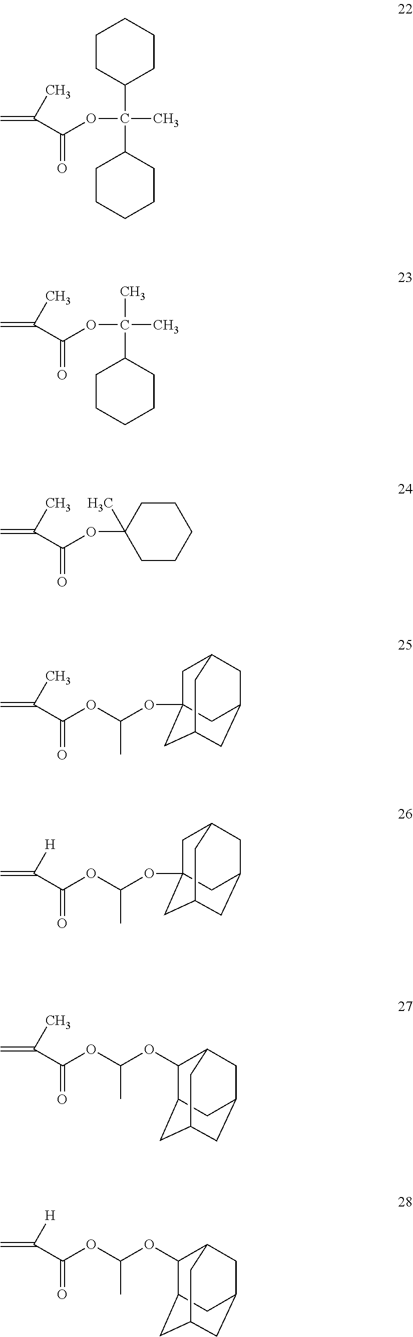

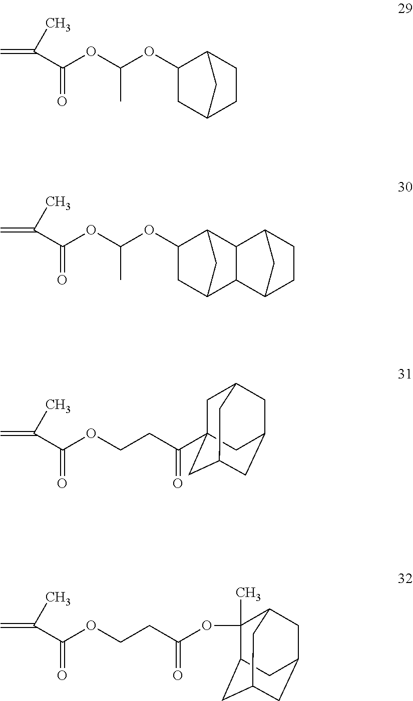

Specific examples of the structure for the repeating unit represented by formula (A2) are illustrated below, but the present invention is not limited thereto.

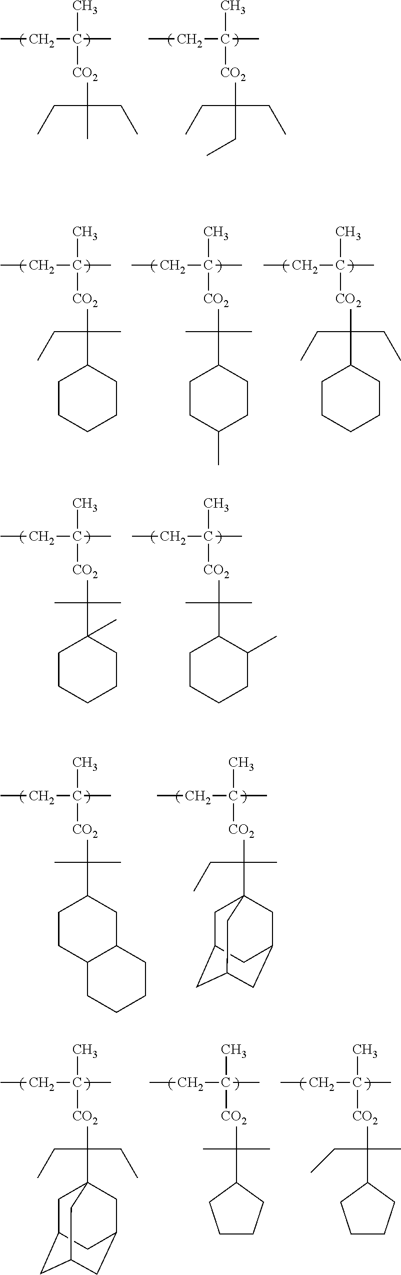

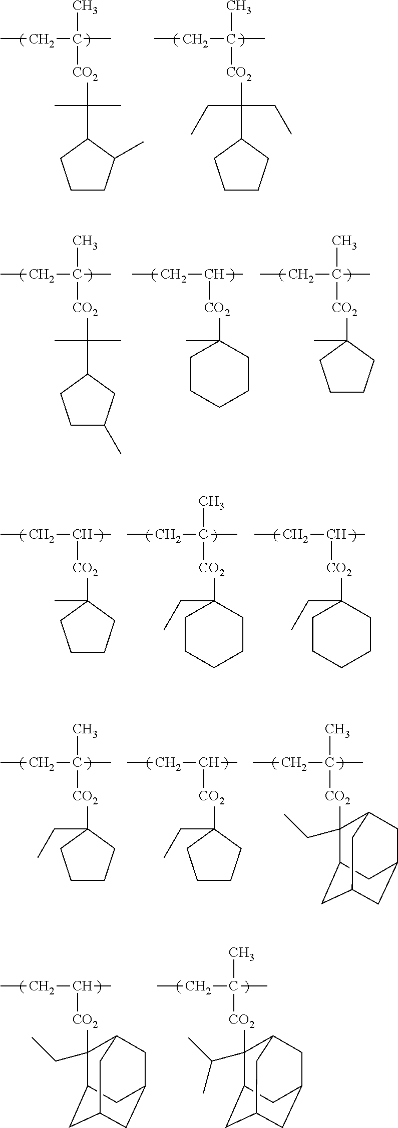

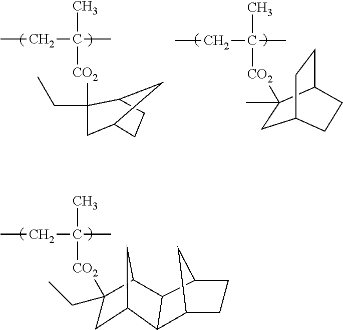

The repeating unit represented by formula (A2) is preferably a repeating unit of tert-butyl methacrylate or ethylcyclopentyl methacrylate.

The resin above preferably further contains a repeating unit represented by the following formula (A4), in addition to the repeating unit (A) and the repeating unit (B). When such a configuration is employed, it becomes possible, for example, to more enhance the film quality and more suppress the film loss in the unexposed area.

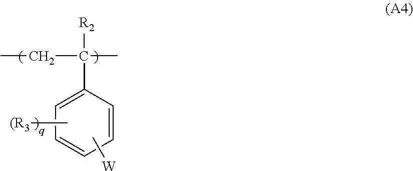

In formula (A4), R₂ represents a hydrogen atom, a methyl group, a cyano group, a halogen atom or a perfluoro group having a carbon number of 1 to 4. R₃ represents a hydrogen atom, an alkyl group, a cycloalkyl group, a halogen atom, an aryl group, an alkoxy group or an acyl group. q represents an integer of 0 to 4. W represents a group incapable of decomposing by the action of an acid (hereinafter, sometimes referred to as an “acid-stable group”).

The acid-stable group of W is preferably an acyl group, an alkylamide group, an alkylcarbonyloxy group, an alkyloxy group, a cycloalkyloxy group or an aryloxy group, more preferably an acyl group, an alkylcarbonyloxy group, an alkyloxy group, a cycloalkyloxy group or an aryloxy group.

The alkyl group of W is preferably an alkyl group having a carbon number of 1 to 4, such as methyl group, ethyl group, propyl group, n-butyl group, sec-butyl group and tert-butyl group.

The cycloalkyl group of W is preferably a cycloalkyl group having a carbon number of 3 to 10, such as cyclopropyl group, cyclobutyl group, cyclohexyl group and adamantyl group.

The alkenyl group of W is preferably an alkenyl group having a carbon number of 2 to 4, such as vinyl group, propenyl group, allyl group and butenyl group.

The aryl group of W is preferably an aryl group having a carbon number of 6 to 14, such as phenyl group, xylyl group, toluoyl group, cumenyl group, naphthyl group and anthryl group.

Examples of the alkyl group in the acyl group, alkylamide group, alkylcarbonyloxy group and alkyloxy group of W are the same as those described above for the alkyl group or W.

Examples of the cycloalkyl group in the cycloalkyloxy group of W are the same as those described above for the cycloalkyl group of W.

Examples of the aryloxy group, arylamidomethyl group and arylamide group of W are the same as those described above for the aryl group of W.

As shown in formula (A4), W may be substituted for an arbitrary hydrogen atom contained in the benzene ring of the styrene structure. The position on which W is substituted is not particularly limited but is preferably the meta-position or para-position, more preferably the para-position.

Specific examples of the repeating unit represented by formula (A4) are illustrated below, but the present invention is not limited thereto.

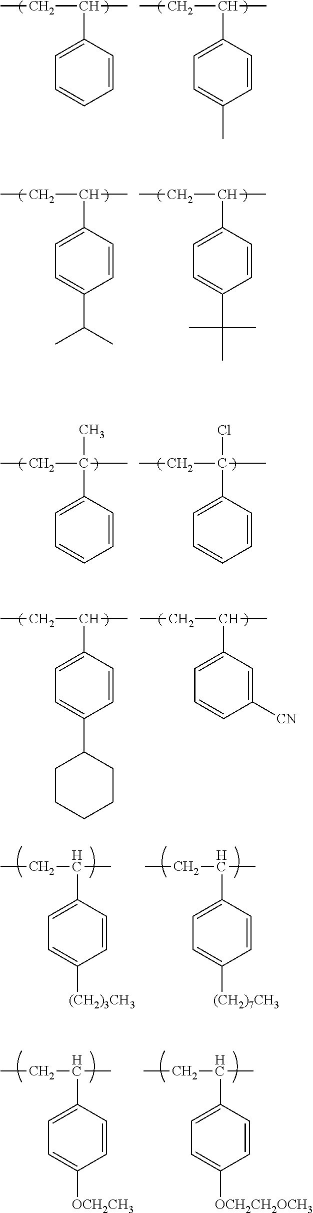

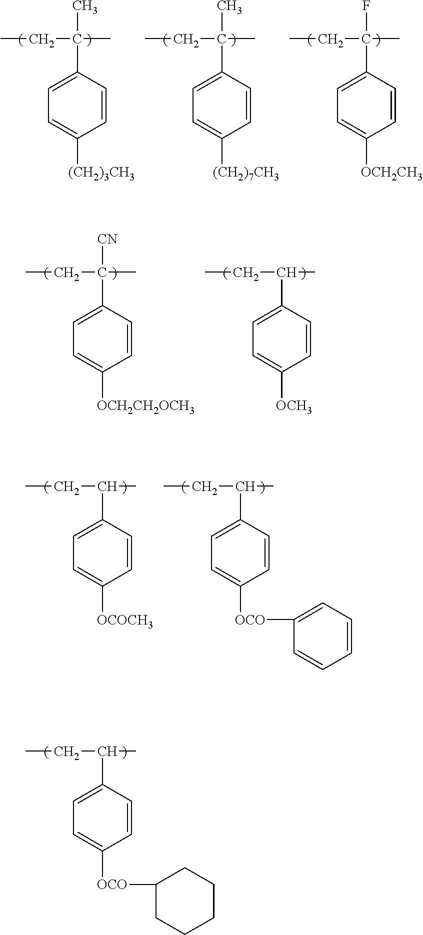

The resin above may further contain a repeating unit represented by any of the following formulae (a1) to (a5), in addition to the repeating unit (A) and the repeating unit (B).

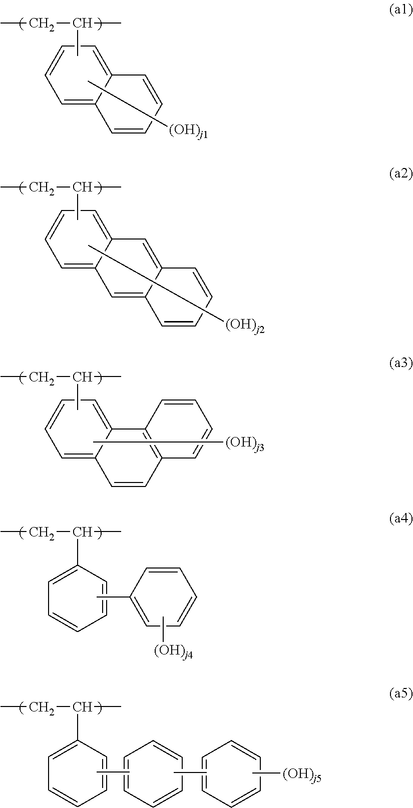

Each of j1, j2, j3, j4 and j5 independently represents an integer of 0 to 3.

Each of j1, j2, j3, j4 and j5 independently represents preferably an integer of 0 to 2, more preferably 0 or 1.

Specific examples of the repeating unit represented by any of formulae (a1) to (a5) are illustrated below, but the present invention is not limited thereto.

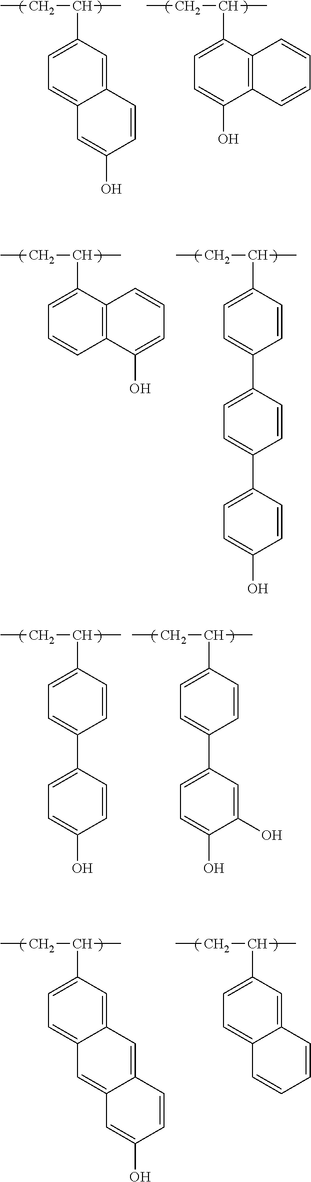

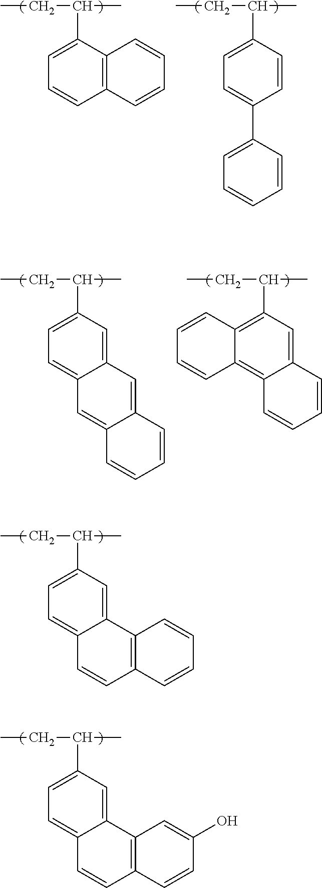

The resin above may further contain a repeating unit composed of a (meth)acrylic acid derivative incapable of decomposing by the action of an acid, in addition to the repeating unit (A) and the repeating unit (B). Specific examples thereof are illustrated below, but the present invention is not limited thereto.

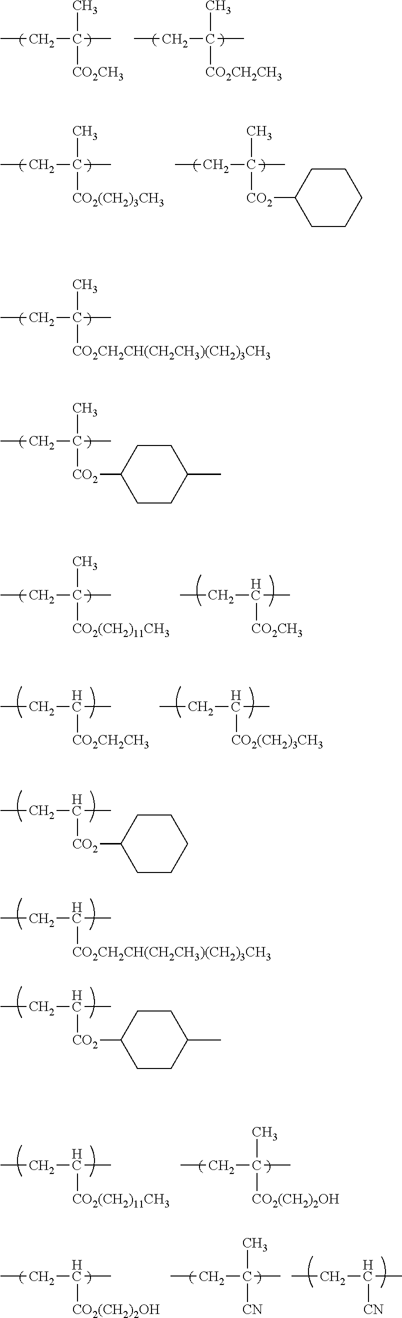

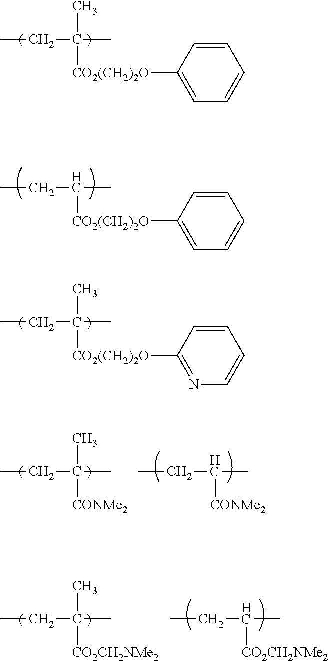

The resin above may further contain a repeating unit having an acid-decomposable group, represented by the formula —C(═O)—X₁—Rₒ, in addition to the repeating unit (A) and the repeating unit (B). In the formula, X₁ represents an oxygen atom, a sulfur atom, —NH—, —NHSO₂— or —NHSO₂NH—. Rₒ is a group capable of leaving by the action of an acid, and examples thereof include a tertiary alkyl group such as tert-butyl group and tert-amyl group, an isoboronyl group, a 1-alkoxyethyl group such as 1-ethoxyethyl group, 1-butoxyethyl group, 1-isobutoxyethyl group and 1-cyclohexyloxyethyl group, an alkoxymethyl group such as 1-methoxymethyl group and 1-ethoxymethyl group, a 3-oxoalkyl group, a tetrahydropyranyl group, a tetrahydrofuranyl group, a trialkylsilyl ester group, a 3-oxocyclohexyl ester group, a 2-methyl-2-adamantyl group, and a mevalonic lactone residue.

Also, the resin above may further contain a repeating unit having a group capable of decomposing by the action of an alkali developer to increase the dissolution rate in an alkali developer.

Examples of the group capable of decomposing by the action of an alkali developer to increase the dissolution rate in an alkali developer include a lactone structure and a phenyl ester structure.

The repeating unit is preferably a repeating unit represented by the following formula (AII):

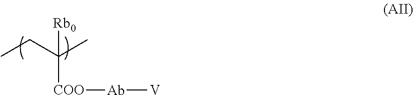

In formula (AII), Rb₀ represents a hydrogen atom, a halogen atom or an alkyl group (preferably having a carbon number of 1 to 4) which may have a substituent.

Preferred substituents which the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, more preferably a hydrogen atom or a methyl group.

Ab represents a single bond, an alkylene group, a divalent linking group having a monocyclic or polycyclic aliphatic hydrocarbon ring structure, an ether group, an ester group, a carbonyl group, or a divalent linking group formed by a combination thereof and is preferably a single bond or a divalent linking group represented by -Ab₁-CO₂—.

Ab₁ represents a linear or branched alkylene group or a monocyclic or polycyclic aliphatic hydrocarbon ring group and is preferably a methylene group, an ethylene group, a cyclohexylene group, an adamantylene group or a norbornylene group.

V represents a group capable of decomposing by the action of an alkali developer to increase the dissolution rate in an alkali developer and is preferably a group having an ester bond, more preferably a group having a lactone structure.

As for the group having a lactone structure, any group may be used as long as it has a lactone structure, but a 5- to 7-membered ring lactone structure is preferred, and a 5- to 7-membered ring lactone structure to which another ring structure is fused to form a bicyclo structure or a Spiro structure is preferred. V is more preferably a group having a lactone structure represented by any of the following formulae (LC1-1) to (LC1-17). Also, the resin may further contain a repeating unit where a lactone structure is bonded directly to the main chain. Preferred lactone structures are (LC1-1), (LC1-4), (LC1-5), (LC1-6), (LC1-13) and (LC1-14).

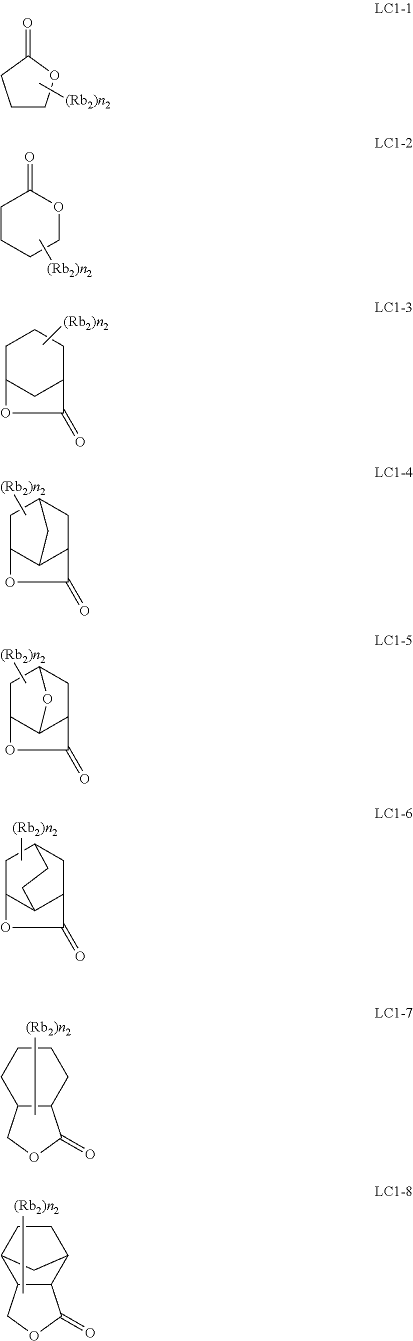

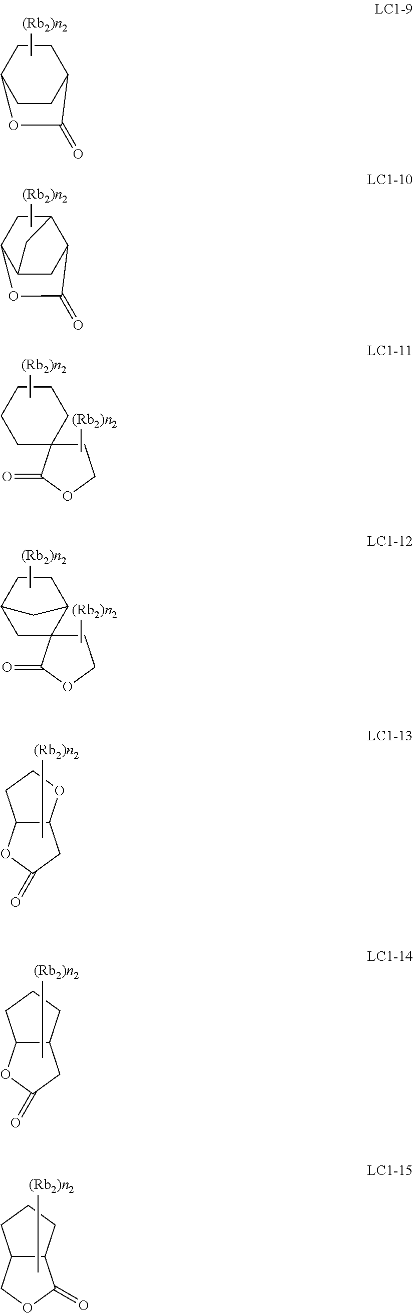

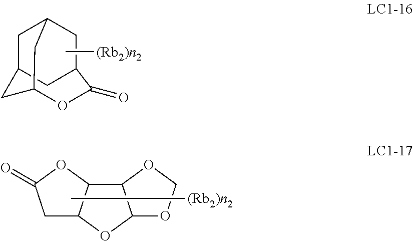

The lactone structure moiety may or may not have a substituent (Rb₂). Preferred examples of the substituent (Rb₂) include an alkyl group having a carbon number of 1 to 8, a monovalent aliphatic hydrocarbon ring group having a carbon number of 4 to 7, an alkoxy group having a carbon number of 1 to 8, an alkoxycarbonyl group having a carbon number of 1 to 8, a carboxy group, a halogen atom, a hydroxyl group, a cyano group and an acid-decomposable group. Among these, an alkyl group having a carbon number of 1 to 4, a cyano group and an acid-decomposable group are more preferred. n₂ represents an integer of 0 to 4. When n₂ is 2 or more, each substituent (Rb₂) may be the same as or different from every other substituents Rb₂. Also, the plurality of substituents (Rb₂) may combine with each other to form a ring.

The repeating unit having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more, more preferably 95% or more.

Specific examples of the repeating unit (D) in the resin are illustrated below, but the present invention is not limited thereto. In the formulae, Rx represents H, CH₃, CH₂OH or CF₃.

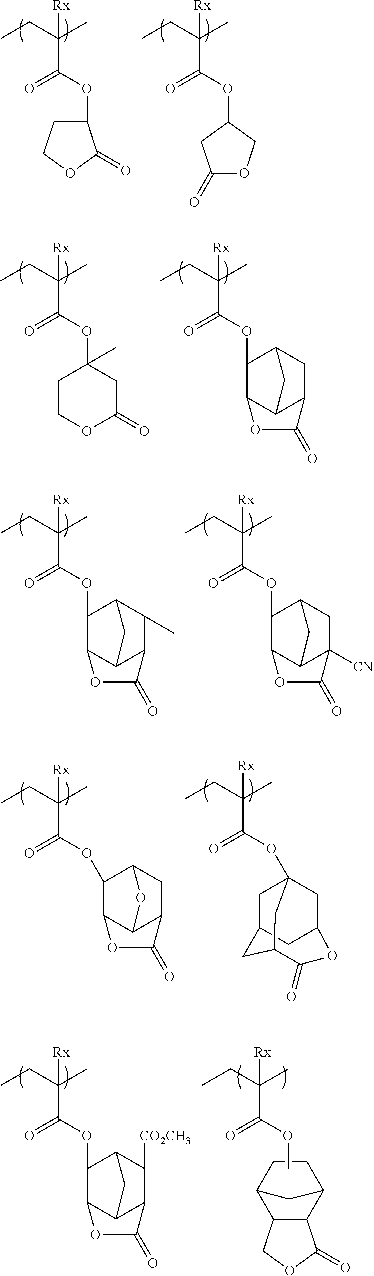

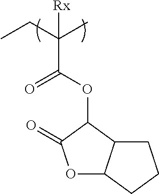

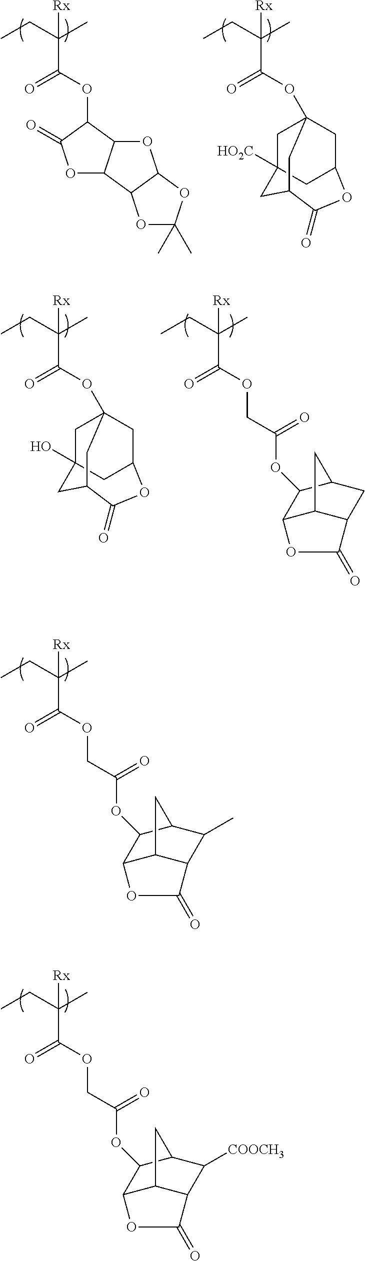

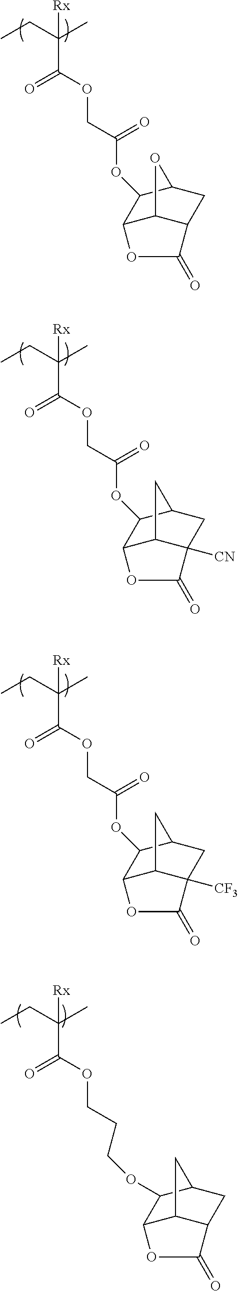

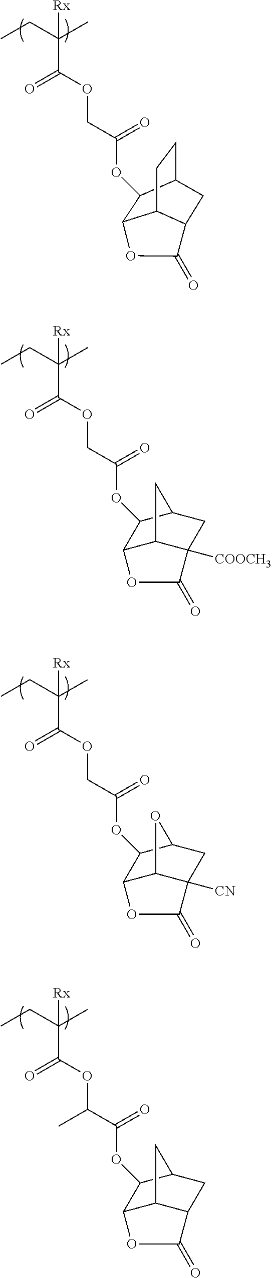

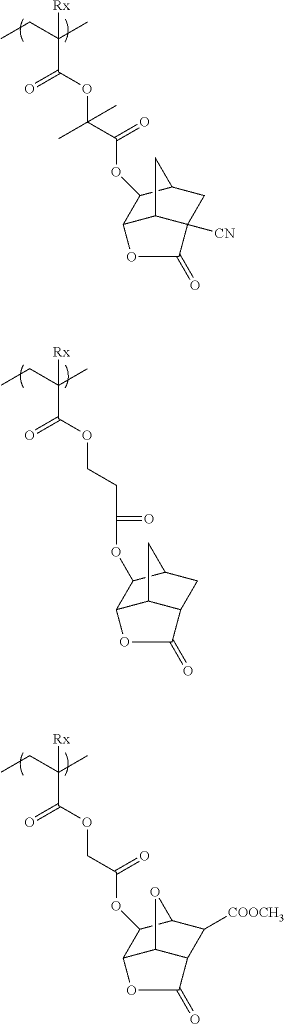

In order to maintain good developability for an alkali developer, the resin above may further contain another repeating unit having an alkali-soluble group such as phenolic hydroxyl group and carboxy group. Also, for more enhancing the film quality, the resin may further contain a hydrophobic repeating unit obtained from a monomer such as alkyl acrylate and alkyl methacrylate.

### [Other Repeating Units]

The resin (P) may further contain a repeating unit having a polar group-containing group, which is a repeating unit other than the repeating units described above. Examples of the polar group include a hydroxyl group, a cyano group, a carboxyl group, a sulfonylimide group, a bissulfonylimide group, and an alcoholic hydroxyl group (hexafluoroisopropanol group. —C(CF₃)₂OH)) with the α-position being substituted with an electron-withdrawing group. Thanks to this repeating unit contained in the resin (P), the adherence to substrate and the affinity for developer can be enhanced. The polar group-containing repeating unit other than the repeating units described above is preferably a repeating unit having a hydroxyl group or a cyano group, more preferably a repeating unit having an alicyclic hydrocarbon structure substituted with a hydroxyl group or a cyano group, and it is still more preferred to contain no acid-decomposable group. The alicyclic hydrocarbon structure in the alicyclic hydrocarbon structure substituted with a hydroxyl group or a cyano group is preferably an adamantyl group, a diamantyl group or a norbornane group. The alicyclic hydrocarbon structure substituted with a hydroxyl group or a cyano group is preferably a partial structure represented by the following formulae (VIIa) to (VIId):

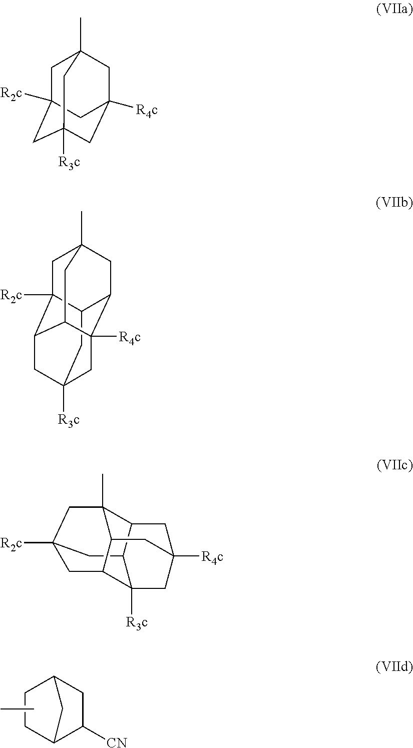

In formulae (VIIa) to (VIIc), each of R₂c to R₄c independently represents a hydrogen atom, a hydroxyl group or a cyano group, provided that at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (Ana) to (AIId):

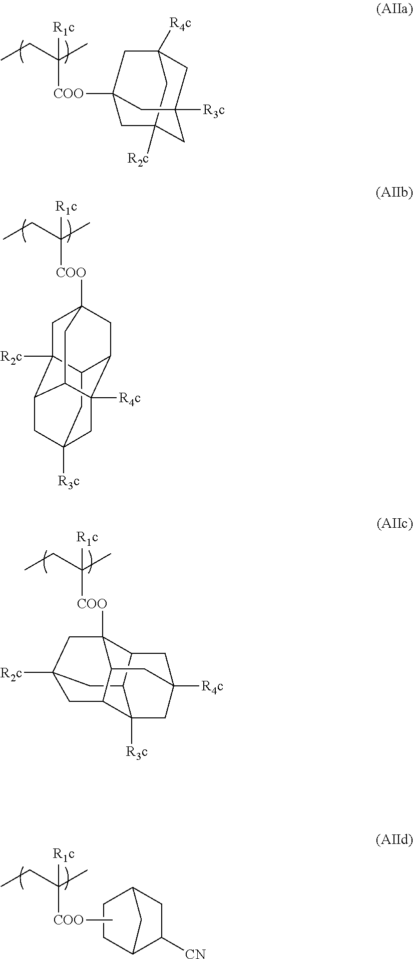

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc). The resin (P) may or may not contain a polar group-containing repeating unit but in the case of containing the repeating unit, the content thereof is preferably from 1 to 60 mol %, more preferably from 5 to 50 mol %, based on all repeating units in the resin (P).

Specific examples of the polar group-containing repeating unit are illustrated below, but the present invention is not limited thereto.

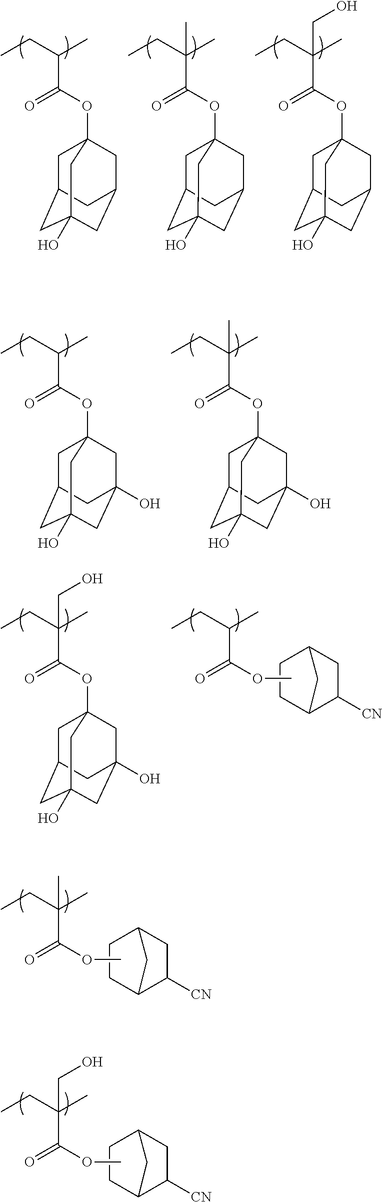

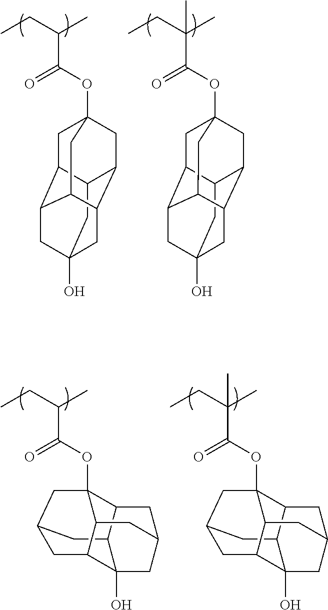

The resin (P) for use in the present invention may further contain a repeating unit having a polar group-free cyclic hydrocarbon structure and not exhibiting acid decomposability. Such a repeating unit includes a repeating unit represented by formula (VII):

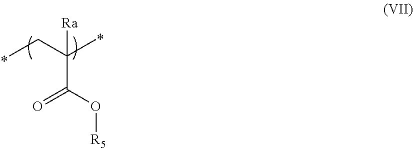

In formula (VII), R₅ represents a hydrocarbon group having at least one cyclic hydrocarbon structure and having no polar group (e.g., hydroxyl group, cyano group).

Ra represents a hydrogen atom, an alkyl group or a —CH₂—O—Ra₂ group, wherein Ra₂ represents a hydrogen atom, an alkyl group or an acyl group. Ra is preferably a hydrogen atom, a methyl group, a hydroxymethyl group or a trifluoromethyl group, more preferably a hydrogen atom or a methyl group.

The cyclic hydrocarbon structure contained in R₅ includes a monocyclic hydrocarbon group and a polycyclic hydrocarbon group. The monocyclic hydrocarbon group is preferably a monocyclic hydrocarbon group having a carbon number of 3 to 7, more preferably a cyclopentyl group or cyclohexyl group.

The polycyclic hydrocarbon group includes a ring assembly hydrocarbon group and a crosslinked cyclic hydrocarbon group. Preferred examples of the crosslinked cyclic hydrocarbon ring include a norbornyl group, an adamantyl group, a bicyclooctanyl group and a tricyclo[5,2,1,0^{2,6}]decanyl group. Among these crosslinked cyclic hydrocarbon rings, a norbornyl group and an adamantyl group are more preferred.

These cyclic hydrocarbon groups may have a substituent, and preferred substituents include a halogen atom (bromine, chlorine, fluorine) and an alkyl group (methyl, ethyl, butyl, tert-butyl group). This alkyl group may further have a substituent, and the substituent which the alkyl group may further have includes a halogen atom, an alkyl group, a hydroxyl group with the hydrogen atom being substituted for, and an amino group with the hydrogen atom being substituted for.

Examples of the substituent substituting for the hydrogen atom include an alkyl group, a monovalent aliphatic hydrocarbon ring group, an aralkyl group, a substituted methyl group, a substituted ethyl group, an alkoxycarbonyl group and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group includes, for example, an alkoxycarbonyl group having a carbon number of 1 to 4. The resin (P) may or may not contain a repeating unit having a polar group-free cyclic hydrocarbon structure and not exhibiting acid decomposability, but in the case of containing the repeating unit, the content thereof is preferably from 1 to 40 mol %, more preferably from 5 to 20 mol %, based on all repeating units in the resin (P).

Specific examples of the repeating unit having a polar group-free cyclic hydrocarbon structure and not exhibiting acid decomposability are illustrated below, but the present invention is not limited thereto. In the formulae, Ra represents H, CH₃, CH₂OH or CF₃.

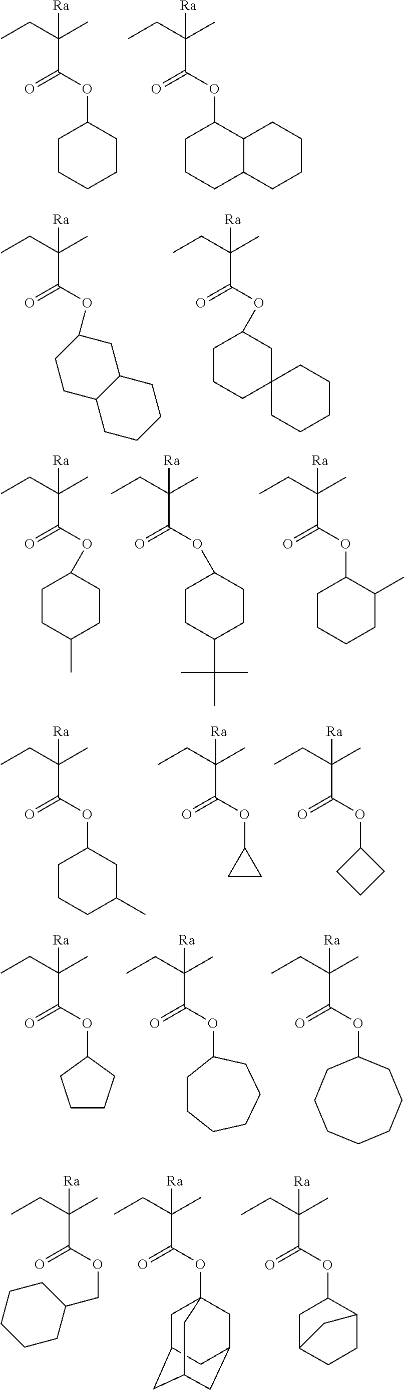

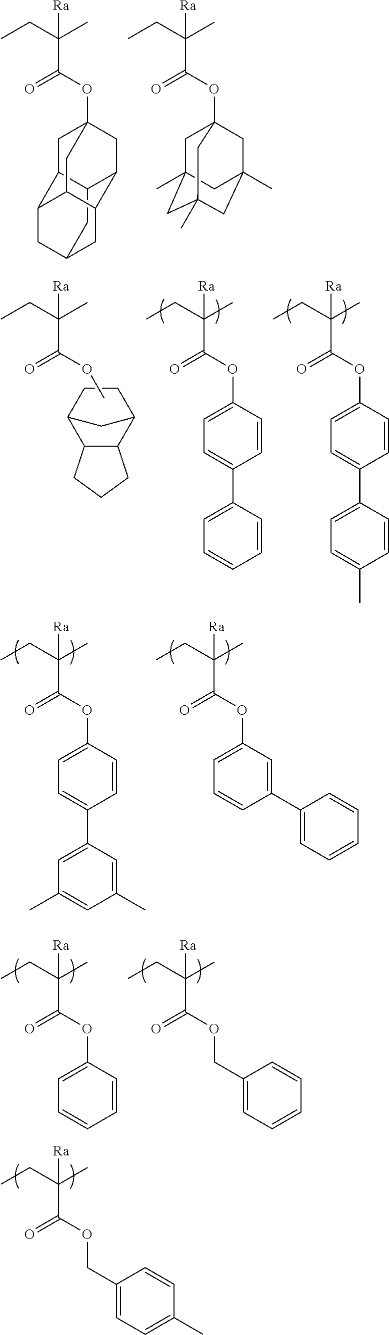

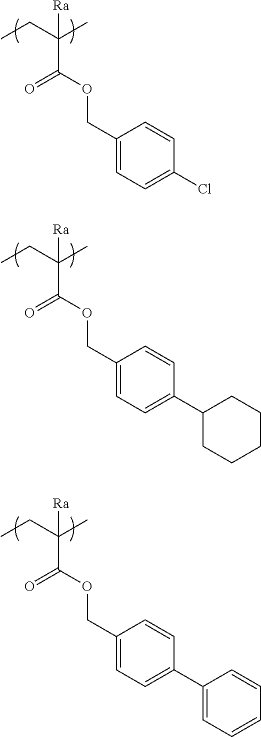

The resin (P) for use in the present invention may contain, in addition to the above-described repeating structural units, various repeating structural units for the purpose of controlling the dry etching resistance, suitability for standard developer, adherence to substrate, resist profile and properties generally required of a resist, such as resolution, heat resistance and sensitivity.

Examples of such a repeating structural unit include, but are not limited to, repeating structural units corresponding to the monomers described below.

Thanks to such a repeating structural unit, the performance required of the resin used in the composition of the present invention, particularly

(1) solubility in the coating solvent,

(2) film-forming property (glass transition point),

(3) alkali developability,

(4) film loss (selection of hydrophilic, hydrophobic or alkali-soluble group),

(5) adherence of unexposed area to substrate,

(6) dry etching resistance,

and the like, can be subtly controlled.

Examples of this monomer include a compound having one addition-polymerizable unsaturated bond selected from acrylic acid esters, methacrylic acid esters, acrylamides, methacrylamides, allyl compounds, vinyl ethers and vinyl esters, styrenes, and crotonic acid esters. Other examples include maleic anhydride, maleimide, acrylonitrile, methacrylonitrile and maleylonitrile.

Furthermore, an addition-polymerizable unsaturated compound copolymerizable with the monomers corresponding to the above-described various repeating structural units may be copolymerized.

Specific preferred examples of the repeating unit derived from such other polymerizable monomers are illustrated below, but the present invention is not limited thereto.

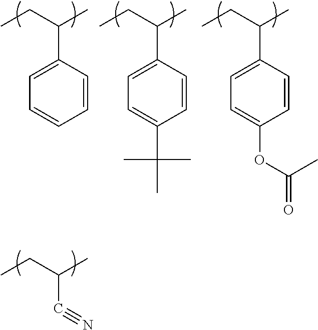

In the resin (P) for use in the composition of the present invention, the molar ratio of respective repeating structural units contained is appropriately determined to control the dry etching resistance of resist, suitability for standard developer, adherence to substrate, resist profile and performances generally required of a resist, such as resolution, heat resistance and sensitivity.

The content of the acid-decomposable group-containing repeating unit occupying in the resin is preferably from 5 to 95 mol %, more preferably from 10 to 60 mol %, still more preferably from 15 to 50 mol %, based on all repeating units.

The content of the repeating unit (A) occupying in the resin is preferably from 1 to 70 mol %, more preferably from 1 to 50 mol %, still more preferably from 1 to 40 mol %, based on all repeating units.

The content of the repeating unit (B) occupying in the resin is preferably from 0.1 to 80 mol %, more preferably from 0.5 to 60 mol %, still more preferably from 1 to 40 mol %, based on all repeating units.

In the case where the resin above contains a repeating unit represented by formula (A1), the content thereof is preferably from 20 to 90 mol %, more preferably from 30 to 85 mol %, still more preferably from 35 to 80 mol %, based on all repeating units.

In the case where the resin above contains a repeating unit represented by formula (A2), the content thereof is preferably from 1 to 90 mol %, more preferably from 5 to 75 mol %, still more preferably from 10 to 60 mol %, based on all repeating units.

In the case where the resin above contains a repeating unit represented by formula (A4), the content thereof is preferably from 1 to 50 mol %, more preferably from 1 to 40 mol %, still more preferably from 1 to 30 mol %, based on all repeating units.

In the case where the resin above contains a repeating unit represented by any of formulae (a1) to (a5), the content thereof is preferably from 1 to 50 mol %, more preferably from 1 to 40 mol %, still more preferably from 1 to 30 mol %, based on all repeating units.

In the case where the resin above contains a repeating unit having a group capable of decomposing by the action of an alkali developer to increase the dissolution rate in an alkali developer, the content thereof is preferably from 0.5 to 80 mol %, more preferably from 1 to 60 mol %, still more preferably from 2 to 40 mol %, based on all repeating units in the resin.

The weight average molecular weight (Mw) of the resin is preferably from 1,000 to 200,000, more preferably from 1,000 to 100,000, still more preferably from 1,000 to 50,000, yet still more preferably from 1,000 to 25,000. If the weight average molecular weight is excessively large, the dissolution rate of the resin for an alkali and the sensitivity of the composition are sometimes decreased. Here, the “weight average molecular weight” indicates the value in terms of polystyrene as determined by gel permeation chromatography (GPC).

The polydispersity (Mw/Mn) of the resin is preferably from 1.0 to 3.0, more preferably from 1.0 to 2.5, still more preferably from 1.0 to 2.0.

The resin having a high polydispersity can be synthesized, for example, as follows. That is, a resin having, for example, a polydispersity of 1.2 to 2.0 can be synthesized by performing radical polymerization using an azo-based polymerization initiator, and a resin having, for example, a polydispersity of 1.0 to 1.5 can be synthesized by employing a living polymerization method.

As for the resin above, one kind of a resin may be used alone, or two or more kinds of resins may be used in combination. The total amount of these resins is usually from 10 to 99 mass %, preferably from 20 to 99 mass %, more preferably from 30 to 99 mass %, based on the entire solid content of the composition.

Specific examples of the containing a repeating unit (A) and a repeating unit (B) are illustrated below, but the present invention is not limited thereto.

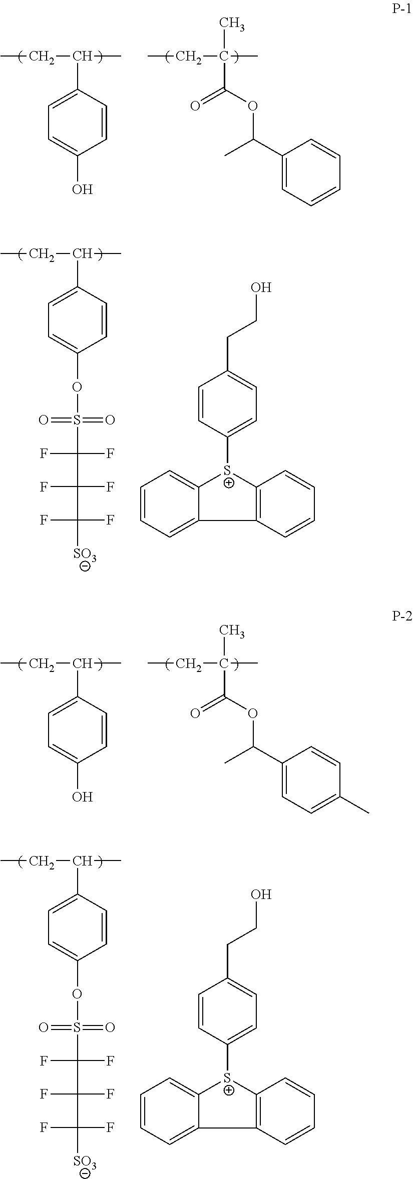

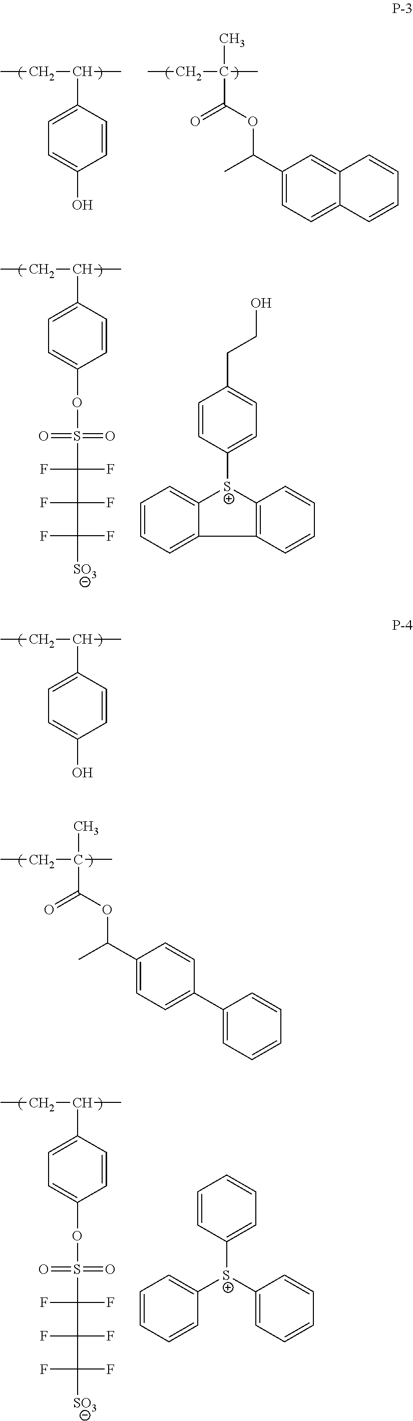

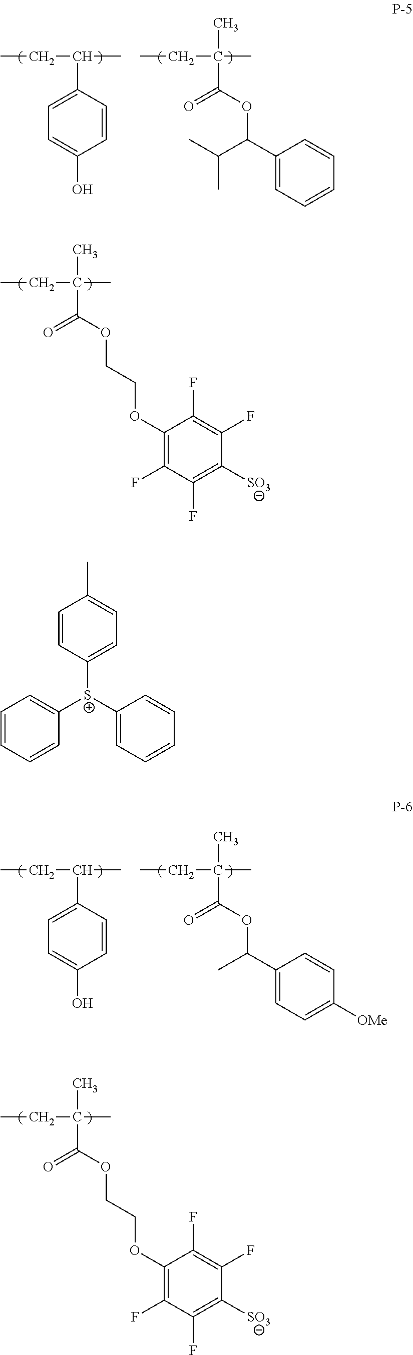

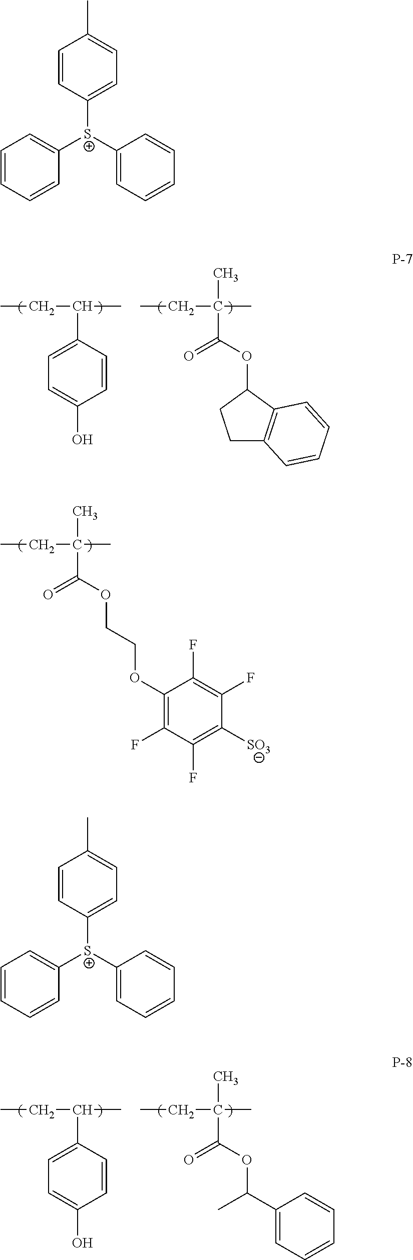

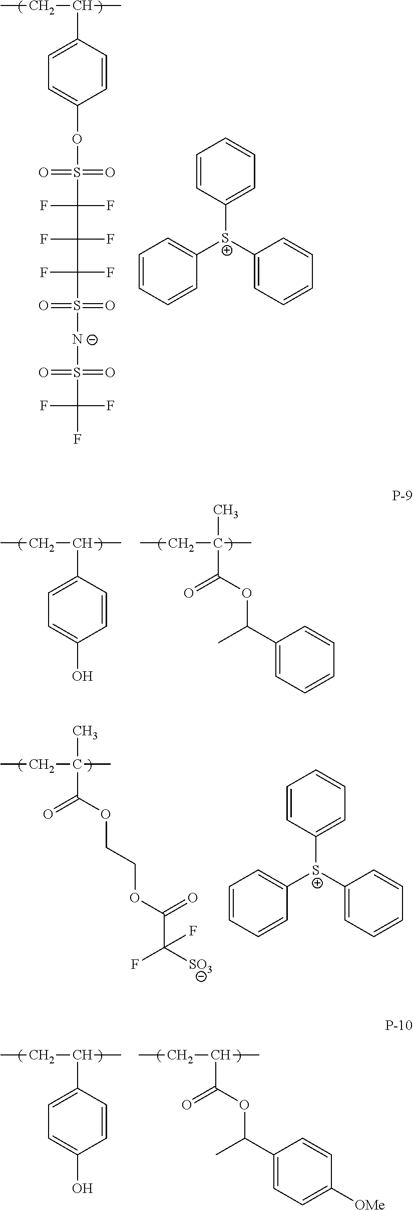

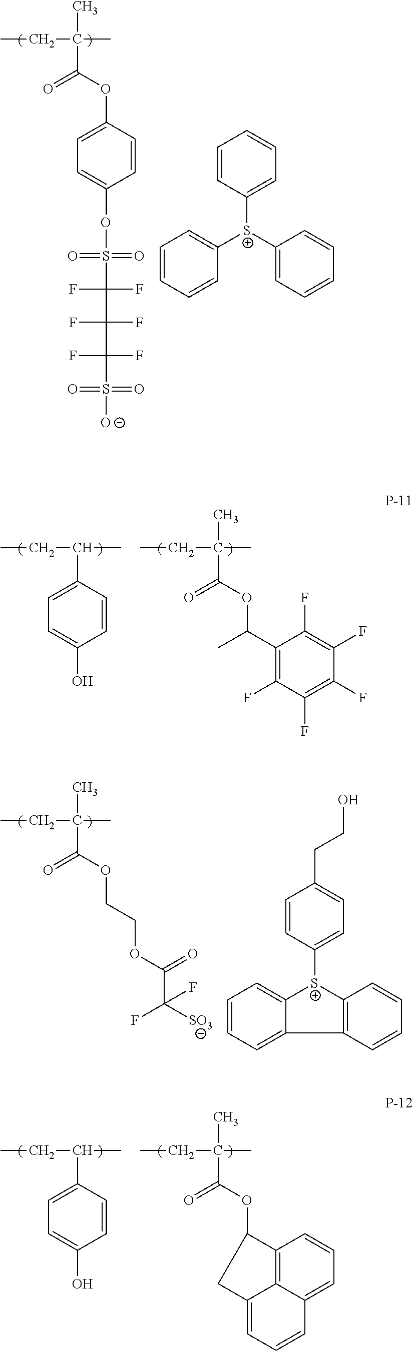

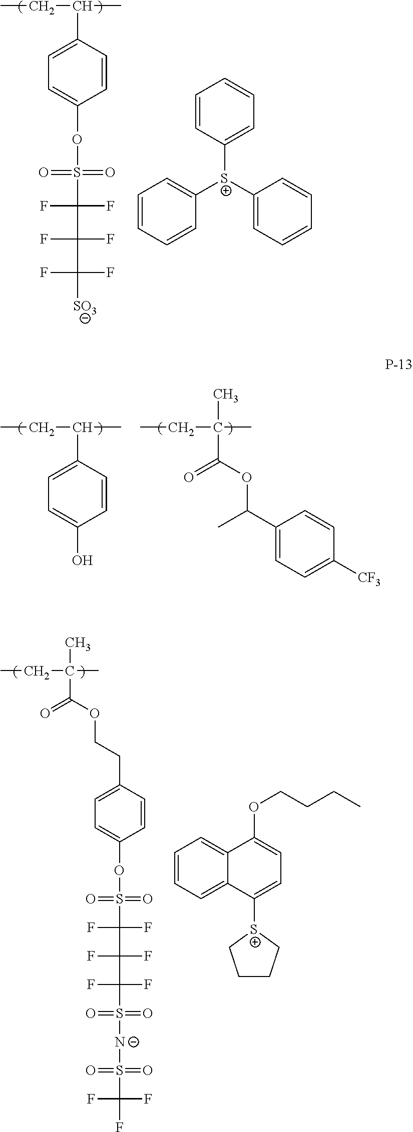

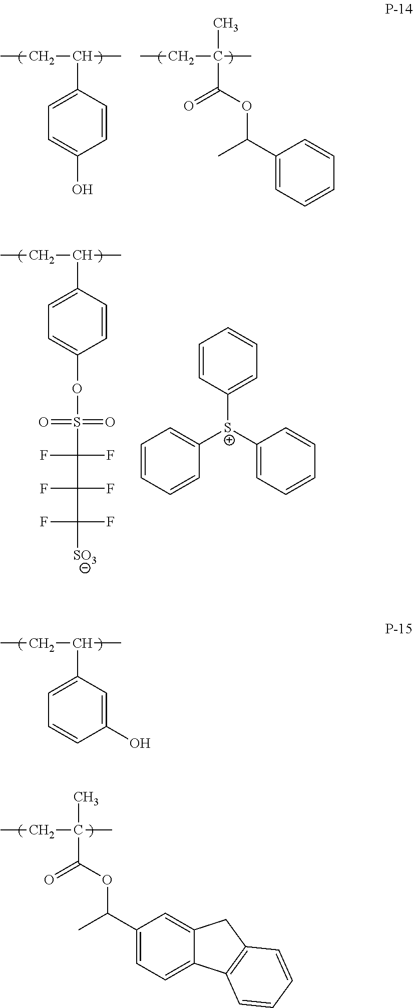

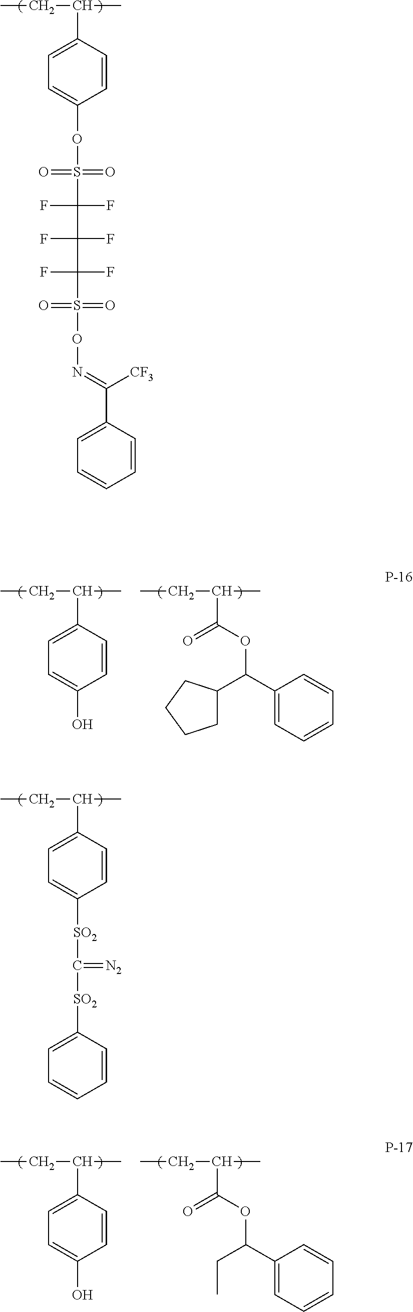

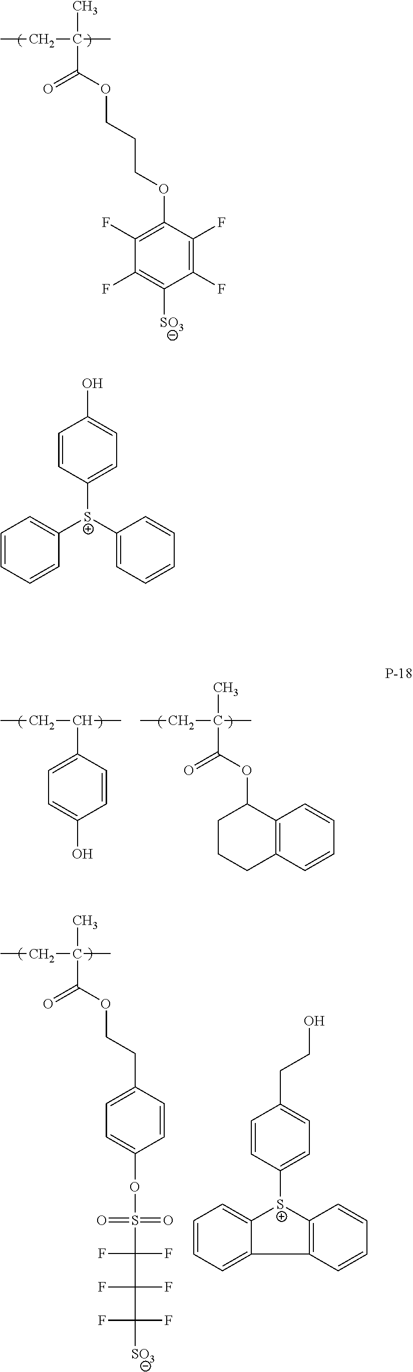

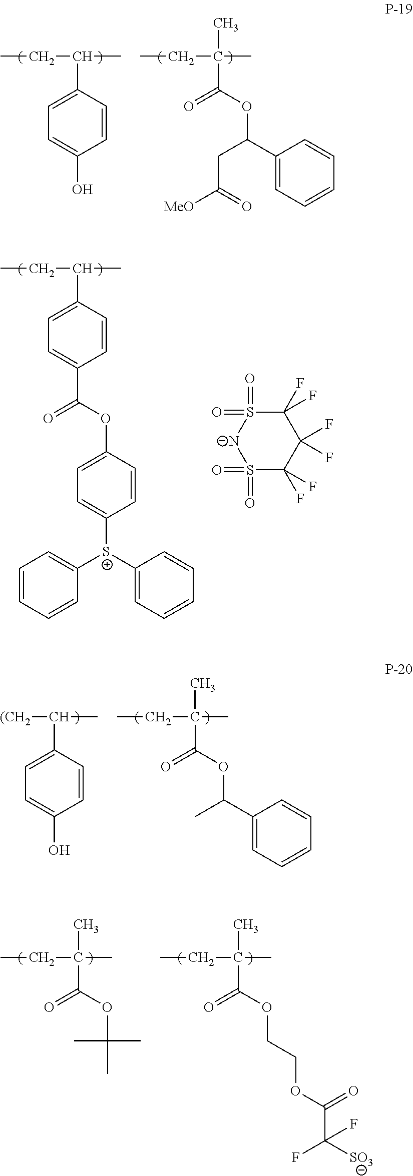

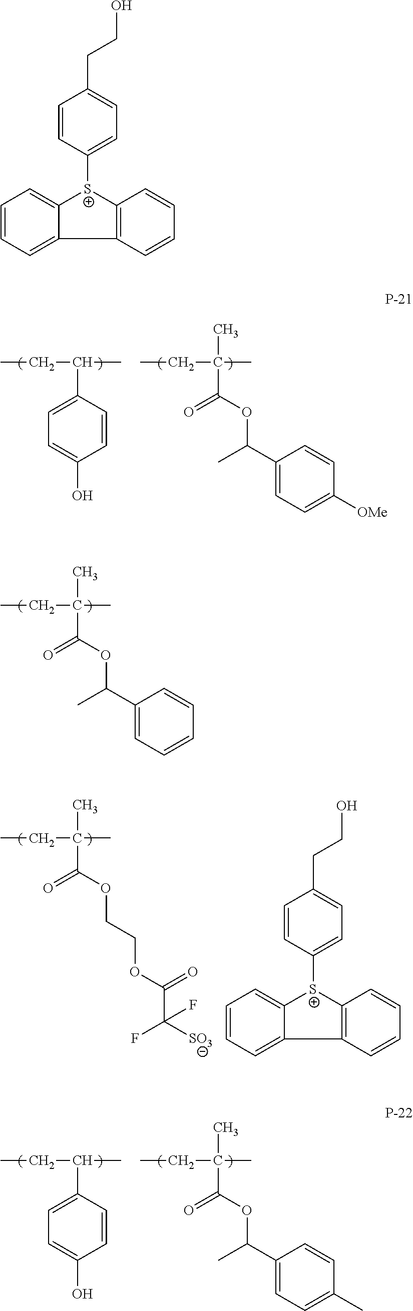

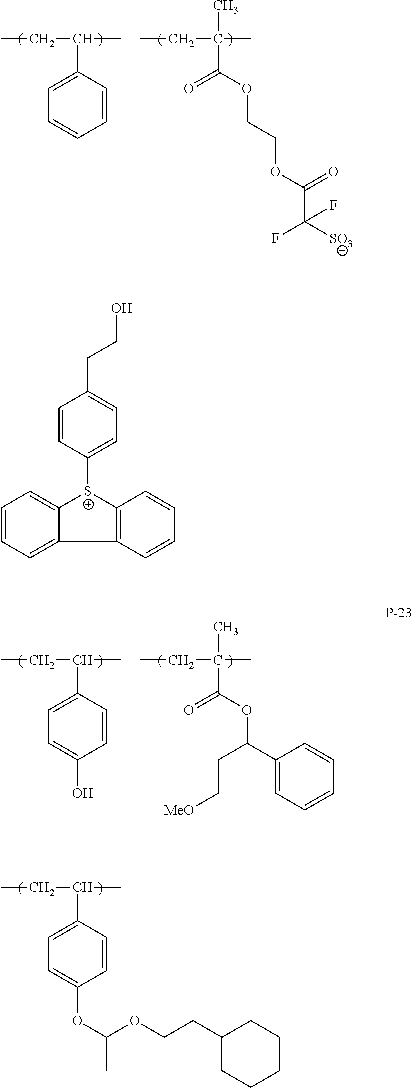

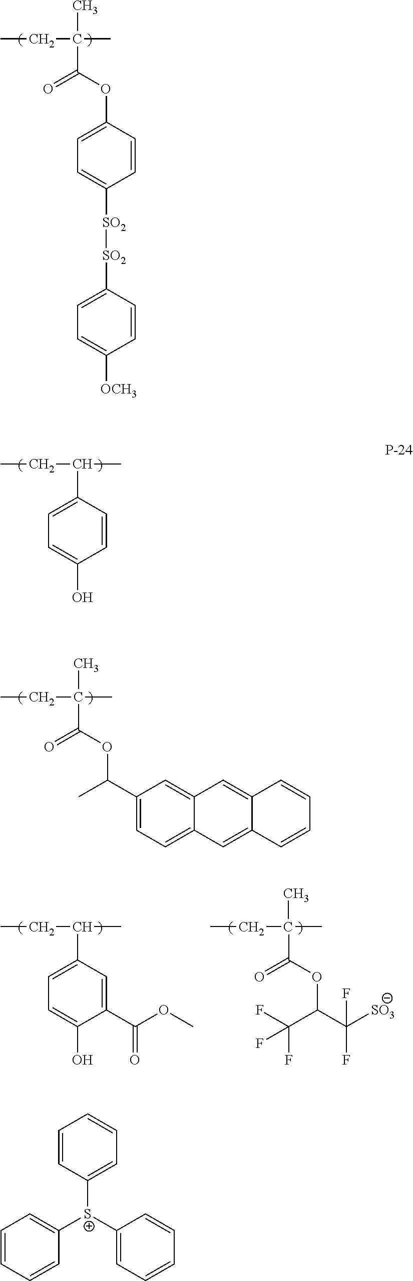

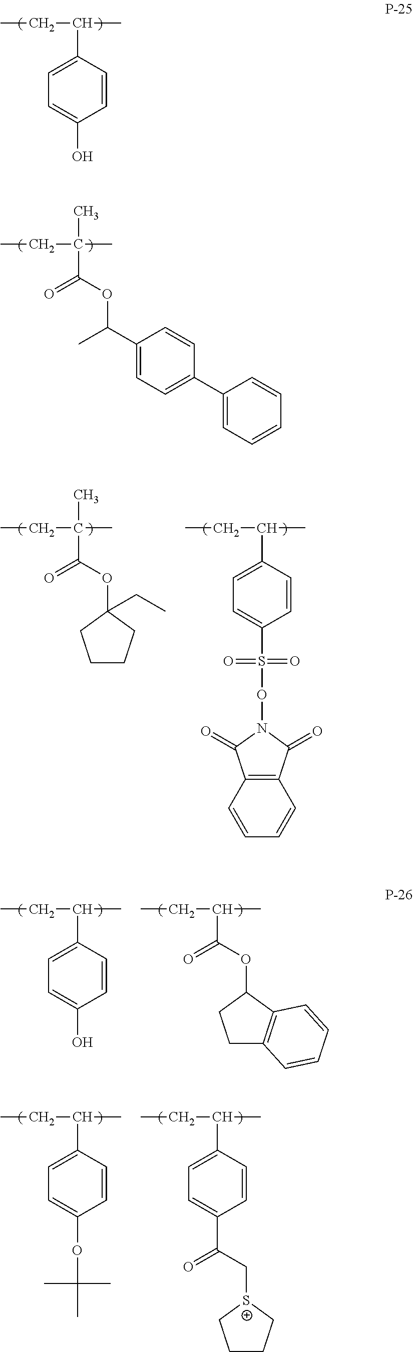

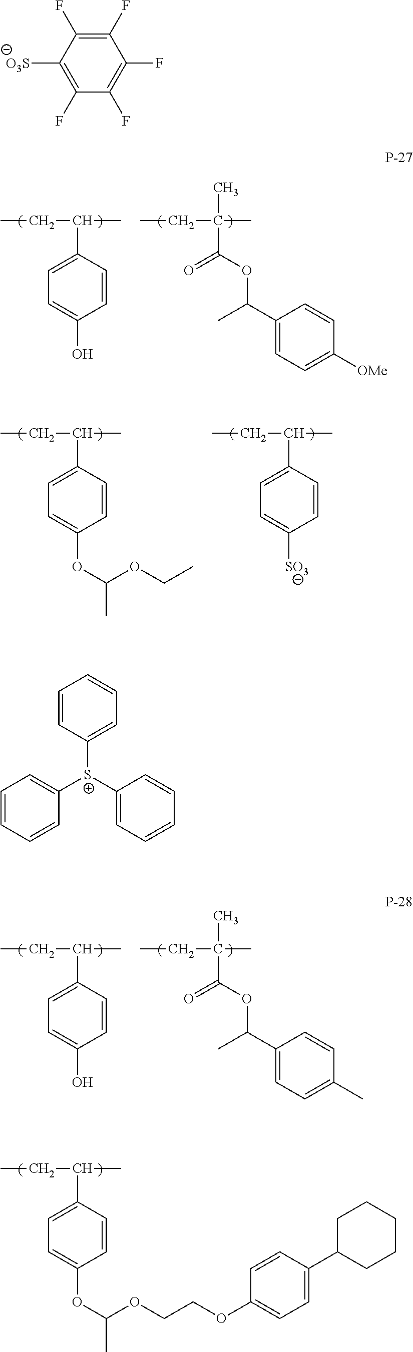

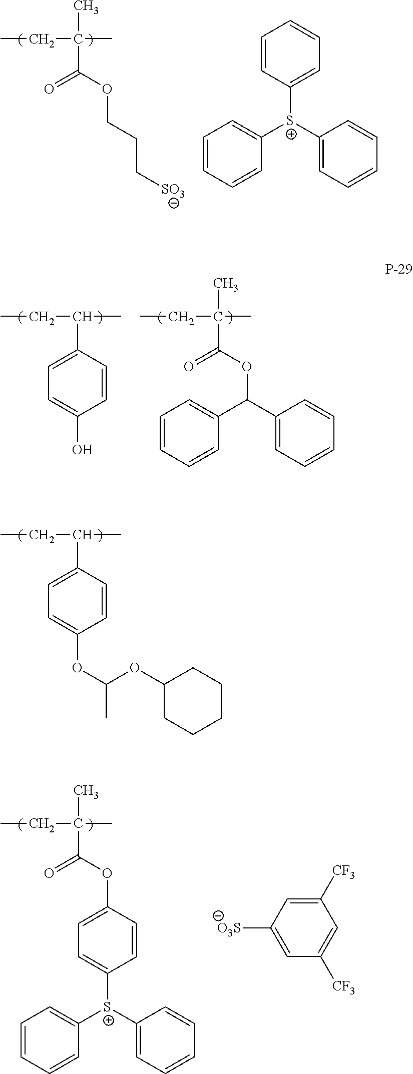

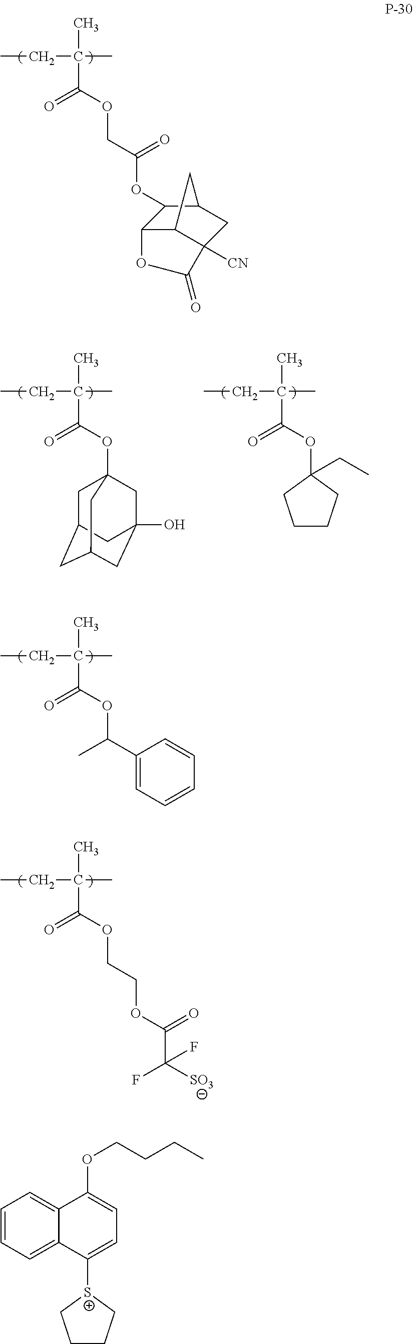

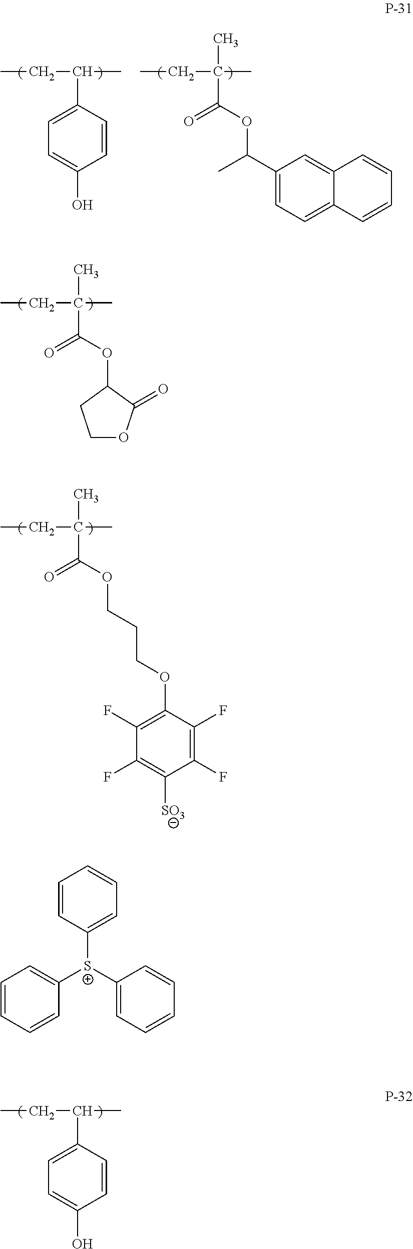

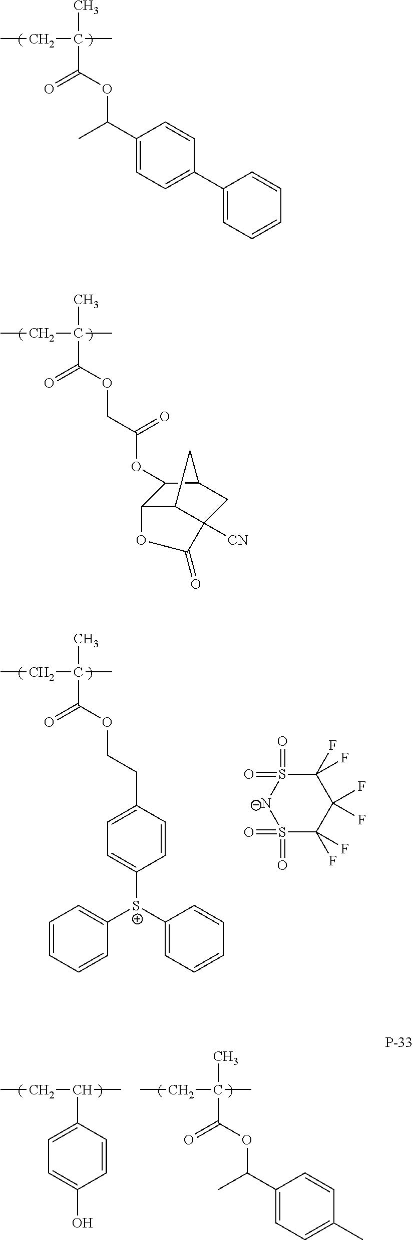

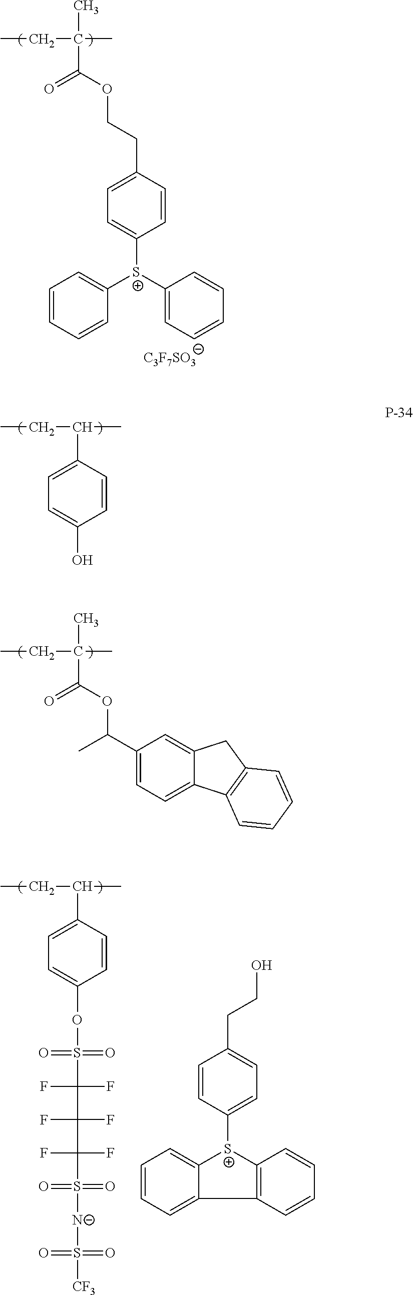

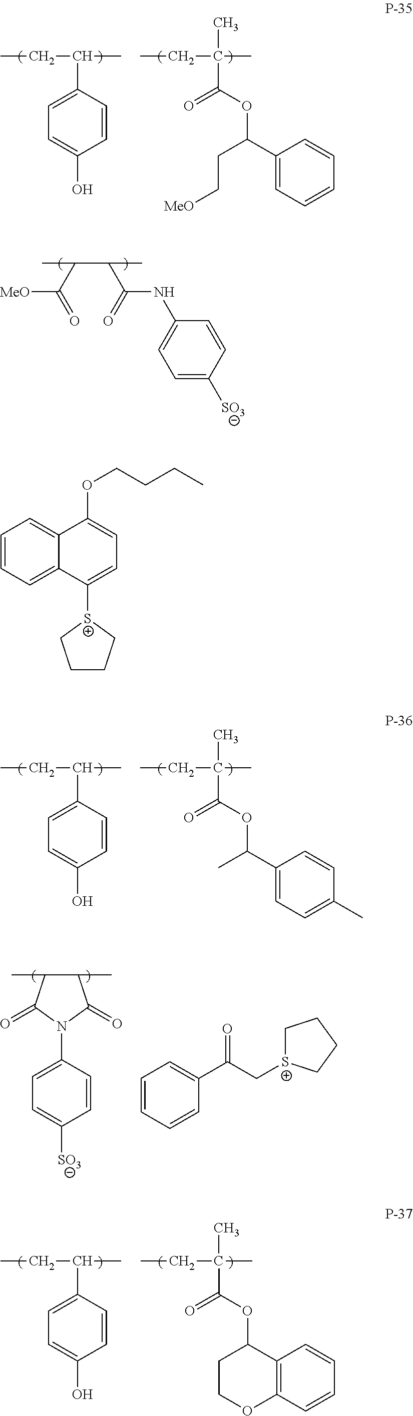

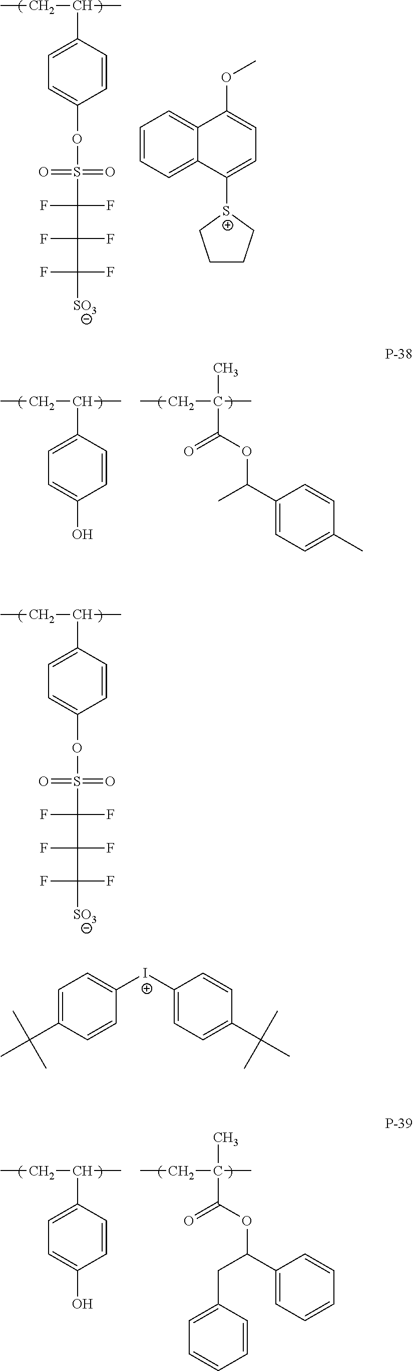

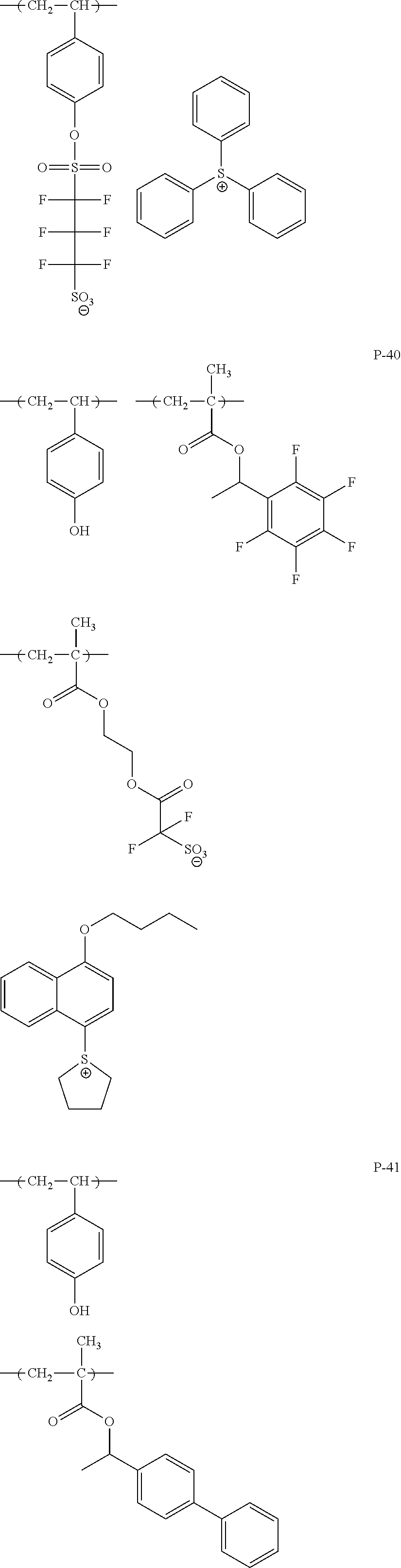

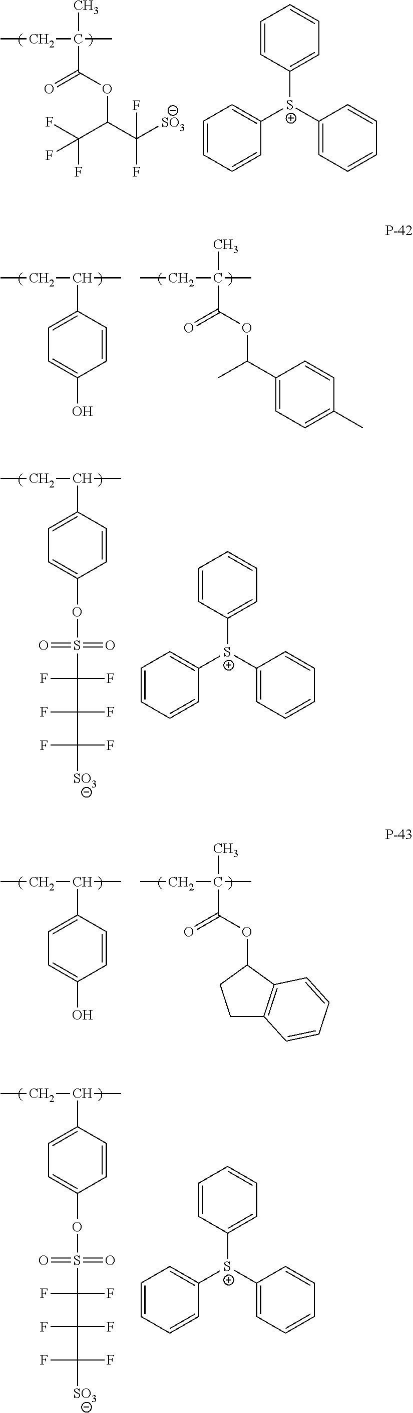

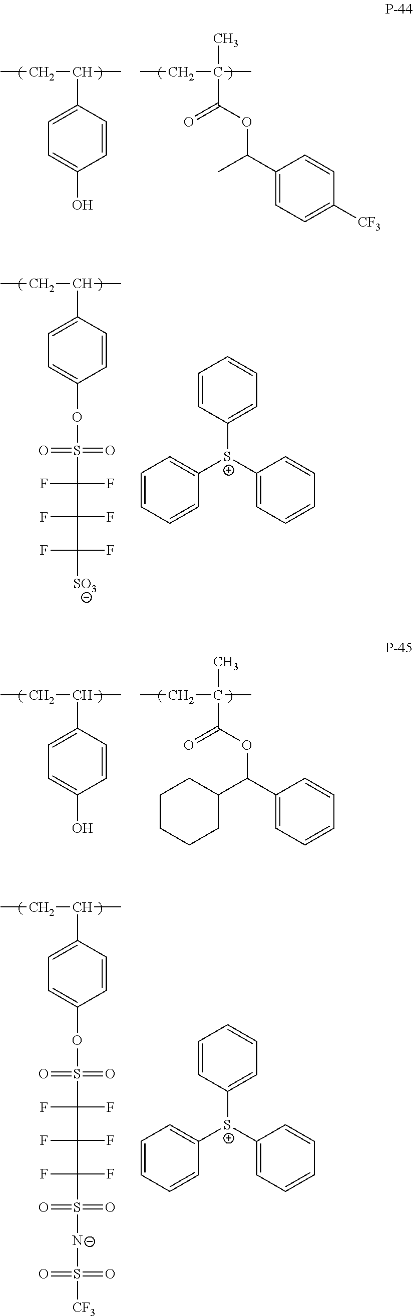

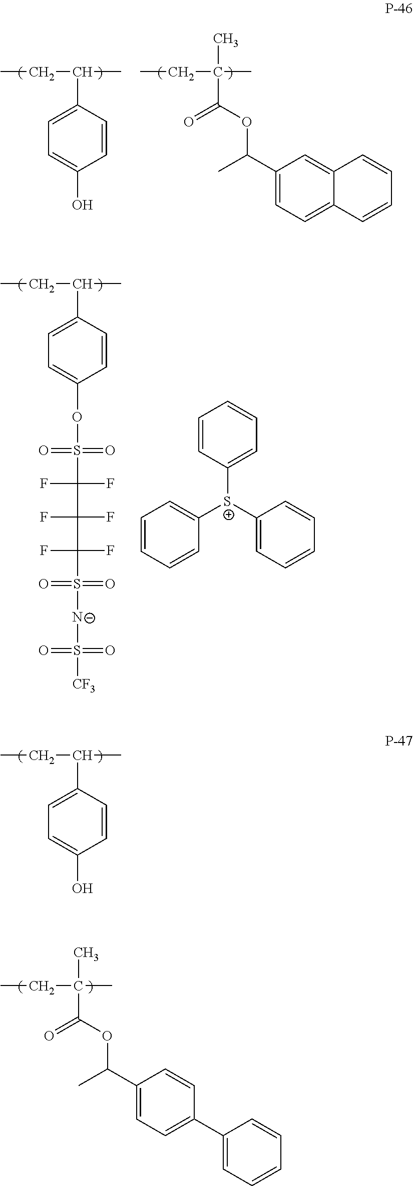

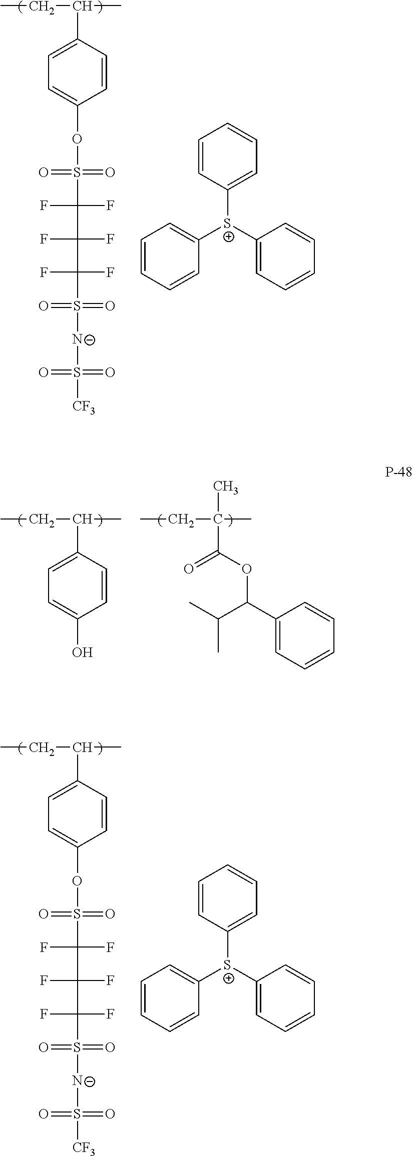

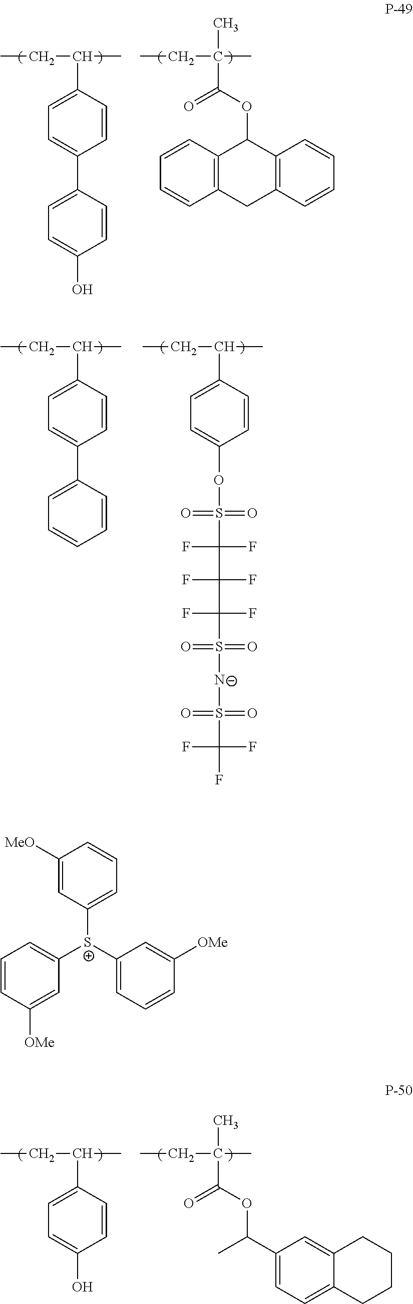

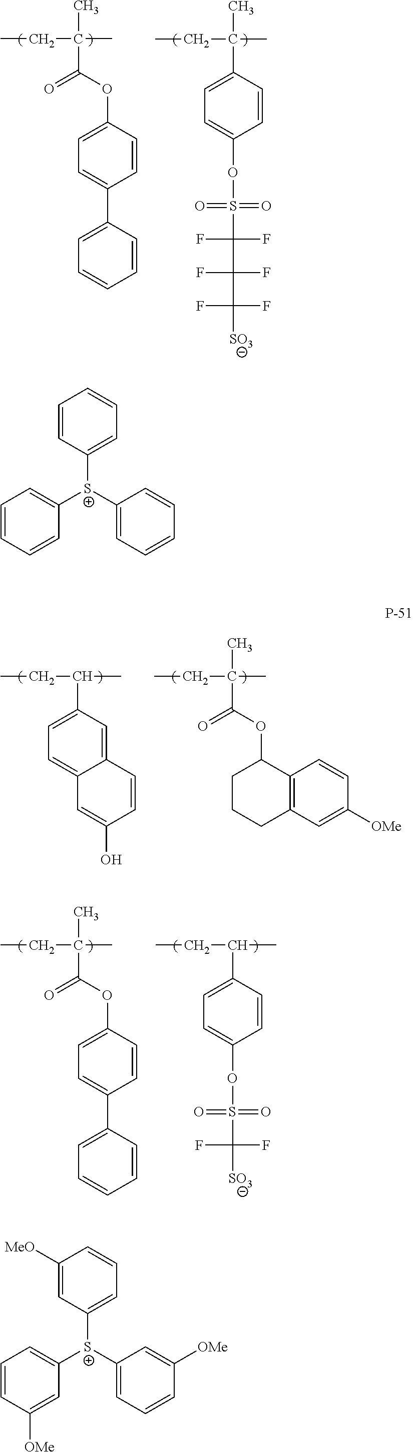

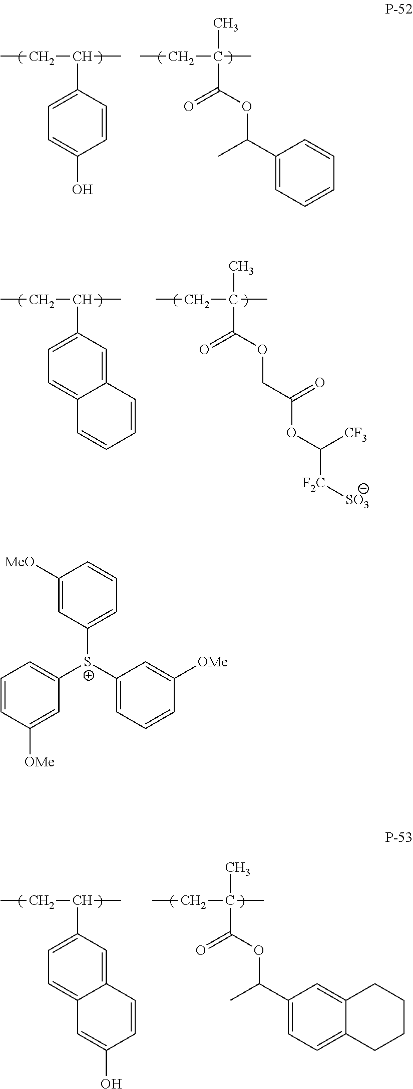

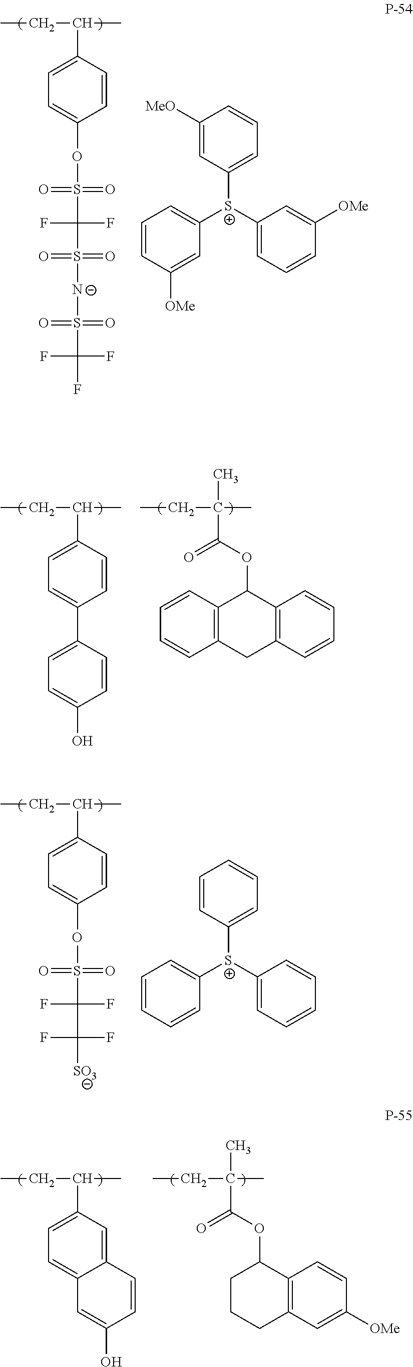

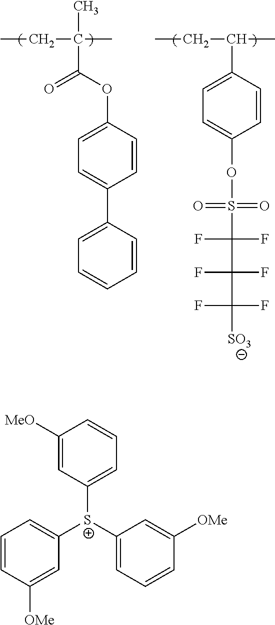

### <Other Components>

The composition of the present invention may further contain a photo-acid generator, a basic compound, a surfactant, a solvent, a dye, a photo-base generator, an antioxidant, a solvent and the like. These components are described below.

### (Photo-Acid Generator)

The composition of the present invention may further contain a photo-acid generator in addition to the repeating unit (A) and the repeating unit (B).

The photo-acid generator is a compound capable of generating an acid upon irradiation with an actinic ray or radiation. The photo-acid generator which can be used may be appropriately selected, for example, from a photo-initiator for cationic photopolymerization, a photo-initiator for radical photopolymerization, a photo-decoloring agent, a photo-discoloring agent, known compounds capable of generating an acid upon irradiation with an actinic ray or radiation, which are used for microresist or the like, and a mixture thereof. Examples thereof include an onium salt such as sulfonium salt and iodonium salt, and a diazodisulfone compound such as bis(alkylsulfonyl diazomethane).

Preferred examples of the photo-acid generator include compounds represented by the following formulae (ZI), (ZII) and (ZIII):

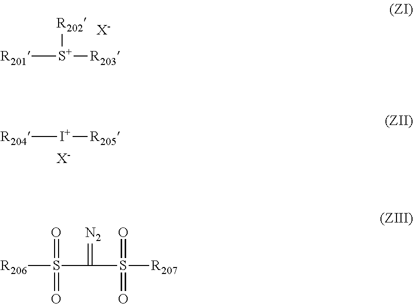

In formulae (ZI) and (ZII), each of R₂₀₁′, R₂₀₂′, R₂₀₃′, R₂₀₄′ and R₂₀₅′ independently represents an organic group. Specific examples of R₂₀₁′, R₂₀₂′, R₂₀₃′, R₂₀₄′ and R₂₀₅′ are the same as those described above for R₂₀₁, R₂₀₂, R₂₀₃, R₂₀₄ and R₂₀₅, respectively, in the structural moiety capable of decomposing upon irradiation with an actinic ray or radiation to generate an acid anion.

X⁻ represents a non-nucleophilic anion. Examples of X⁻ include a sulfonate anion, a bis(alkylsulfonyl)amide anion, a tris(alkylsulfonyl)methide anion, BF₄⁻, PF₆⁻ and SbF₆⁻. X⁻ is preferably an organic anion containing a carbon atom. Preferred organic anions include organic anions represented by the following formulae AN1 to AN3:

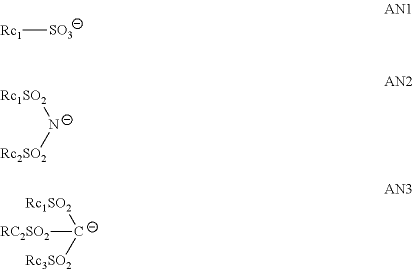

In formulae AN1 to AN3, each of Rc₁ to Rc₃ independently represents an organic group. The organic group includes, for example, an organic group having a carbon number of 1 to 30 and is preferably an alkyl group, an aryl group, or a group formed by connecting a plurality of these groups through a single bond or a linking group. Examples of the linking group include —O—, —CO₂—, —S—, —SO₃— and —SO₂N(Rd₁)-. Here, Rd₁ represents a hydrogen atom or an alkyl group and may form a ring structure together with the alkyl group or aryl group to which Rd₁ is bonded.

The organic group of Rc₁ to Rc₃ may be an alkyl group substituted with a fluorine atom or a fluoroalkyl group at the 1-position, or a phenyl group substituted with a fluorine atom or a fluoroalkyl group. By virtue of having a fluorine atom or a fluoroalkyl group, the acidity of the acid generated upon irradiation with light is increased and in turn, the sensitivity of the actinic ray-sensitive or radiation-sensitive resin composition is enhanced. Incidentally, each of Rc₁ to Rc₃ may combine with another alkyl group, aryl group or the like to form a ring structure.

As the photo-acid generator, a compound having a plurality of structures represented by formula (ZI) may be also used. For example, the compound may be a compound having a structure where at least one of R₂₀₁′ to R₂₀₃′ in a compound represented by formula (ZI) is bonded to at least one of R₂₀₁′ to R₂₀₃′ in another compound represented by formula (ZI).

Formula (ZIII) is described below.

In formula (ZIII), each of R₂₀₆ and R₂₀₇ independently represents an aryl group, an alkyl group or a cycloalkyl group. These aryl group, alkyl group and cycloalkyl group may have a substituent.

Preferred examples of the aryl group as R₂₀₆ and R₂₀₇ are the same as those enumerated above for R₂₀₁ to R₂₀₃ in the (ZI-1) group capable of decomposing upon irradiation with an actinic ray or radiation to generate an acid anion.

Preferred examples of the alkyl group and cycloalkyl group as R₂₀₆ and R₂₀₇ are the same as those enumerated above for the linear, branched or cyclic alkyl group of R₂₀₁ to R₂₀₃ in the (ZI-2) group capable of decomposing upon irradiation with an actinic ray or radiation to generate an acid anion.

Each of the aryl group, alkyl group and cycloalkyl group of R₂₀₆ and R₂₀₇ may have a substituent. Examples of the substituent which the aryl group, alkyl group and cycloalkyl group of R₂₀₆ and R₂₀₇ may have include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group and a phenylthio group.

Other preferred examples of the photo-acid generator include compounds represented by the following formulae (ZIV), (ZV) and (ZVI):

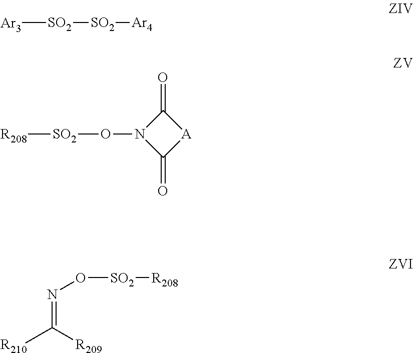

In formulae (ZIV) to (ZVI), each of Ar₃ and An₄ independently represents a substituted or unsubstituted aryl group.

Each R₂₀₈ in formulae (ZV) and (ZVI) independently represents an alkyl group, a cycloalkyl group or a aryl group. These alkyl group, cycloalkyl group and aryl group may or may not be substituted.

Such a group is preferably substituted with a fluorine atom. In this case, the strength of the acid generated from the photo-acid generator can be increased.

Each of R₂₀₉ and R₂₁₀ independently represents an alkyl group, a cycloalkyl group, an aryl group or an electron-withdrawing group. These alkyl group, cycloalkyl group, aryl group and electron-withdrawing group may or may not be substituted. Examples of the substituent which the alkyl group, cycloalkyl group, aryl group and electron-withdrawing group may have include a halogen atom, an alkoxy group (for example, having a carbon number of 1 to 5), a hydroxyl group, a cyano group and a nitro group.

R₂₀₉ is preferably a substituted or unsubstituted aryl group.

R₂₁₀ is preferably an electron-withdrawing group. This electron-withdrawing group is preferably a cyano group or a fluoroalkyl group.

A represents an alkylene group, an alkenylene group or an arylene group. These alkylene group, alkenylene group and arylene group may have a substituent.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in formula (ZI-1).

Specific examples of the alkyl group and cycloalkyl group of R₂₀₈, R₂₀₉ and R₂₁₀ are the same as specific examples of the alkyl group and cycloalkyl group as R₂₀₁, R₂₀₂ and R₂₀₃ in formula (ZI-2).

The alkylene group of A includes an alkylene group having a carbon number of 1 to 12 (e.g., methylene group, ethylene group, propylene group, isopropylene group, butylenes group, isobutylene group); the alkenylene group of A includes an alkenylene group having a carbon number of 2 to 12 (e.g., ethynylene group, propenylene group, butenylene group); and the arylene group of A includes an arylene group having a carbon number of 6 to 10 (e.g., phenylene group, tolylene group, naphthylene group).

As the photo-acid generator, a compound having a plurality of structures represented by formula (ZVI) is also preferred. For example, the compound includes a compound having a structure where R₂₀₉ or R₂₁₀ in a compound represented by formula (ZVI) is bonded to R₂₀₉ or R₂₁₀ in another compound represented by formula (ZVI).

The photo-acid generator is preferably a compound represented by any of formulae (ZI) to (ZIII), more preferably a compound represented by formula (ZI).

Specific examples of the photo-acid generator are illustrated below, but the present invention is not limited thereto.

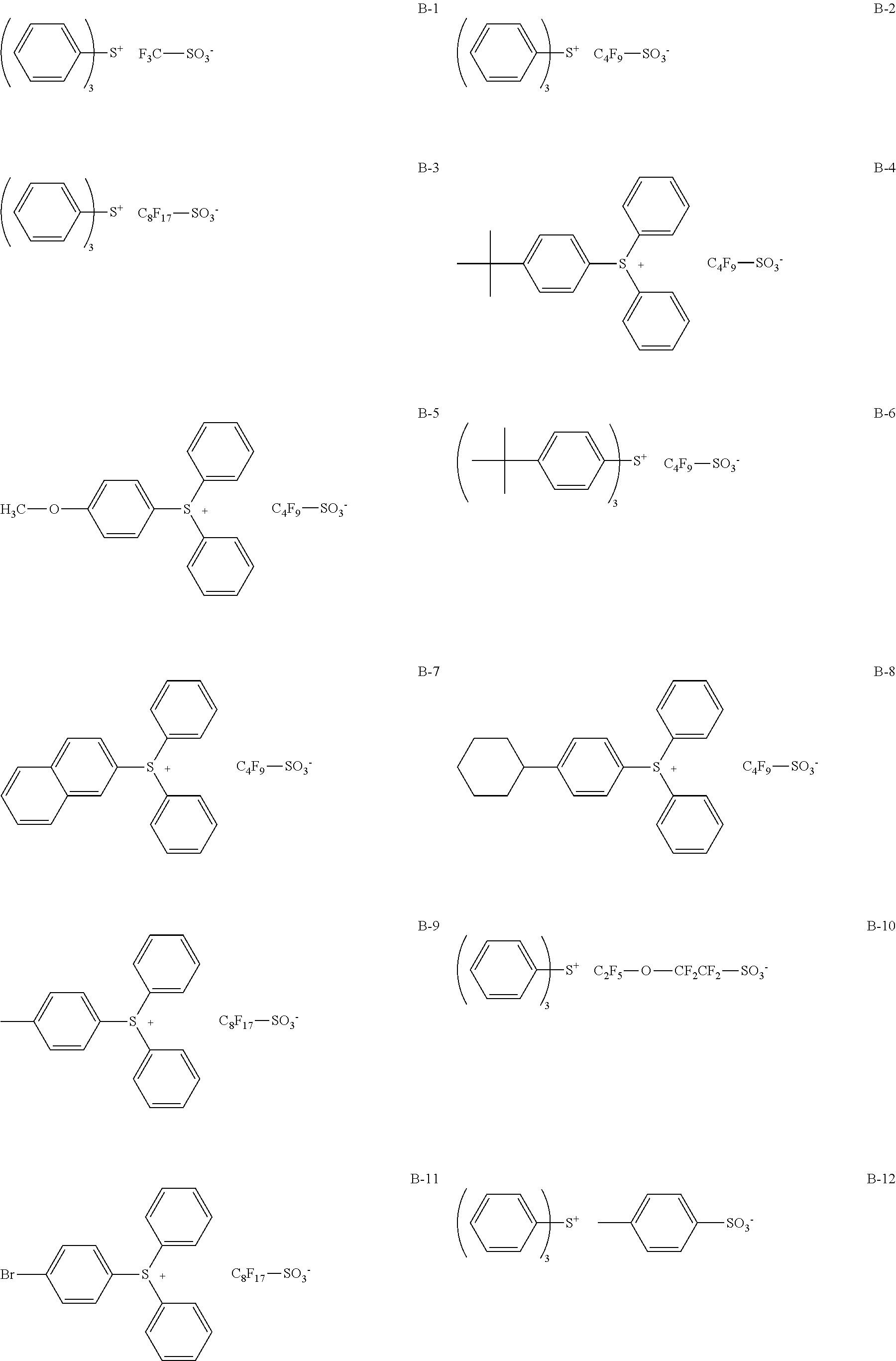

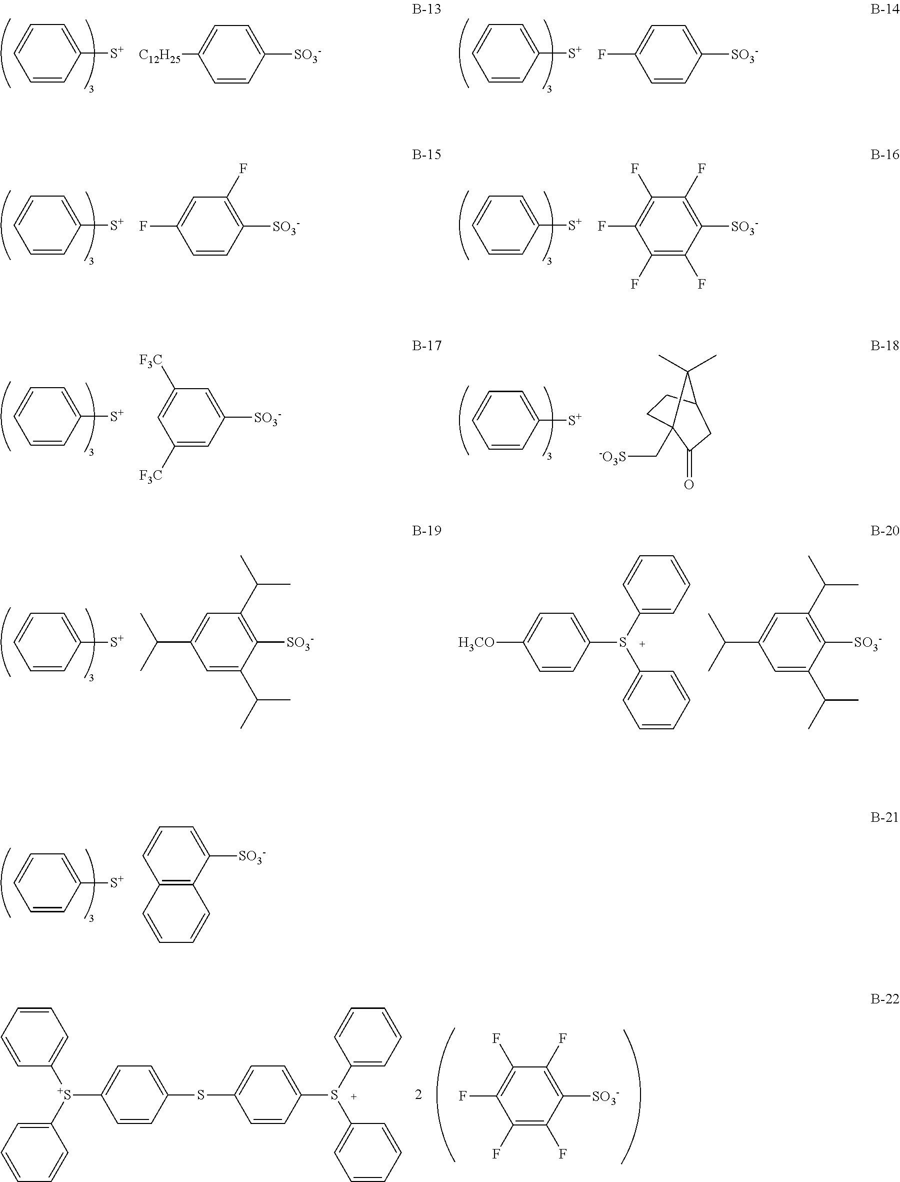

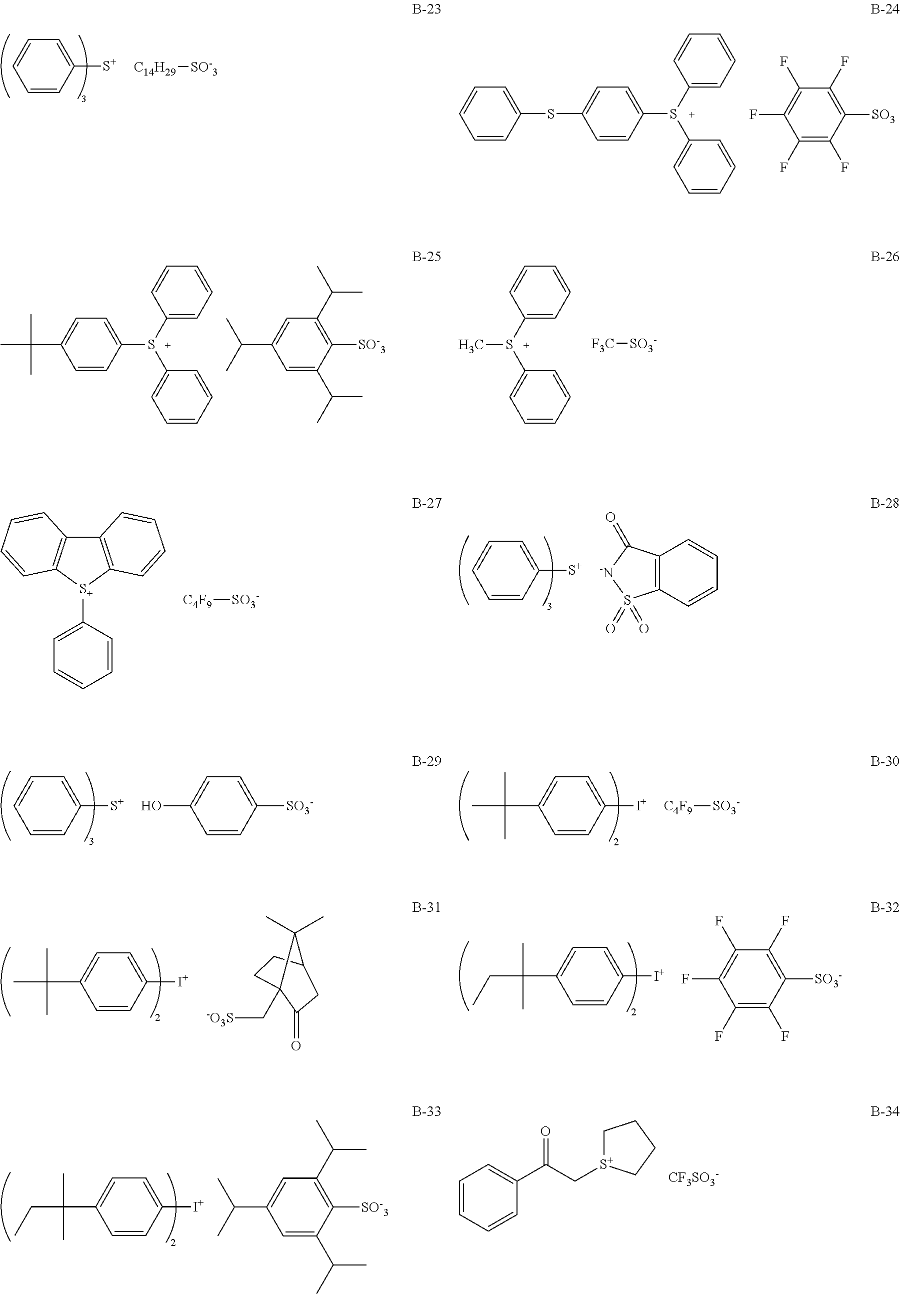

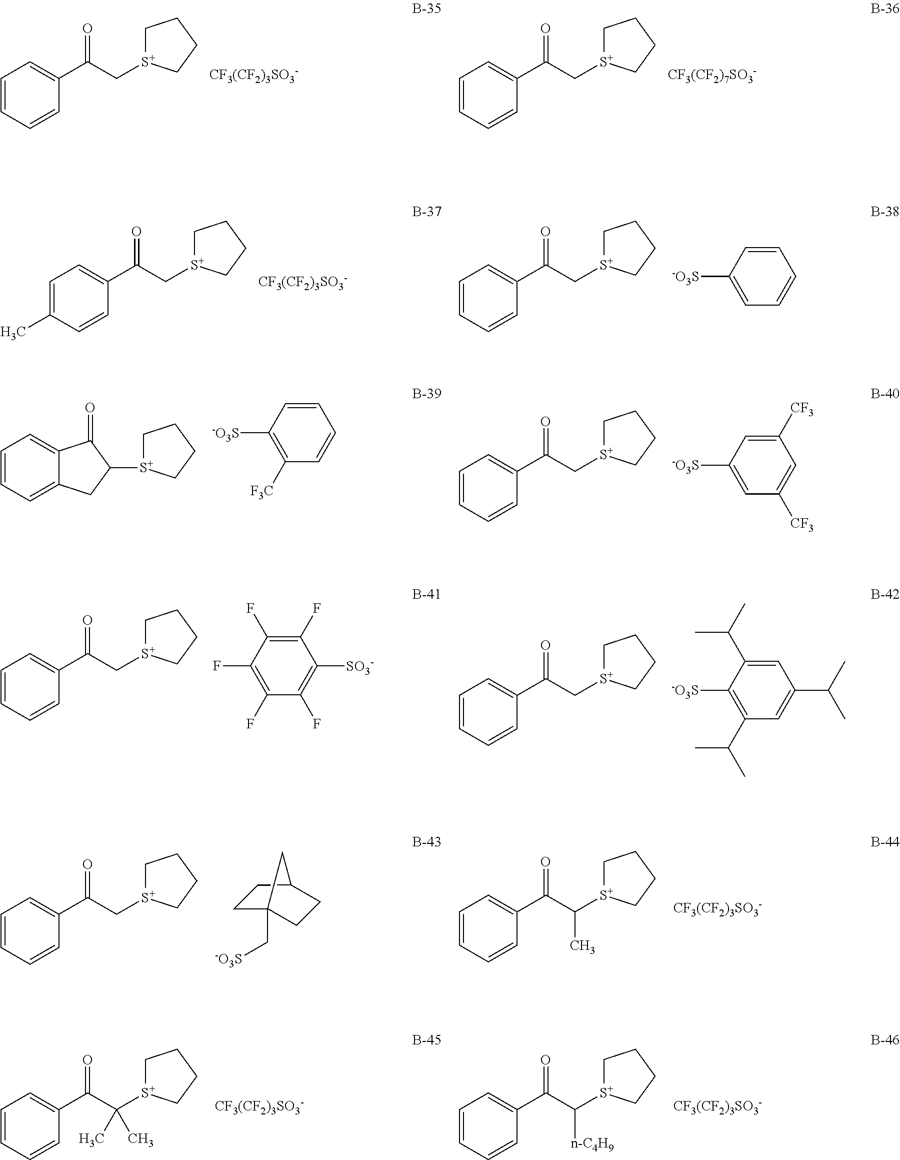

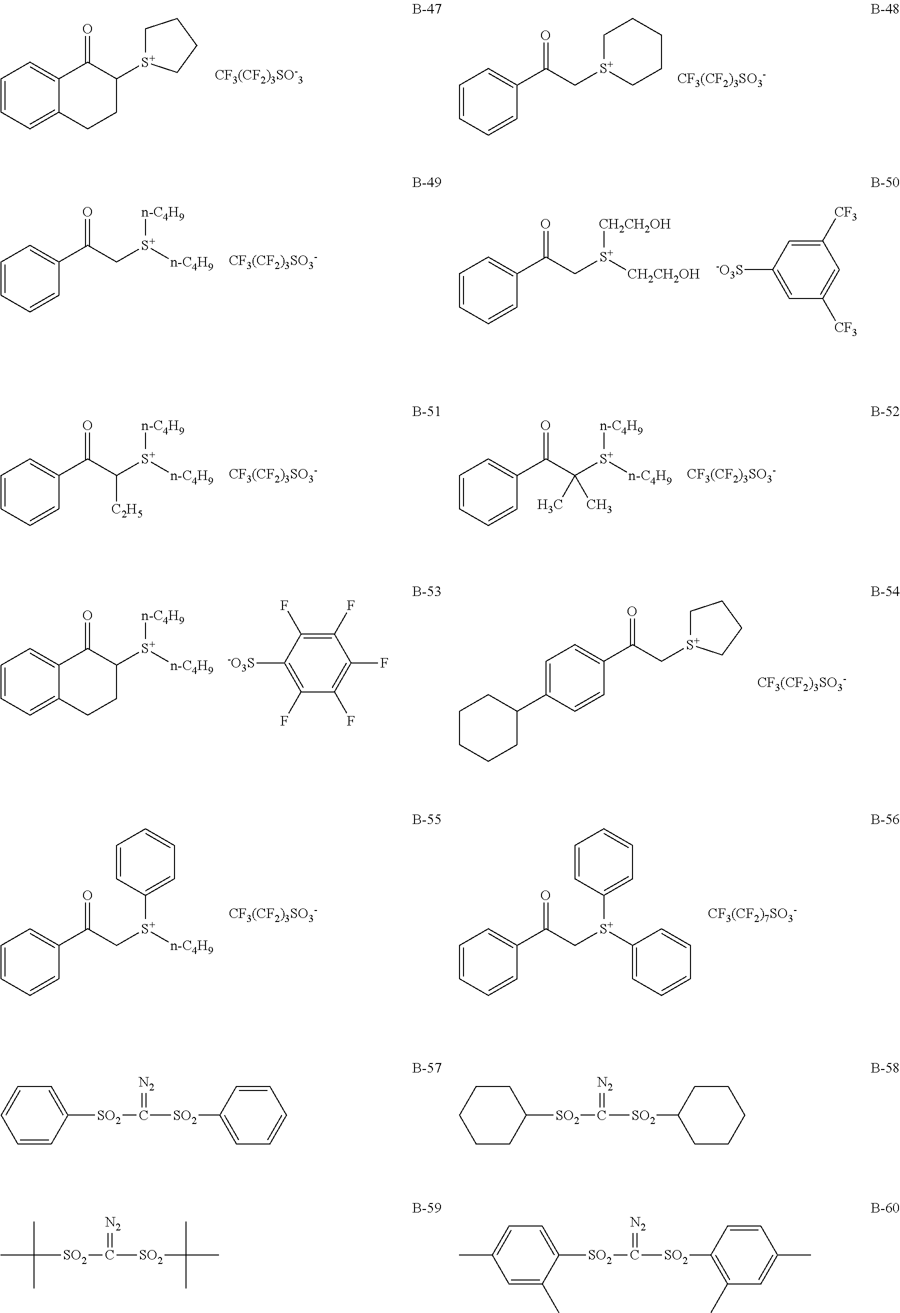

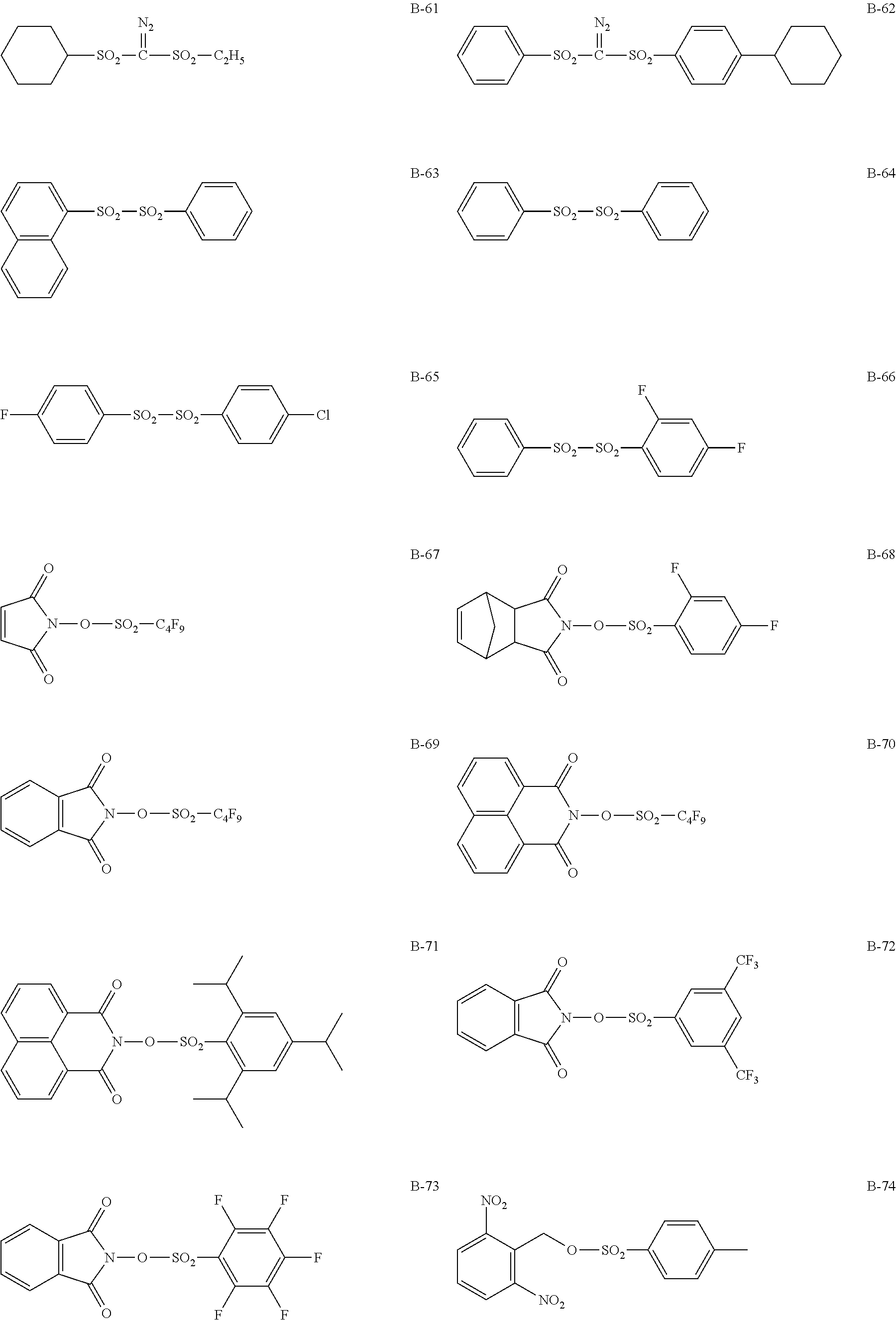

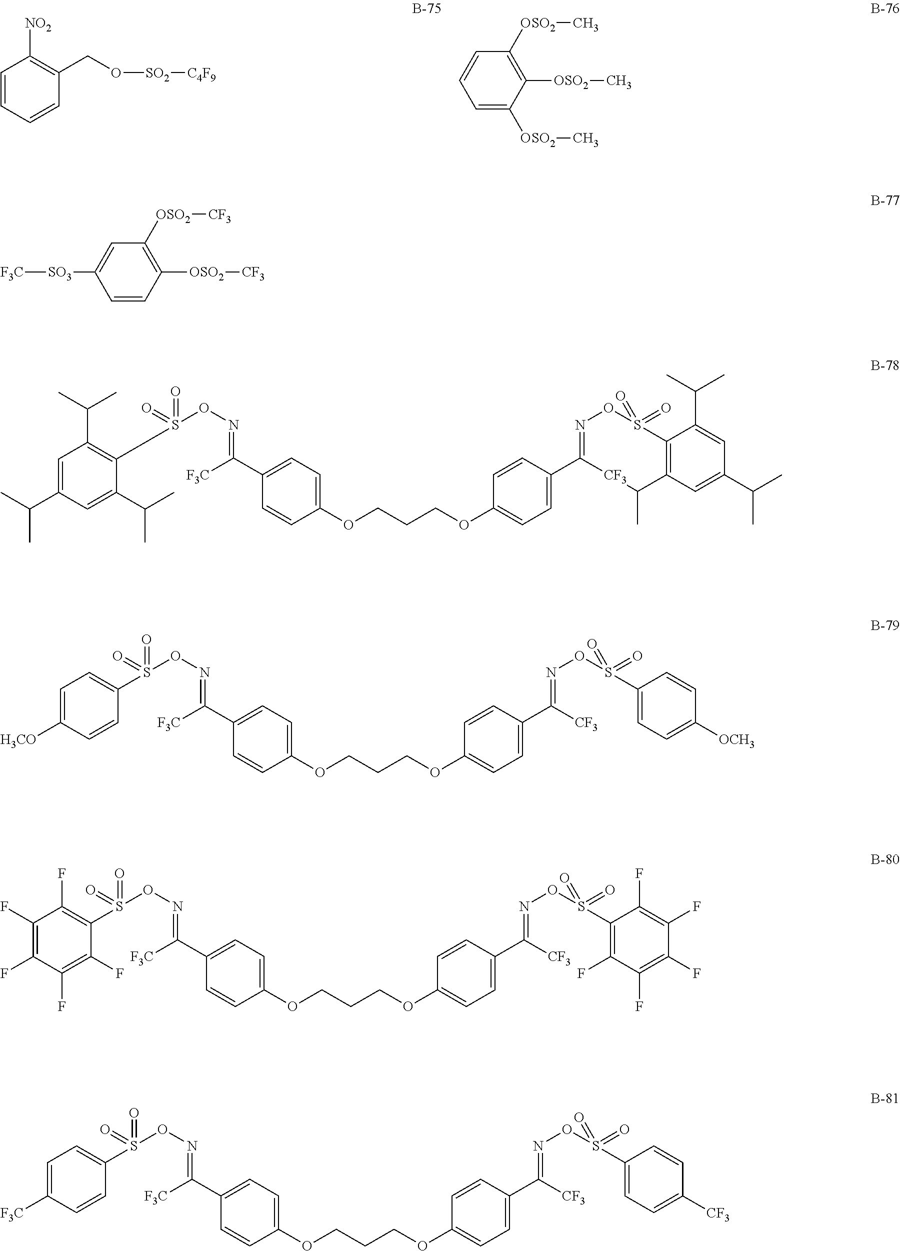

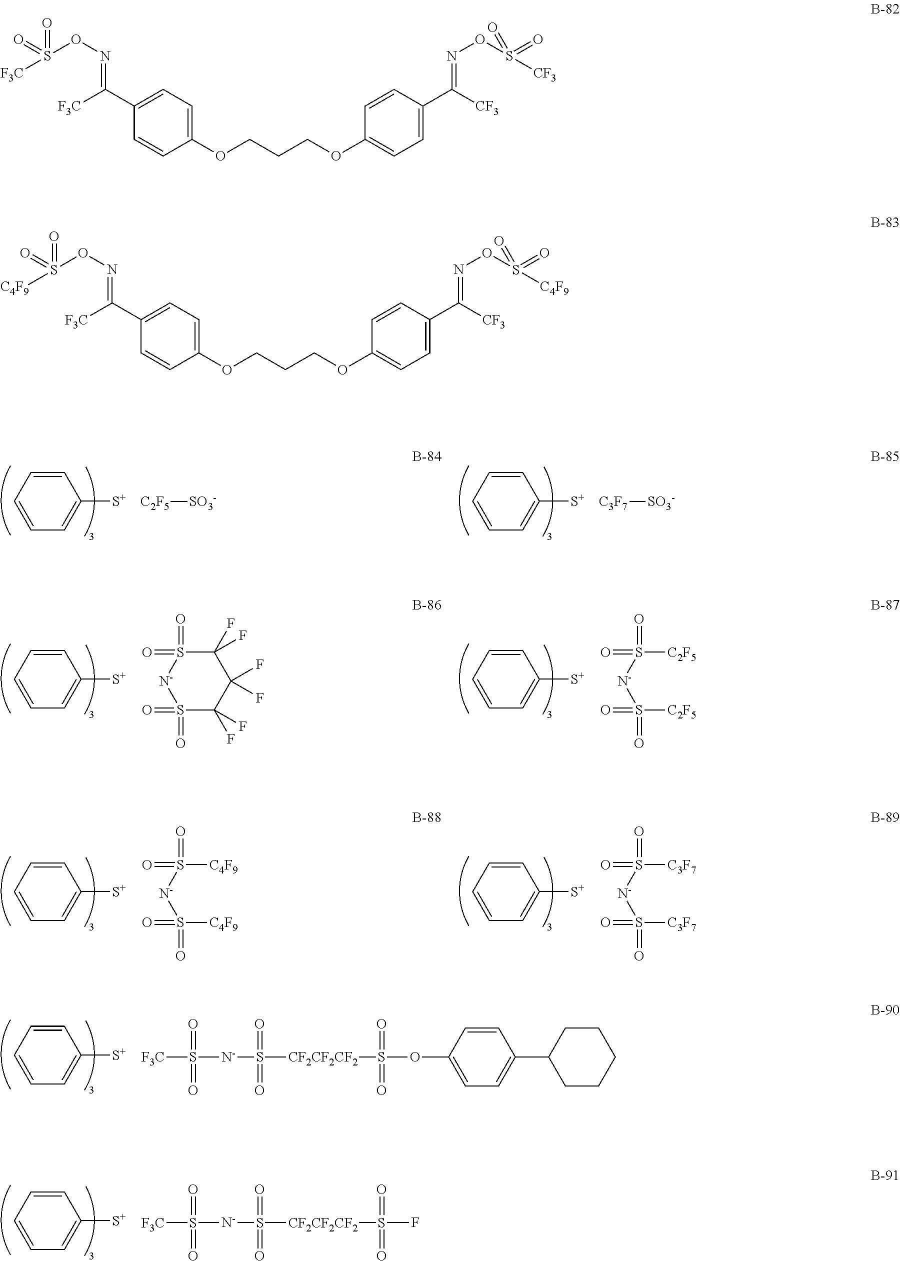

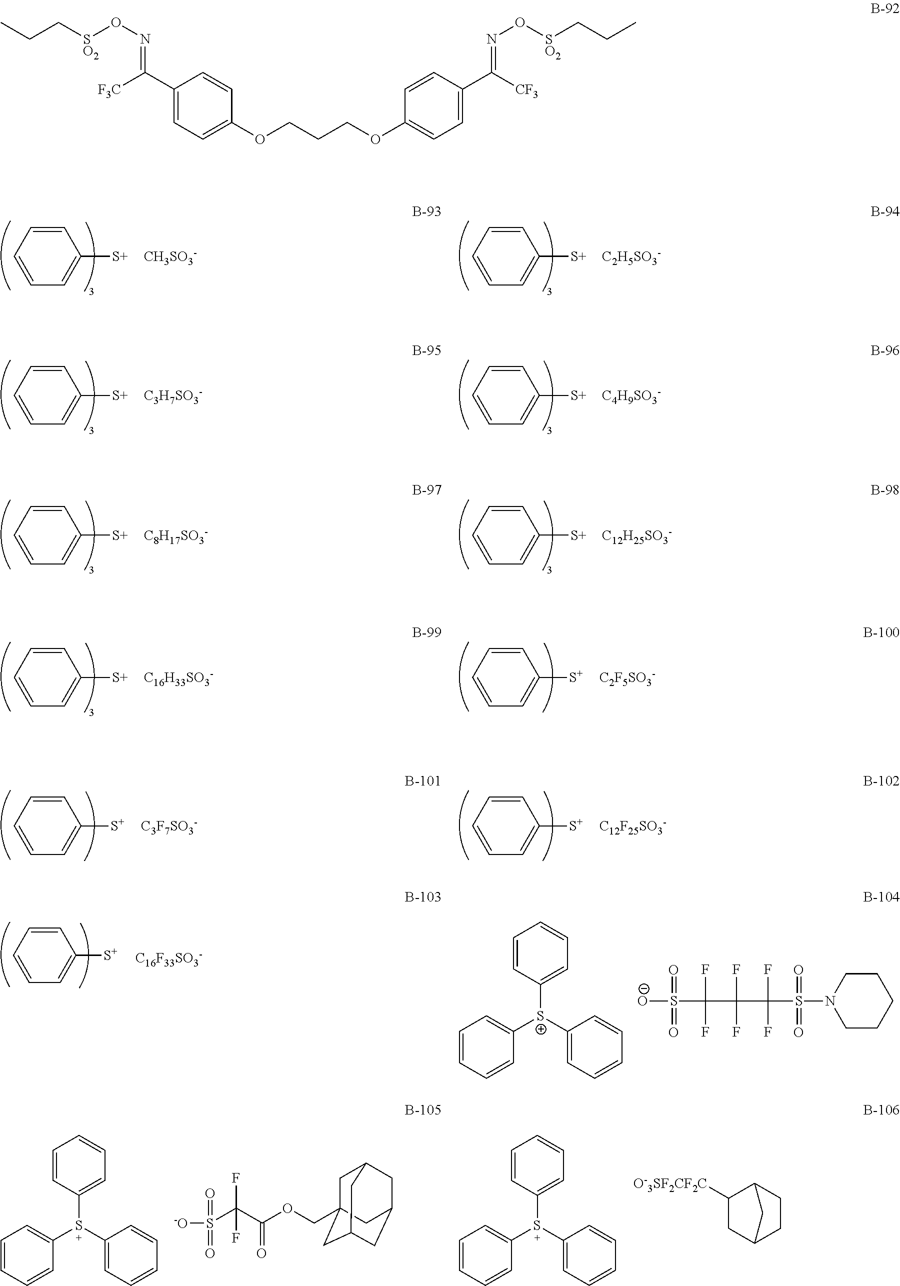

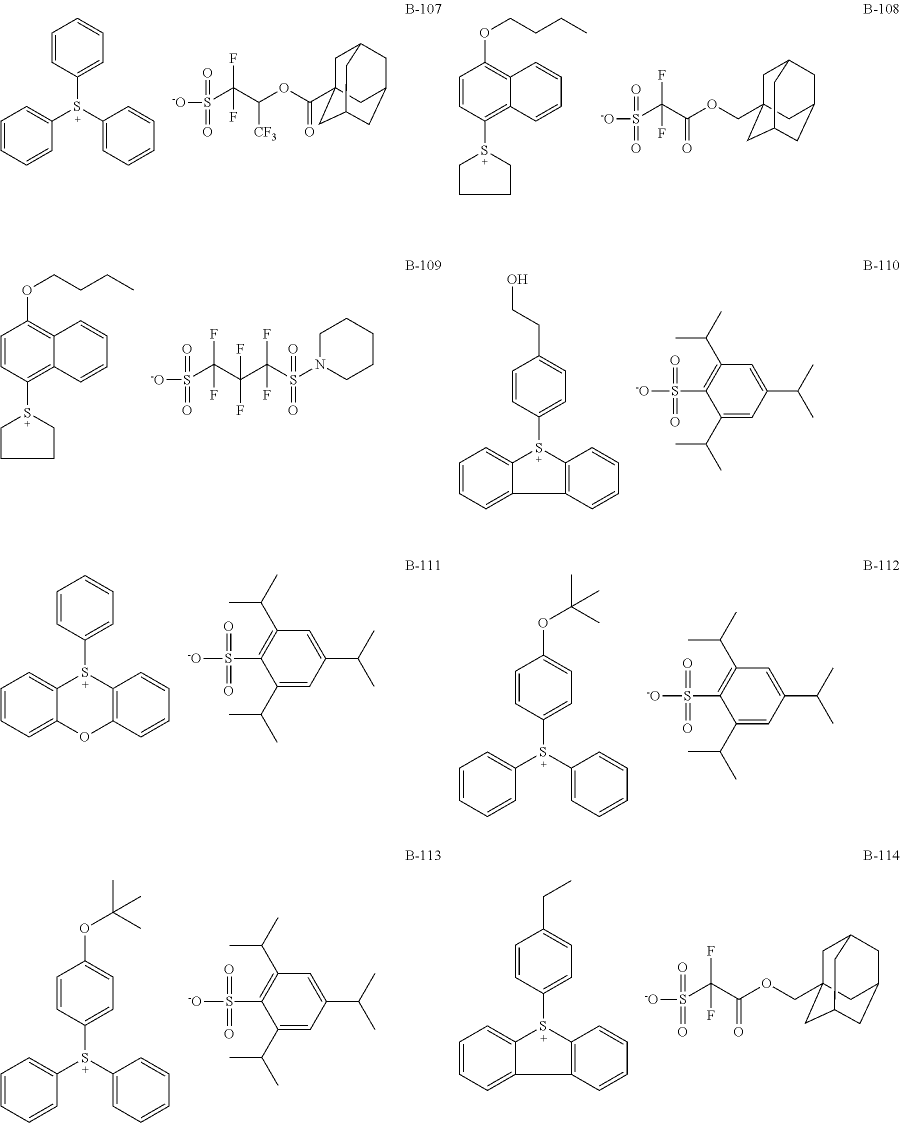

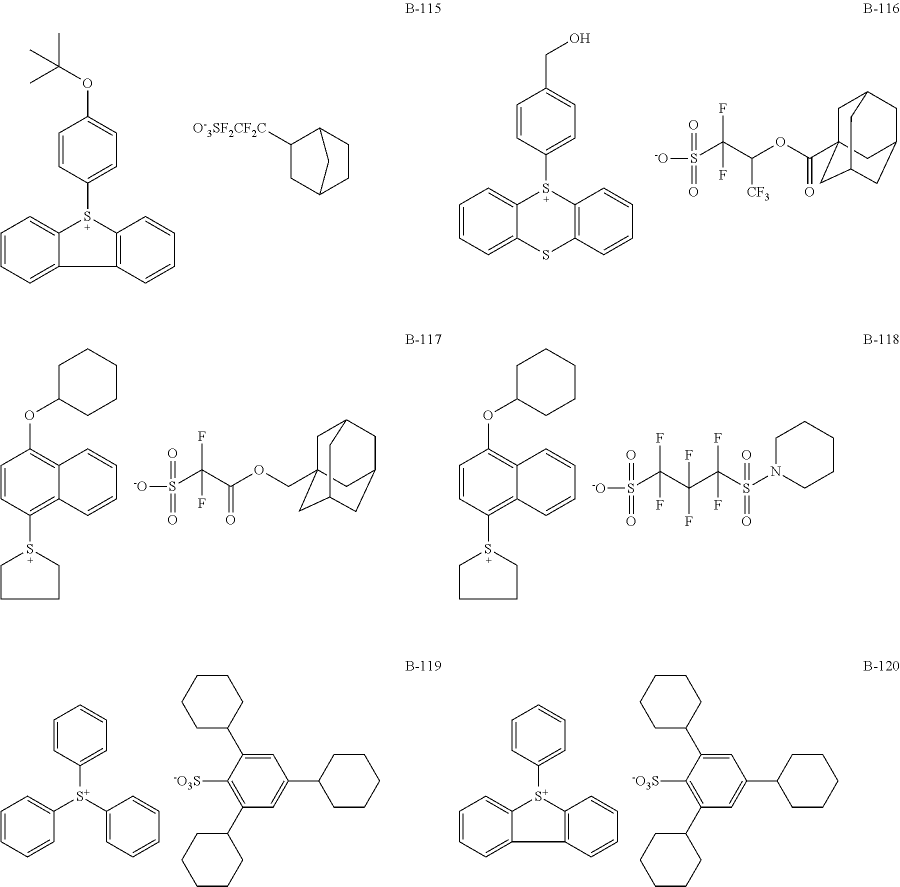

The composition of the present invention may further contain, as a photo-acid generator, a compound capable of generating a carboxylic acid upon irradiation with an actinic ray or radiation. Examples of such a compound include the followings.

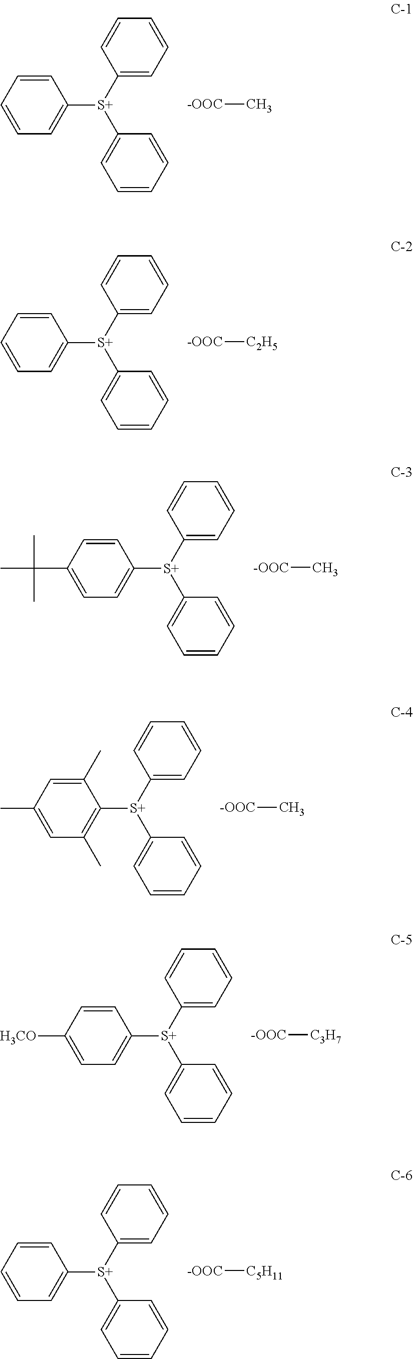

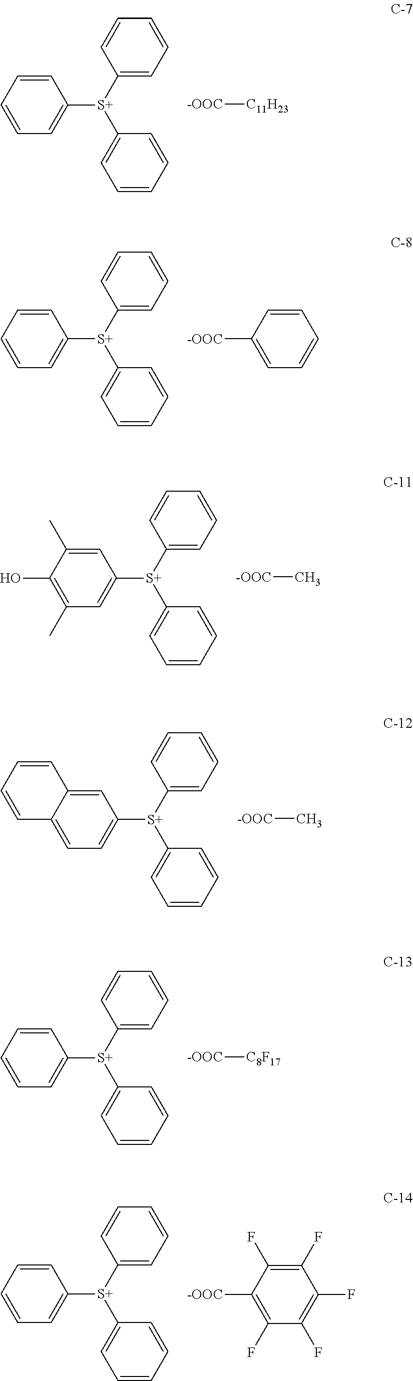

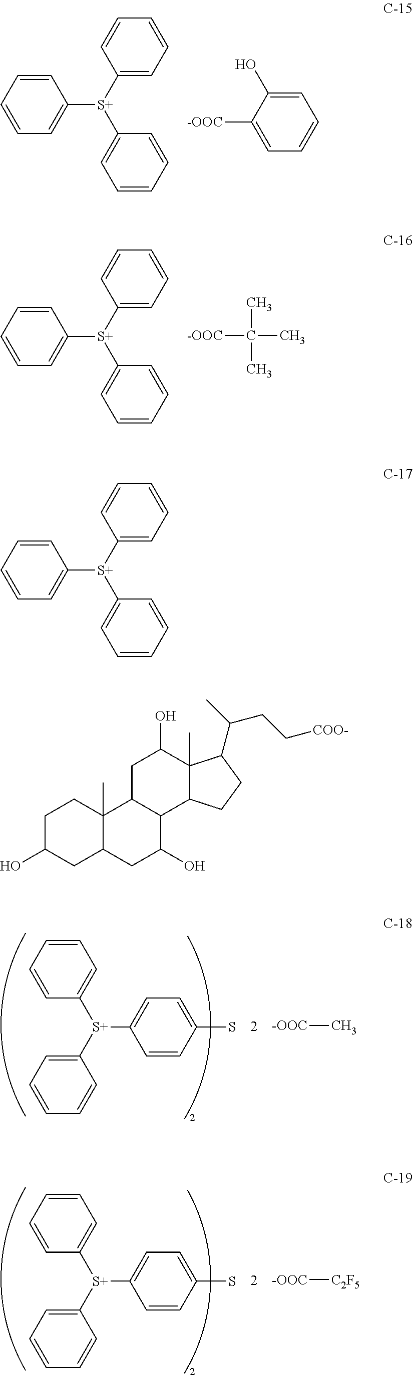

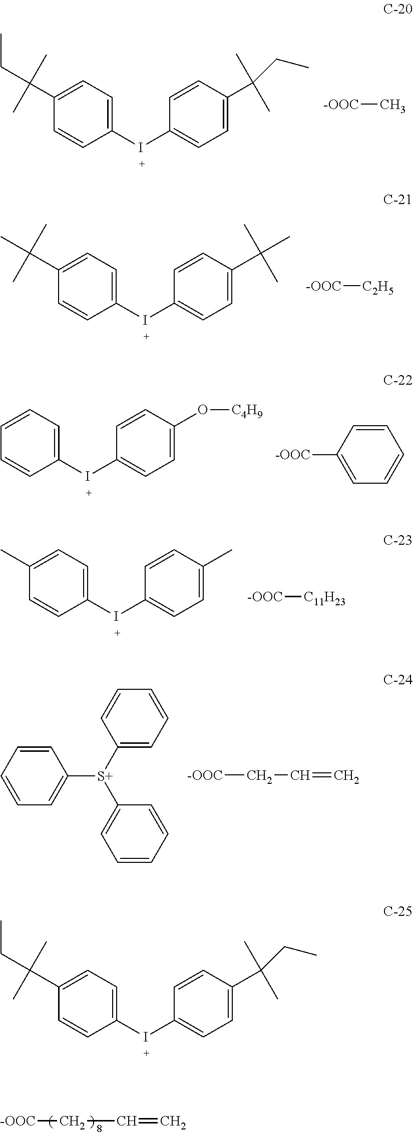

The molecular weight of the photo-acid generator is, for example, from 100 to 1,500 and typically from 200 to 1,000.

As for the photo-acid generator, one kind of a compound may be used alone, or two or more kinds of compounds may be used in combination. In the latter case, compounds capable of generating two kinds of organic acids differing in the number of all atoms excluding hydrogen atom by 2 or more are preferably combined.

In the case where the composition of the present invention further contains a photo-acid generator, the content thereof is preferably from 0.1 to 40 mass %, more preferably from 0.5 to 30 mass %, still more preferably from 1 to 20 mass %, based on the entire solid content of the composition.

### (Basic Compound)

The composition of the present invention may further contain a basic compound. The basic compound is preferably a compound having basicity stronger than that of phenol. The basic compound is preferably an organic basic compound, more preferably a nitrogen-containing basic compound.

The nitrogen-containing basic compound which can be used is not particularly limited, but, for example, compounds classified into the following (1) to (5) may be used.

### (1) Compound Represented by the Following Formula (BS-1):

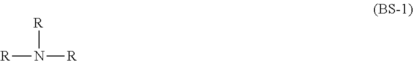

In formula (BS-1), each R independently represents a hydrogen atom or an organic group, provided that at least one of three R's is an organic group. This organic group is a linear or branched alkyl group, a monocyclic or polycyclic cycloalkyl group, an aryl group or an aralkyl group.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specific examples thereof include a phenyl group and a naphthyl group.

The carbon number of the aralkyl group as R is not particularly limited but is usually from 7 to 20, preferably from 7 to 11. Specific examples thereof include a benzyl group.

In the alkyl group, cycloalkyl group, aryl group and aralkyl group as R, a hydrogen atom may be substituted for by a substituent. Examples of the substituent include an alkyl group, a cycloalkyl group, an aryl group, an aralkyl group, a hydroxy group, a carboxy group, an alkoxy group, an aryloxy group, an alkylcarbonyloxy group and an alkyloxycarbonyl group.

In the compound represented by formula (BS-1), it is preferred that at least two R's are an organic group.

Specific examples of the compound represented by formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dihexylaniline, 2,6-diisopropylaniline and 2,4,6-tri(tert-butyl)aniline.

Also, the basic compound represented by formula (BS-1) is preferably a basic compound where at least one of three R's is an alkyl group having a hydrophilic group. Thanks to this configuration, the resolution can be enhanced and at the same time, a good pattern profile can be formed.

The alkyl group having a hydrophilic group preferably has a carbon number of 1 to 8, more preferably from 1 to 6.

Examples of the alkyl group having a hydrophilic group include an alkyl group having a hydroxy group or a mercapto group. Specific examples of the basic compound having such an alkyl group include triethanolamine and N,N-dihydroxyethylaniline.

The alkyl group having a hydrophilic group also includes an alkyl group having an oxygen atom, a sulfur atom or a carbonyl group in the alkyl chain. That is, the alkyl group as R may be an oxyalkylene chain, a thioalkylene chain or a ketoalkylene chain. The oxyalkylene chain is preferably —CH₂CH₂O—. Specific examples thereof include tris(methoxyethoxyethyl)amine and compounds illustrated in U.S. Pat. No. 6,040,112, column 3, line 60 et seq.

The alkyl group having a hydrophilic group may be also an alkyl group having a hydroxy group or a mercapto group as a substituent and having an oxygen atom, a sulfur atom or a carbonyl group in the alkyl chain.

The alkyl group having a hydrophilic group may further have a substituent, and examples of the further substituent include a substituted or unsubstituted aryl group. In the case where the aryl group is a substituted aryl group, examples of the substituent in the substituted aryl group include an alkyl group, an alkoxy group and an aryl group.

Specific examples of the basic compound where in formula (BS-1), at least one of three R's is an alkyl group having a hydrophilic group, are illustrated below, but the present invention is not limited thereto.

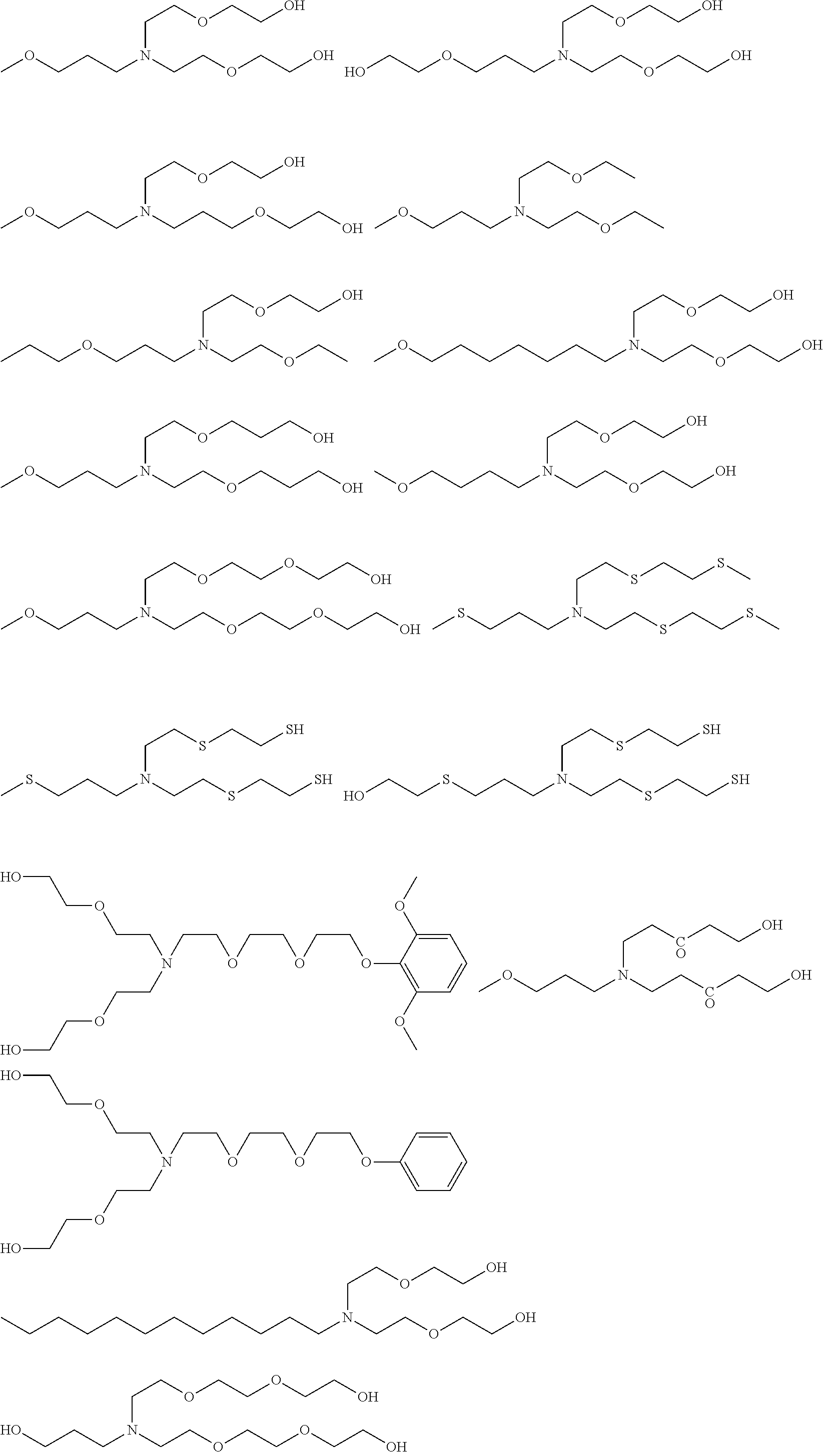

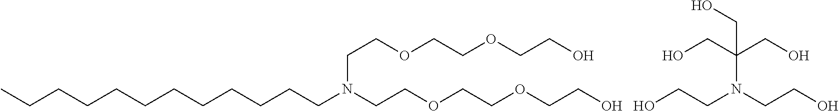

### (2) Compound Having a Nitrogen-Containing Heterocyclic Structure

The nitrogen-containing heterocyclic ring may or may not have aromaticity, may contain a plurality of nitrogen atoms, and may further contain a heteroatom other than nitrogen. Specific examples of the compound include a compound having an imidazole structure (e.g., 2-phenylbenzimidazole, 2,4,5-triphenylimidazole), a compound having a piperidine structure [e.g., N-hydroxyethylpiperidine, bis(1,2,2,6,6-pentamethyl-4-piperidyl)sebacate], a compound having a pyridine structure (e.g., 4-dimethylaminopyridine), and a compound having an antipyrine structure (e.g., antipyrine, hydroxyantipyrine).

A compound having two or more ring structures is also suitably used. Specific examples thereof include 1,5-diazabicyclo[4.3.0]non-5-ene and 1,8-diazabicyclo[5.4.0]undec-7-ene.

### (3) Phenoxy Group-Containing Amine Compound

The phenoxy group-containing amine compound is a compound where the alkyl group contained in an amine compound has a phenoxy group at the terminal opposite the N atom. The phenoxy group may have a substituent such as alkyl group, alkoxy group, halogen atom, cyano group, nitro group, carboxy group, carboxylic acid ester group, sulfonic acid ester group, aryl group, aralkyl group, acyloxy group and aryloxy group.

The compound preferably has at least one oxyalkylene chain between the phenoxy group and the nitrogen atom. The number of oxyalkylene chains in one molecule is preferably from 3 to 9, more preferably from 4 to 6. Among oxyalkylene chains, —CH₂CH₂O— is preferred.

Specific examples of the compound include 2-[2-{2-(2,2-dimethoxyphenoxyethoxy)ethyl}-bis-(2-methoxyethyl)]-amine and Compounds (C1-1) to (C3-3) illustrated in paragraph [0066] of U.S. Patent Application Publication No. 200710224539A1.

The phenoxy group-containing amine compound is obtained, for example, by reacting a primary or secondary amine having a phenoxy group with a haloalkyl ether under heating and after adding an aqueous solution of a strong base such as sodium hydroxide, potassium hydroxide and tetraalkylammonium, extracting the reaction product with an organic solvent such as ethyl acetate and chloroform. The phenoxy group-containing amine compound may be also obtained by reacting a primary or secondary amine with a haloalkyl ether having a phenoxy group at the terminal under heating and after adding an aqueous solution of a strong base such as sodium hydroxide, potassium hydroxide and tetraalkylammonium, extracting the reaction product with an organic solvent such as ethyl acetate and chloroform.

### (4) Ammonium Salt

An ammonium salt is also appropriately used as the basic compound.

Examples of the anion of the ammonium salt include a halide, a sulfonate, a borate and a phosphate. Among these, a halide and a sulfonate are preferred.

The halide is preferably chloride, bromide or iodide.

The sulfonate is preferably an organic sulfonate having a carbon number of 1 to 20. Examples of the organic sulfonate include an alkylsulfonate having a carbon number of 1 to 20 and an arylsulfonate.

The alkyl group contained in the alkylsulfonate may have a substituent, and examples of the substituent include a fluorine atom, a chlorine atom, a bromine atom, an alkoxy group, an acyl group and an aryl group. Specific examples of the alkylsulfonate include methanesulfonate, ethanesulfonate, butanesulfonate, hexanesulfonate, octanesulfonate, benzylsulfonate, trifluoromethanesulfonate, pentafluoroethanesulfonate and nonafluorobutanesulfonate.

Examples of the aryl group contained in the arylsulfonate include a phenyl group, a naphthyl group and an anthryl group. These aryl groups may have a substituent. The substituent is preferably, for example, a linear or branched alkyl group having a carbon number of 1 to 6, or a cycloalkyl group having a carbon number of 3 to 6. Specific preferred examples thereof include methyl, ethyl, n-propyl, isopropyl, n-butyl, i-butyl, tert-butyl, n-hexyl and cyclohexyl. Other substituents include an alkoxy group having a carbon number of 1 to 6, a halogen atom, cyano, nitro, an acyl group and an acyloxy group.

The ammonium salt may be a hydroxide or a carboxylate. In this case, the ammonium salt is preferably a tetraalkylammonium hydroxide having a carbon number of 1 to (e.g., tetramethylammonium hydroxide, tetraethylammonium hydroxide, tetra-(n-butyl)ammonium hydroxide).

Preferred examples of the basic compound include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine and aminoalkylmorpholine. These compounds may further have a substituent, and preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group and a cyano group.

More preferred examples of the basic compound include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine and N-(2-aminoethyl)morpholine.

In a particularly preferred embodiment of the present invention, the basic compound is a guanidine compound. The guanidine compound preferably has a log P value of 1.2 or more. By using a guanidine compound (preferably a guanidine compound having a log P value not lower than the value above) as the basic compound, scum can be improved and excellent resolution can be imparted. This compound can also contribute to excellent performance in terms of PEB temperature dependency.

The log P of the guanidine compound is preferably 10 or less. Thanks to this value or less, the guanidine compound can be uniformly contained in the resist film.

The log P of the guanidine compound for use in the present invention is preferably from 2 to 10, more preferably from 3 to 8, still more preferably from 4 to 8.

Also, it is preferred that the guanidine compound for use in the present invention does not have a nitrogen atom other than in the guanidine structure.

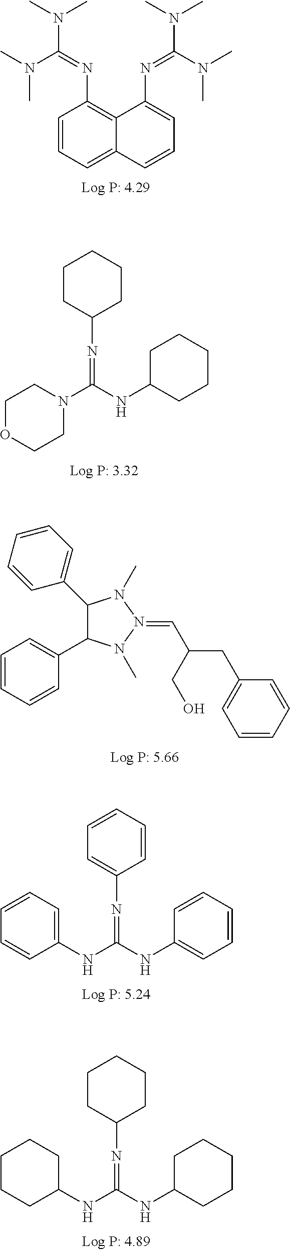

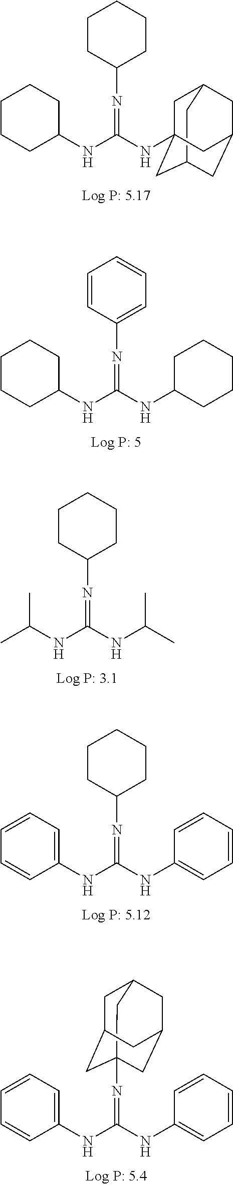

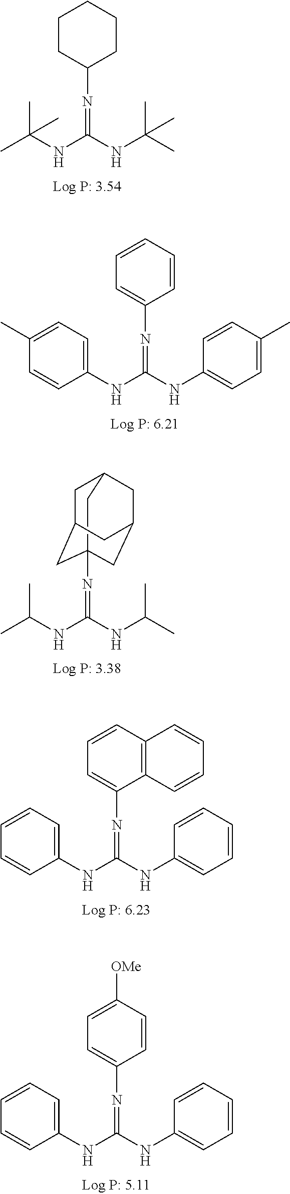

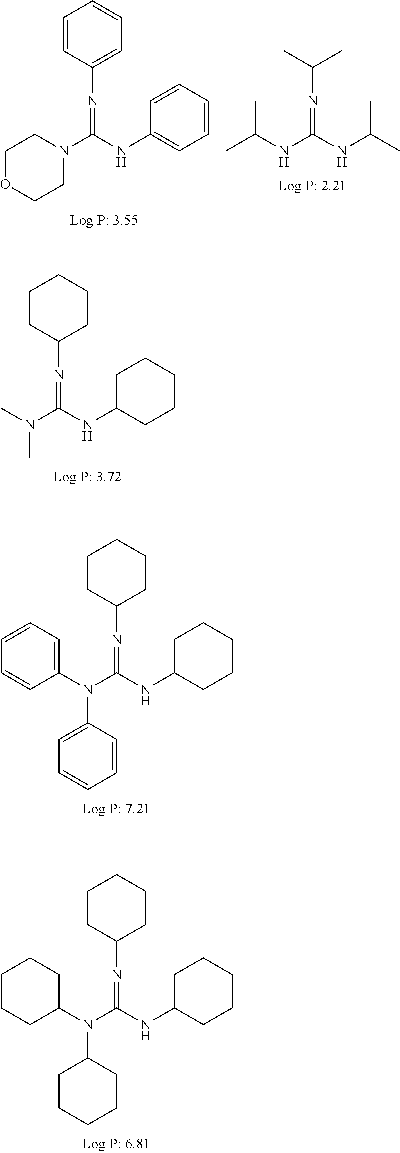

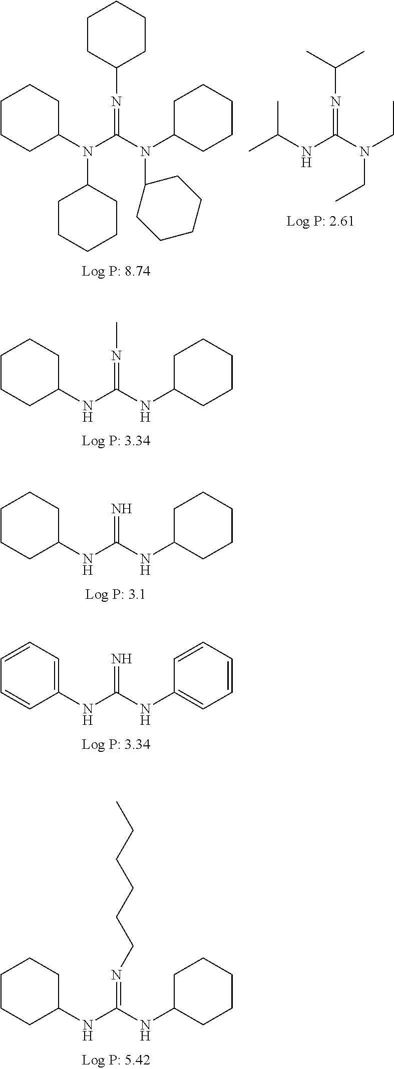

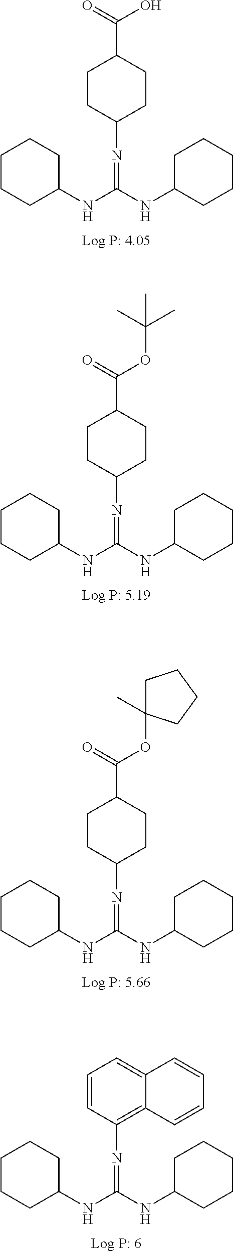

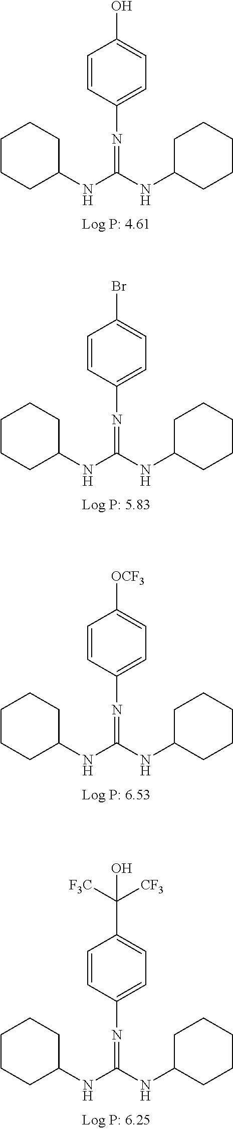

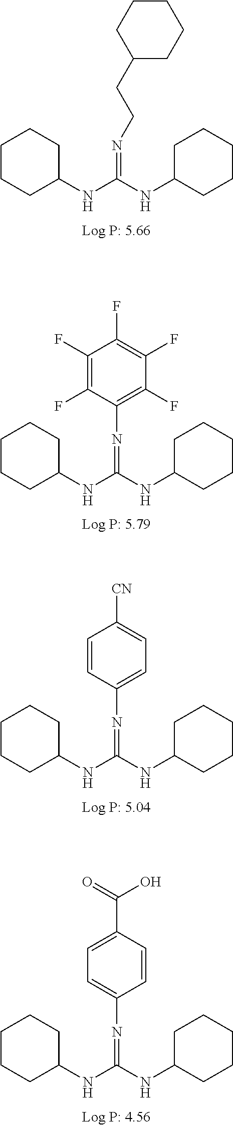

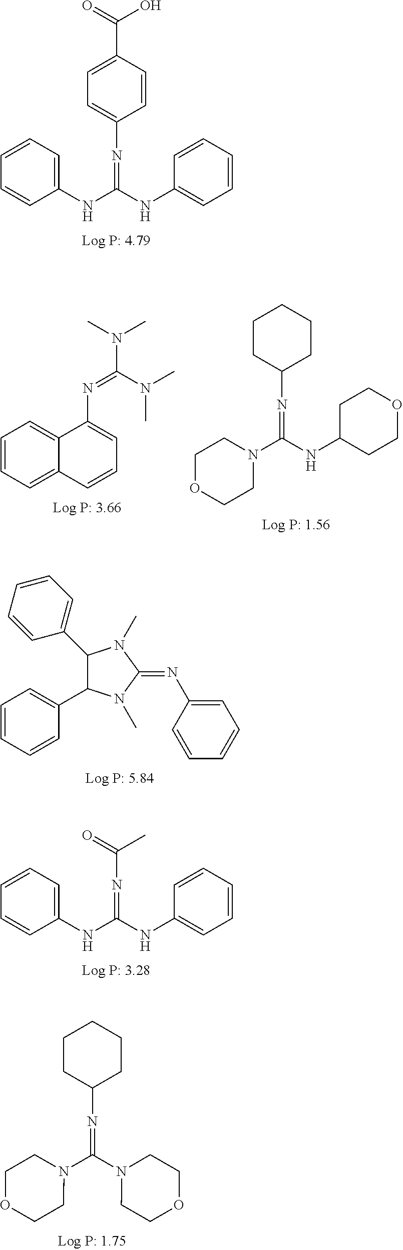

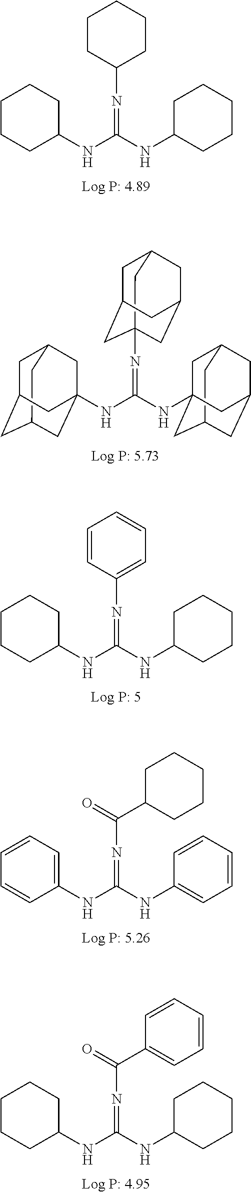

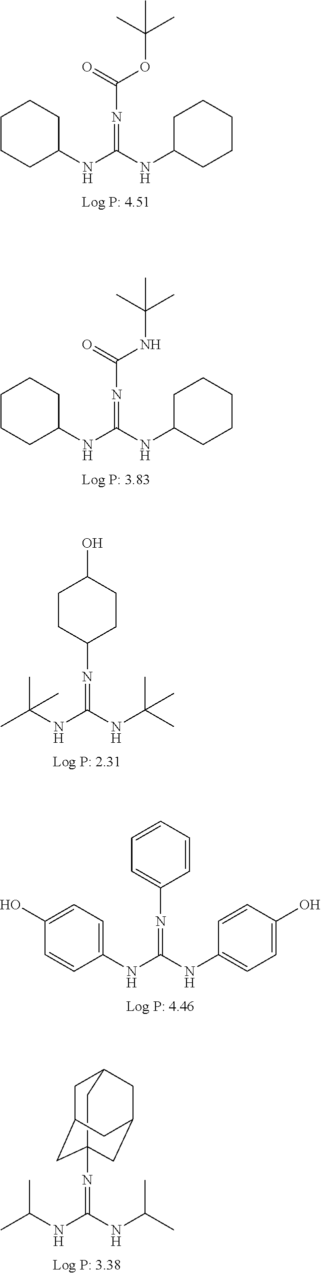

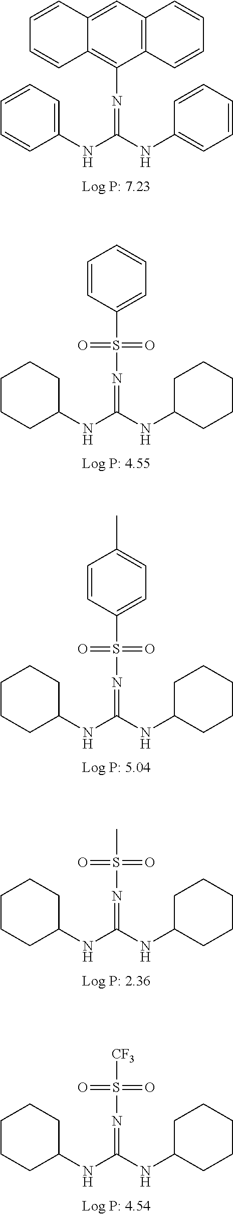

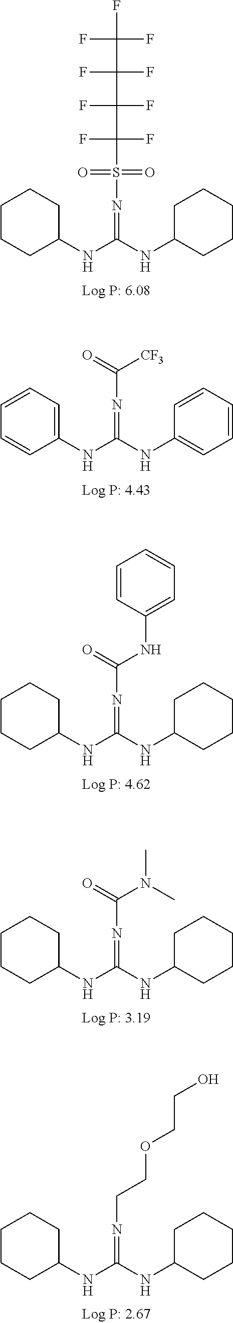

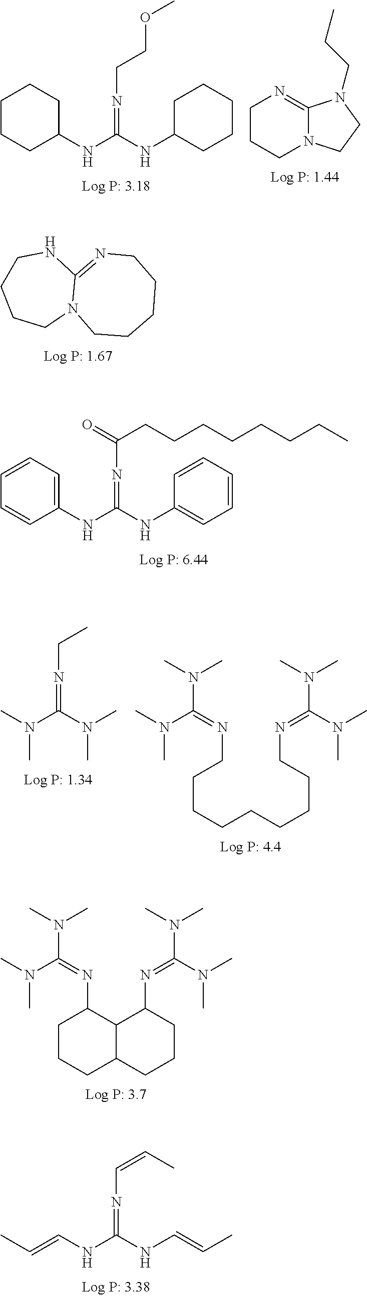

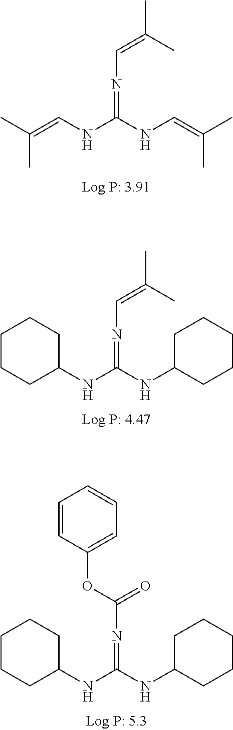

(5) Compound Having a Proton Acceptor Functional Group and Undergoing Decomposition Upon Irradiation with an Actinic Ray or Radiation to Generate a Compound Reduced in or Deprived of the Proton Acceptor Property or Changed to be Acidic from being Proton Acceptor-Functioning (PA)

The composition of the present invention may further contain, as a basic compound, a compound having a proton acceptor functional group and undergoing decomposition upon irradiation with an actinic ray or radiation to generate a compound reduced in or deprived of the proton acceptor property or changed to be acidic from being proton acceptor-functioning [hereinafter sometimes referred to as a “compound (PA)”].

The proton acceptor functional group is a functional group having a group or electron capable of electrostatically interacting with a proton and means, for example, a functional group having a macrocyclic structure such as cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formulae:

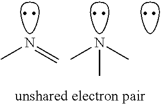

Preferred examples of the partial structure for the proton acceptor functional group include a crown ether structure, an aza-crown ether structure, a primary to tertiary amine structure, a pyridine structure, an imidazole structure and a pyrazine structure.

The compound (PA) decomposes upon irradiation with an actinic ray or radiation to generate a compound reduced in or deprived of the proton acceptor property or changed to be acidic from being proton acceptor-functioning. The expression “reduced in or deprived of the proton acceptor property or changed to be acidic from being proton acceptor-functioning” as used herein indicates a change in the proton acceptor property due to addition of a proton to the proton acceptor functional group and specifically means that when a proton adduct is produced from the proton acceptor functional group-containing compound (PA) and a proton, the equilibrium constant in the chemical equilibrium decreases.

The proton acceptor property can be confirmed by measuring the pH.

In the present invention, the acid dissociation constant pKa of the compound generated resulting from decomposition of the compound (PA) upon irradiation with an actinic ray or radiation preferably satisfies pKa<−1, more preferably −13<pKa<−1, still more preferably −13<pKa<−3.

In the present invention, the acid dissociation constant pKa indicates an acid dissociation constant pKa in an aqueous solution and is a value described, for example, in Kagaku Binran (Chemical Handbook) II (4th revised edition, compiled by The Chemical Society of Japan, Maruzen Co., Ltd., Maruzen (1993)). As this value is lower, the acid strength is higher. Specifically, the actual measurement can be performed by measuring the acid dissociation constant pKa at 25° C. in an aqueous infinite dilution solution. Alternatively, a value based on a data base containing Hammett's substituent constants and values known in publications can be determined by computation using the following Software Package 1. The pKa values referred to in the description of the present invention all are a value determined by computation using this software package.

Software Package 1: Advanced Chemistry Development (ACD/Labs) Software V8.14 for Solaris (1994-2007 ACD/Labs)

The compound (PA) decomposes upon irradiation with an actinic ray or radiation to produce, for example, a compound represented by the following formula (PA-1) as a proton adduct. The compound represented by formula (PA-1) is a compound having an acidic group together with a proton acceptor functional group and thereby being reduced in or deprived of the proton acceptor property or changed to be acidic from being proton acceptor-functioning as compared with the compound (PA).

Q-A-(X)ₙ—B—R (PA-1)

In formula (PA-1), Q represents —SO₃H, —CO₂H or —X₁NHX₂R_{f}, wherein R_{f} represents an alkyl group, a cycloalkyl group or an aryl group and each of X₁ and X₂ independently represents —SO₂— or —CO—.

A represents a single bond or a divalent linking group.

X represents —SO₂— or —CO—.

n represents 0 or 1.

B represents a single bond, an oxygen atom or —N(Rx)Ry—, wherein Rx represents a hydrogen atom or a monovalent organic group, Ry represents a single bond or a divalent organic group, and it may combine with Ry to form a ring or combine with R to form a ring.

R represents a monovalent organic group having a proton acceptor functional group.

Formula (PA-1) is described in detail below.

The divalent linking group in A is preferably a divalent linking group having a carbon number of 2 to 12, and examples thereof include an alkylene group and a phenylene group. An alkylene group having at least one fluorine atom is preferred, and the carbon number thereof is preferably from 2 to 6, more preferably from 2 to 4. The alkylene chain may contain a linking group such as oxygen atom and sulfur atom therein. The alkylene group is preferably an alkylene group where from 30 to 100% by number of hydrogen atoms are substituted for by a fluorine atom, more preferably an alkylene group where the carbon atom bonded to the Q site has a fluorine atom, still more preferably a perfluoroalkylene group, yet still more preferably a perfluoroethylene group, a perfluoropropylene group or a perfluorobutylene group.

The monovalent organic group in Rx preferably has a carbon number of 1 to 30, and examples thereof include an alkyl group, a cycloalkyl group, an aryl group, an aralkyl group and an alkenyl group. These groups may further have a substituent.

The alkyl group in Rx may have a substituent and is preferably a linear or branched alkyl group having a carbon number of 1 to 20, and the alkyl chain may contain an oxygen atom, a sulfur atom or a nitrogen atom therein.

The divalent organic group in Ry is preferably an alkylene group.

The ring structure which may be formed by combining Rx and Ry with each other includes a 5- to 10-membered ring and is preferably a 6-membered ring.

The alkyl group having a substituent includes particularly a group where a cycloalkyl group is substituted on a linear or branched alkyl group (for example, an adamantylmethyl group, an adamantylethyl group, a cyclohexylethyl group and a camphor residue).

The cycloalkyl group in Rx, which may have a substituent, is preferably a cycloalkyl group having a carbon number of 3 to 20 and may contain an oxygen atom in the ring.

The aryl group in Rx may have a substituent and is preferably an aryl group having a carbon number of 6 to 14.

The aralkyl group in Rx may have a substituent and is preferably an aralkyl group having a carbon number of 7 to 20.

The alkenyl group in Rx may have a substituent and includes, for example, a group having a double bond at an arbitrary position of the alkyl group described as Rx.

The proton acceptor functional group of R is as described above and includes a group containing, for example, a nitrogen-containing heterocyclic aromatic structure such as aza-crown ether, primary to tertiary amine, pyridine and imidazole.

The group containing such a structure preferably has a carbon number of 4 to 30, and examples thereof include an alkyl group, a cycloalkyl group, an aryl group, an aralkyl group and an alkenyl group.

Examples of the alkyl group, cycloalkyl group, aryl group, aralkyl group and alkenyl group in the proton acceptor functional group- or ammonium group-containing alkyl group, cycloalkyl group, aryl group, aralkyl group or alkenyl group of R are the same as those of the alkyl group, cycloalkyl group, aryl group, aralkyl group and alkenyl group described for Rx.

Examples of the substituent which the above-described groups each may have include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 20). As for the cyclic structure in the aryl group, cycloalkyl group and the like and the aminoacyl group, examples of the substituent further include an alkyl group (preferably having a carbon number of 1 to 20).

When B is —N(Rx)Ry—, R and Rx preferably combine together to form a ring. By forming a ring structure, the stability is enhanced and the composition using this compound is also increased in the storage stability. The number of carbons constituting the ring is preferably from 4 to 20, and the ring may be monocyclic or polycyclic and may contain an oxygen atom, a sulfur atom or a nitrogen atom therein.

Examples of the monocyclic structure include a 4-membered ring, a 5-membered ring, a 6-membered ring, a 7-membered ring and a 8-membered ring each containing a nitrogen atom. Examples of the polycyclic structure include a structure comprising a combination of two monocyclic structures or three or more monocyclic structures. The monocyclic structure and polycyclic structure each may have a substituent, and preferred examples of the substituent include a halogen atom, a hydroxyl group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 15), an acyloxy group (preferably having a carbon number of 2 to 15), an alkoxycarbonyl group (preferably having a carbon number of 2 to 15), and an aminoacyl group (preferably having a carbon number of 2 to 20). As for the cyclic structure in the aryl group, cycloalkyl group and the like, examples of the substituent further include an alkyl group (preferably having a carbon number of 1 to 15). As for the aminoacyl group, examples of the substituent further include an alkyl groups (preferably having a carbon number of 1 to 15).

R_{f} in —X₁NHX₂R_{f} represented by Q is preferably an alkyl group having a carbon number of 1 to 6, which may have a fluorine atom, more preferably a perfluoroalkyl group having a carbon number of 1 to 6. Also, at least one of X₁ and X₂ is preferably —SO₂—, and it is more preferred that both of X₁ and X₂ are —SO₂—.

Out of the compounds represented by formula (PA-1), the compound where the Q site is a sulfonic acid can be synthesized by using a general sulfonamidation reaction. For example, the compound may be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through a reaction with an amine compound.

The compound (PA) is preferably an ionic compound. The proton acceptor functional group may be contained in either the anion moiety or the cation moiety but is preferably contained in the anion moiety.

The compound (PA) is preferably a compound represented by any of the following formula (4) to (6):

R_{f}—X₂—N⁻—X₁-A-(X)ₙ—B—R[C]⁺ (4)

R—SO₃⁻[C]⁺ (5)

R—CO₂⁻[C]⁺ (6)

In formulae (4) to (6), A, X, n, B, R, Rf, X₁ and X₂ have the same meanings as in formula (PA-1).

C⁺ represents a counter cation.

The counter cation is preferably an onium cation. More specifically, preferred examples thereof include a sulfonium cation in S⁺(R₂₀₁′)(R₂₀₂′)(R₂₀₃′) of formula (ZI) and an iodonium cation in I⁺(R₂₀₄′)(R₂₀₅′) of formula (ZII), which are described with respect to the photo-acid generator.

Specific examples of compound (PA) are illustrated below, but the present invention is not limited thereto.

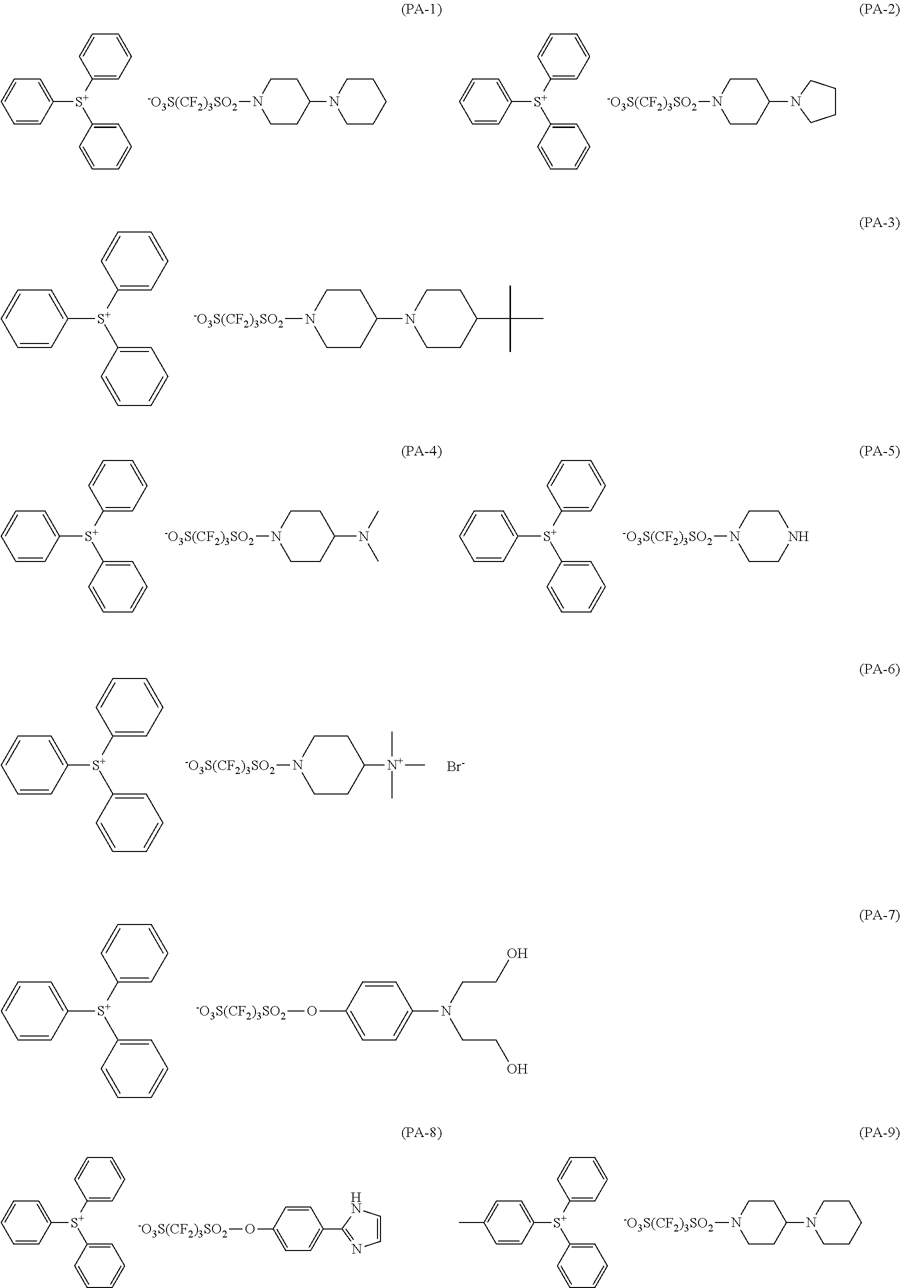

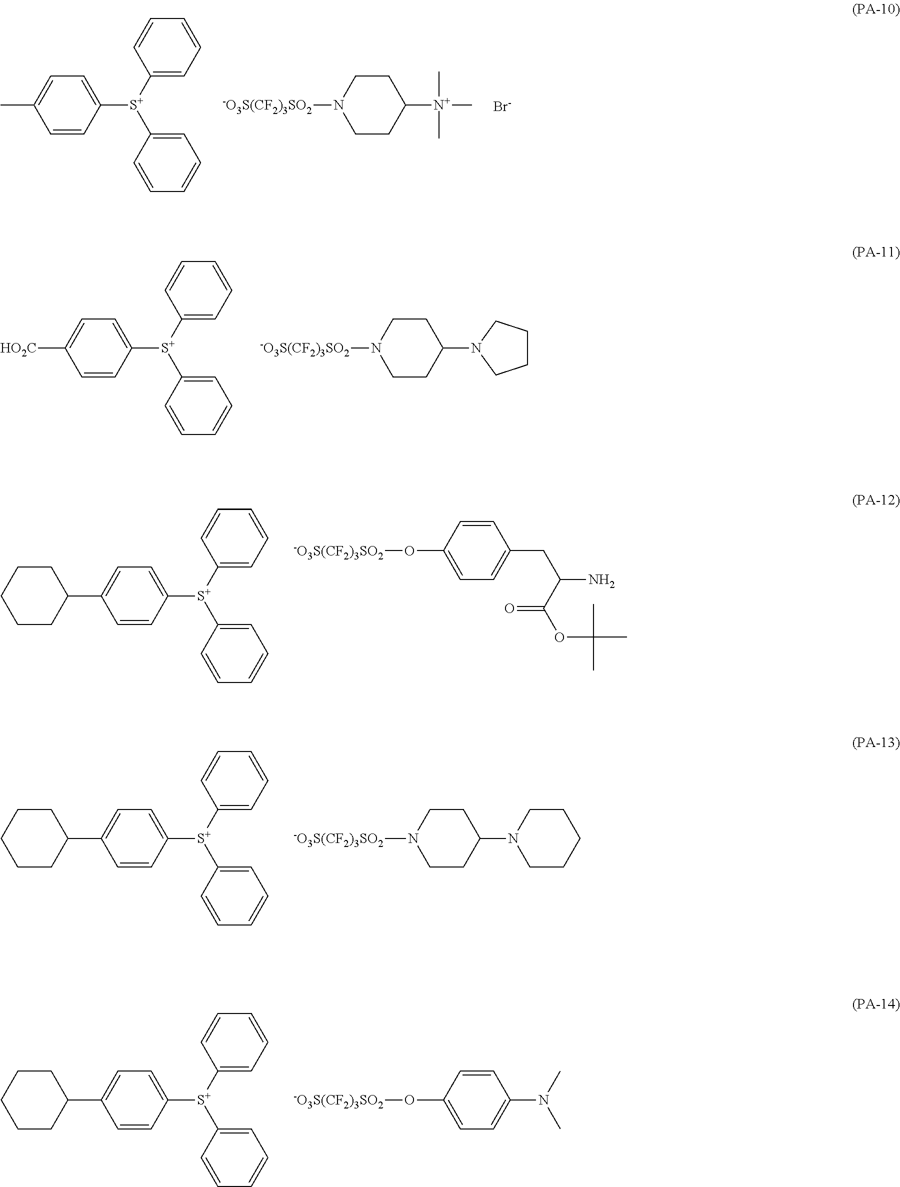

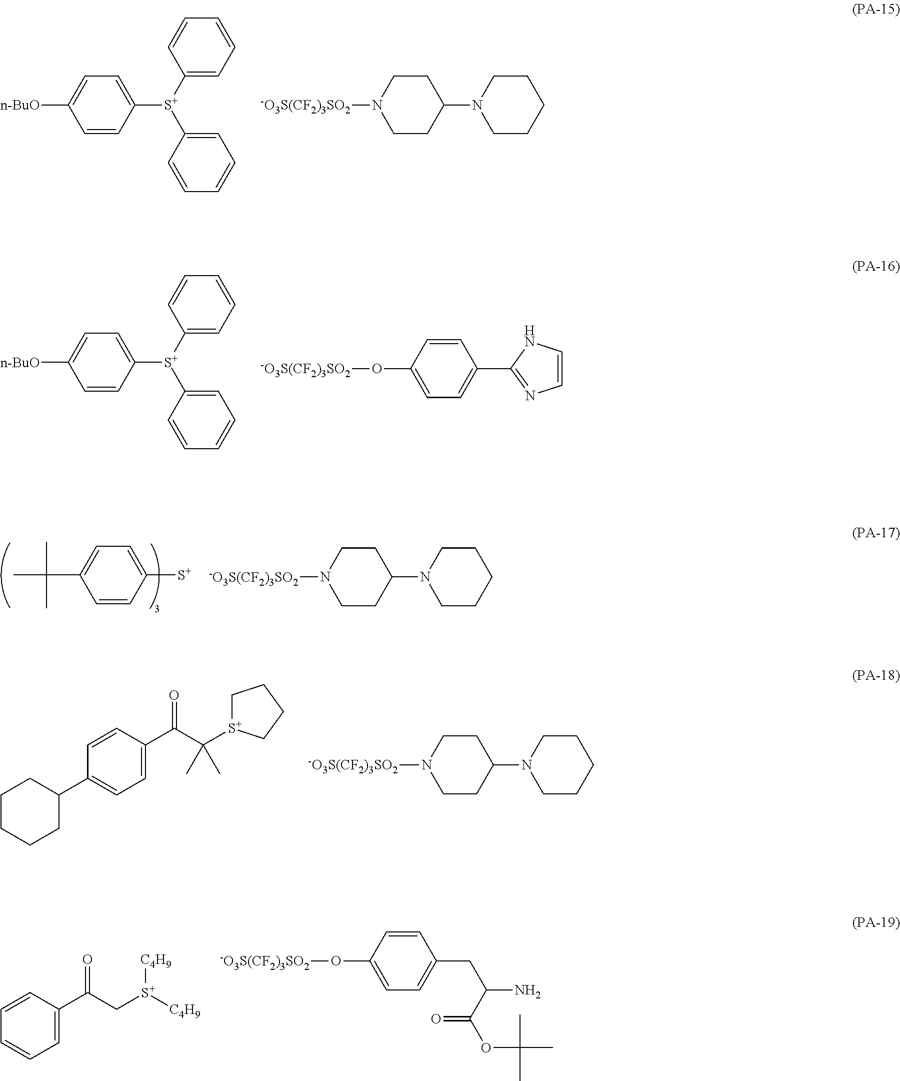

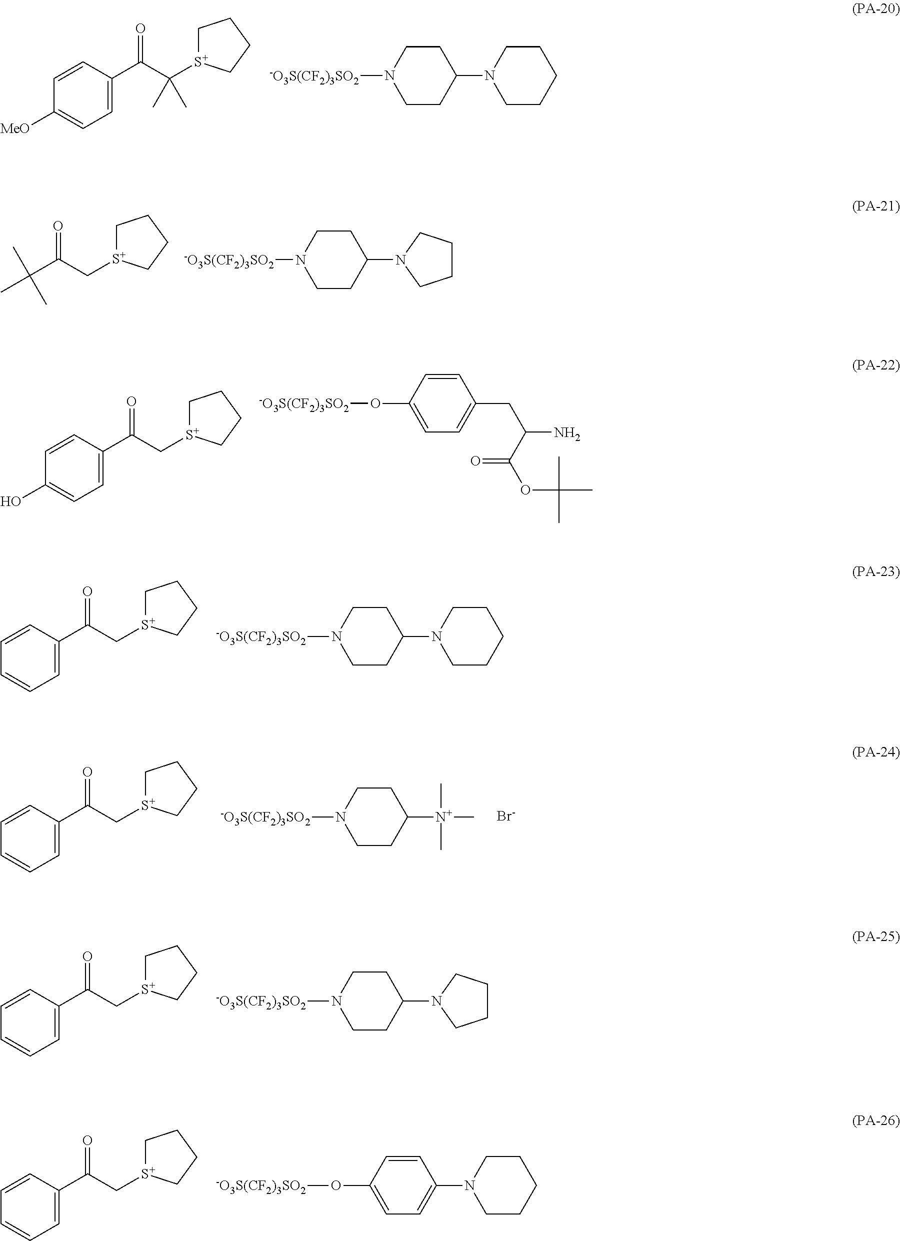

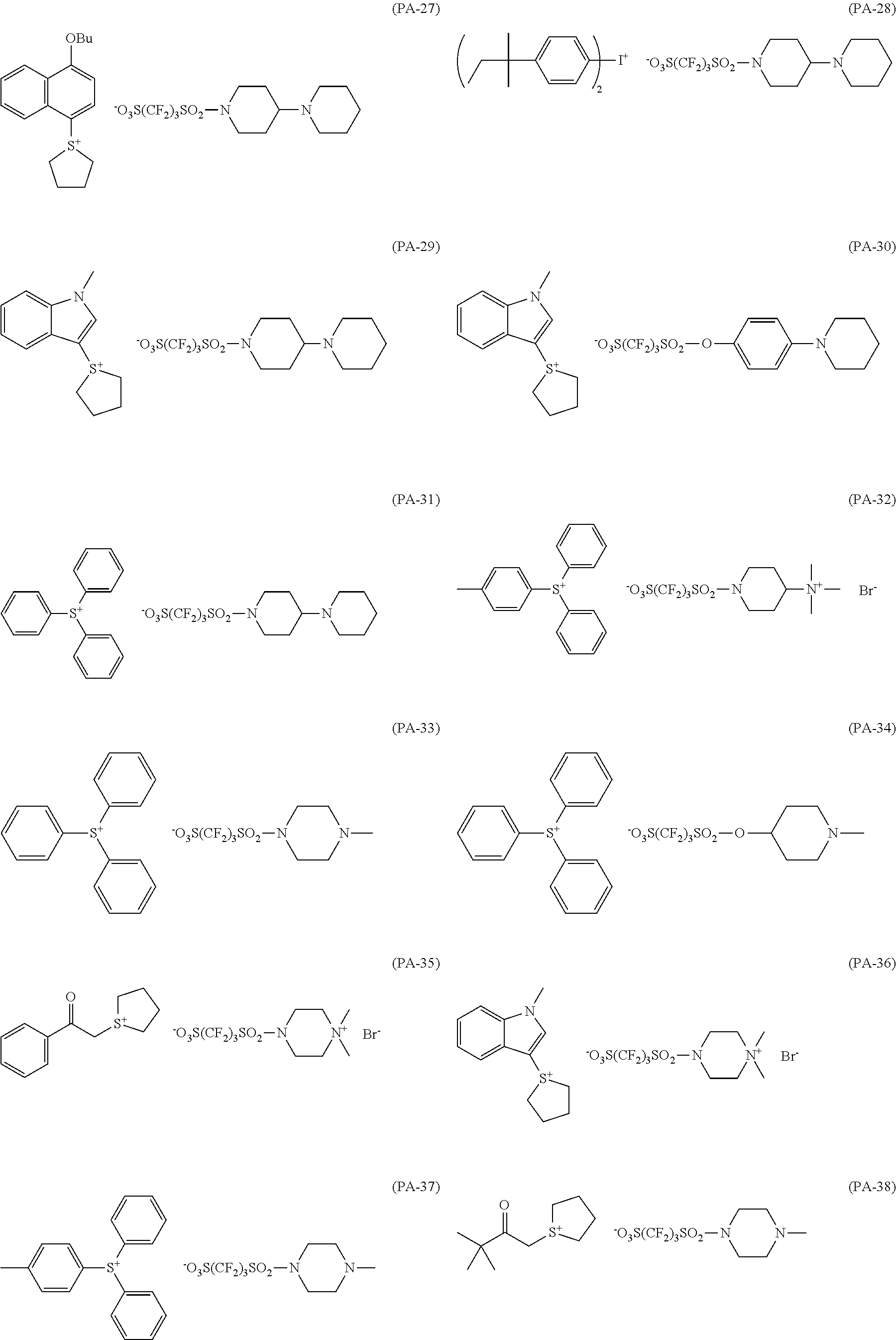

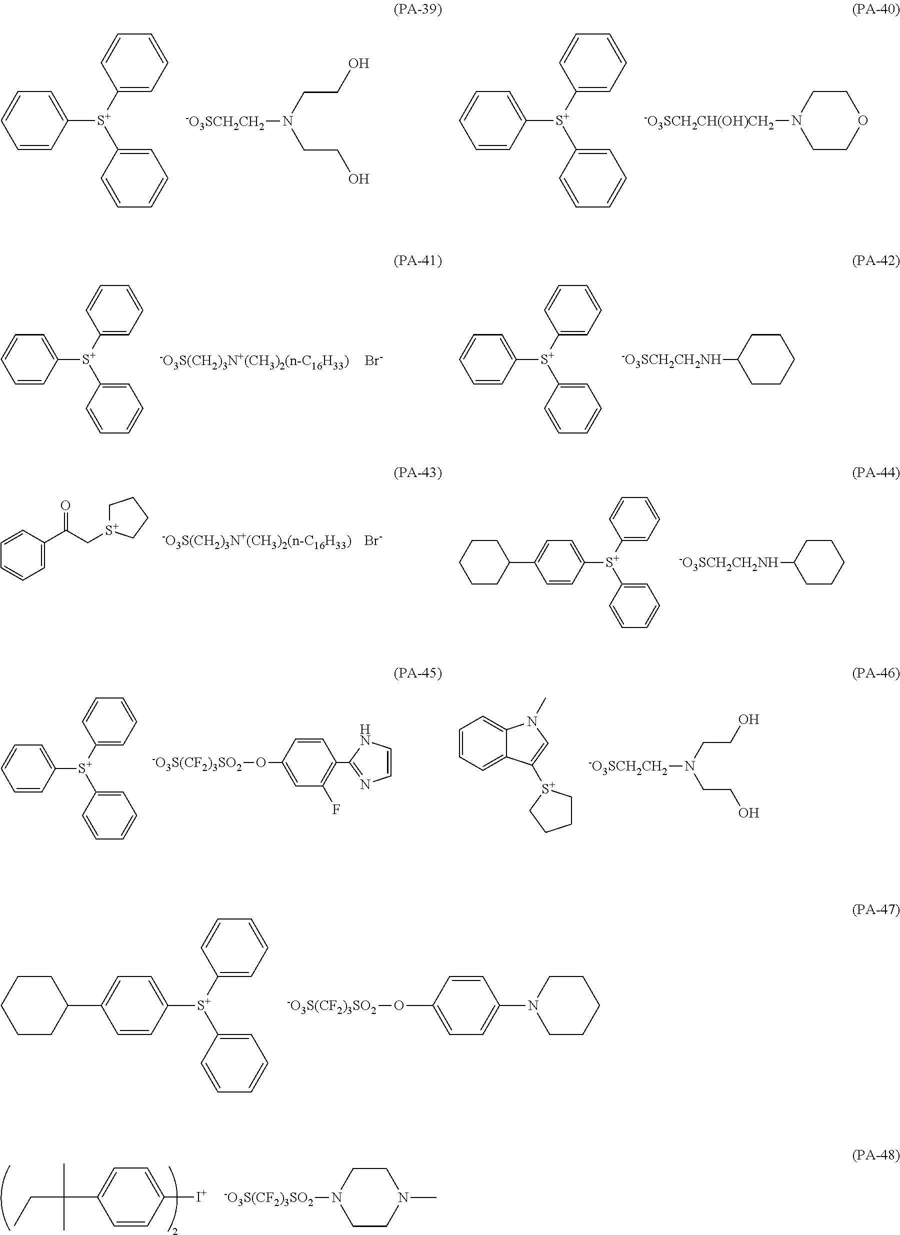

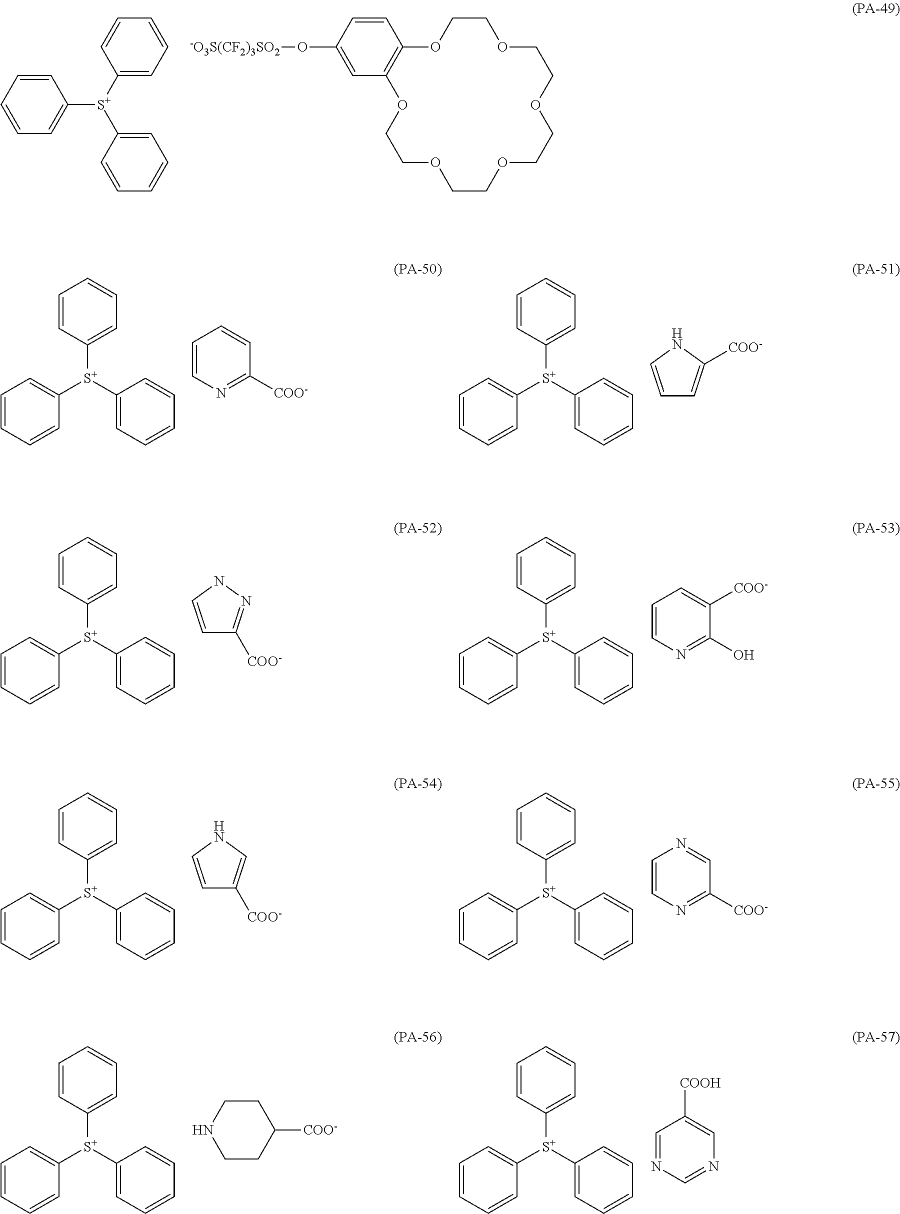

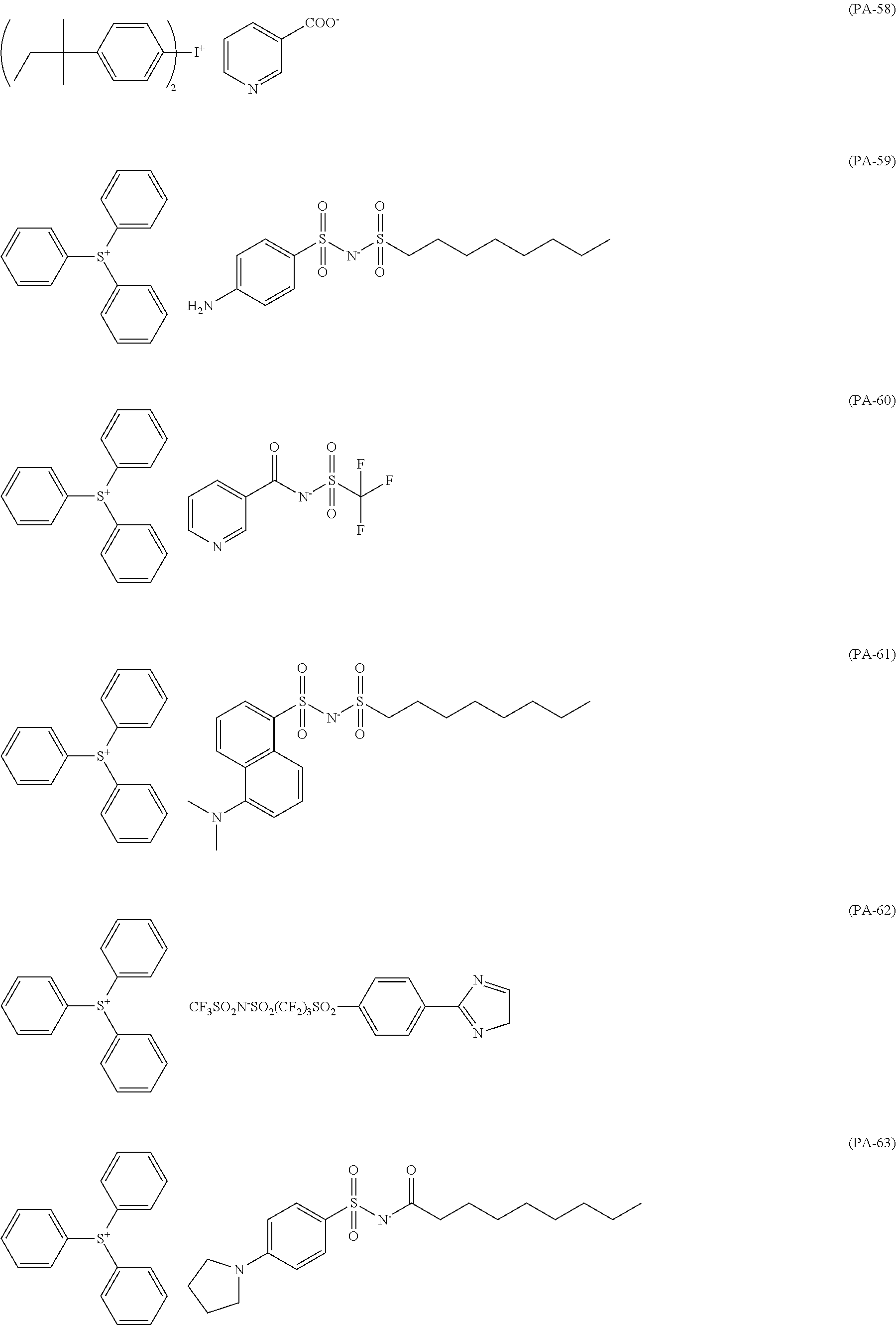

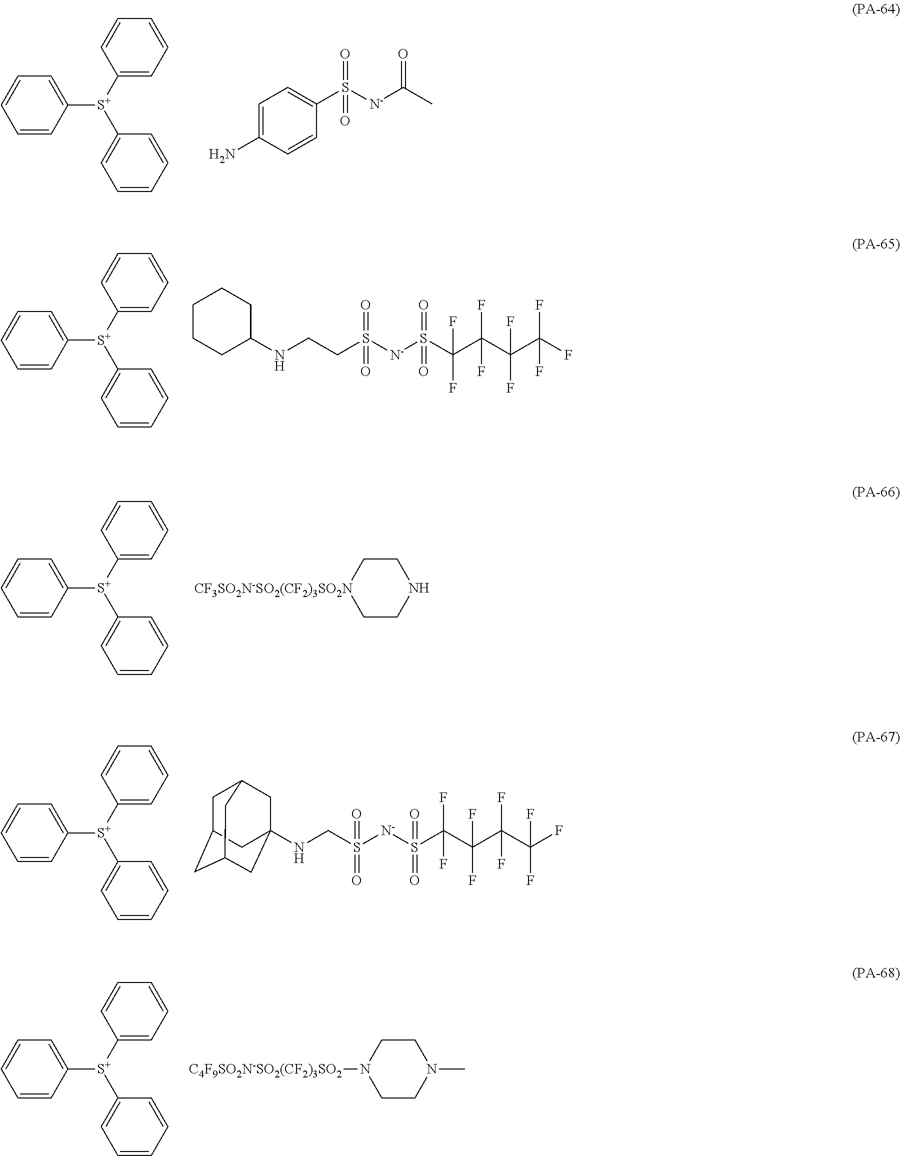

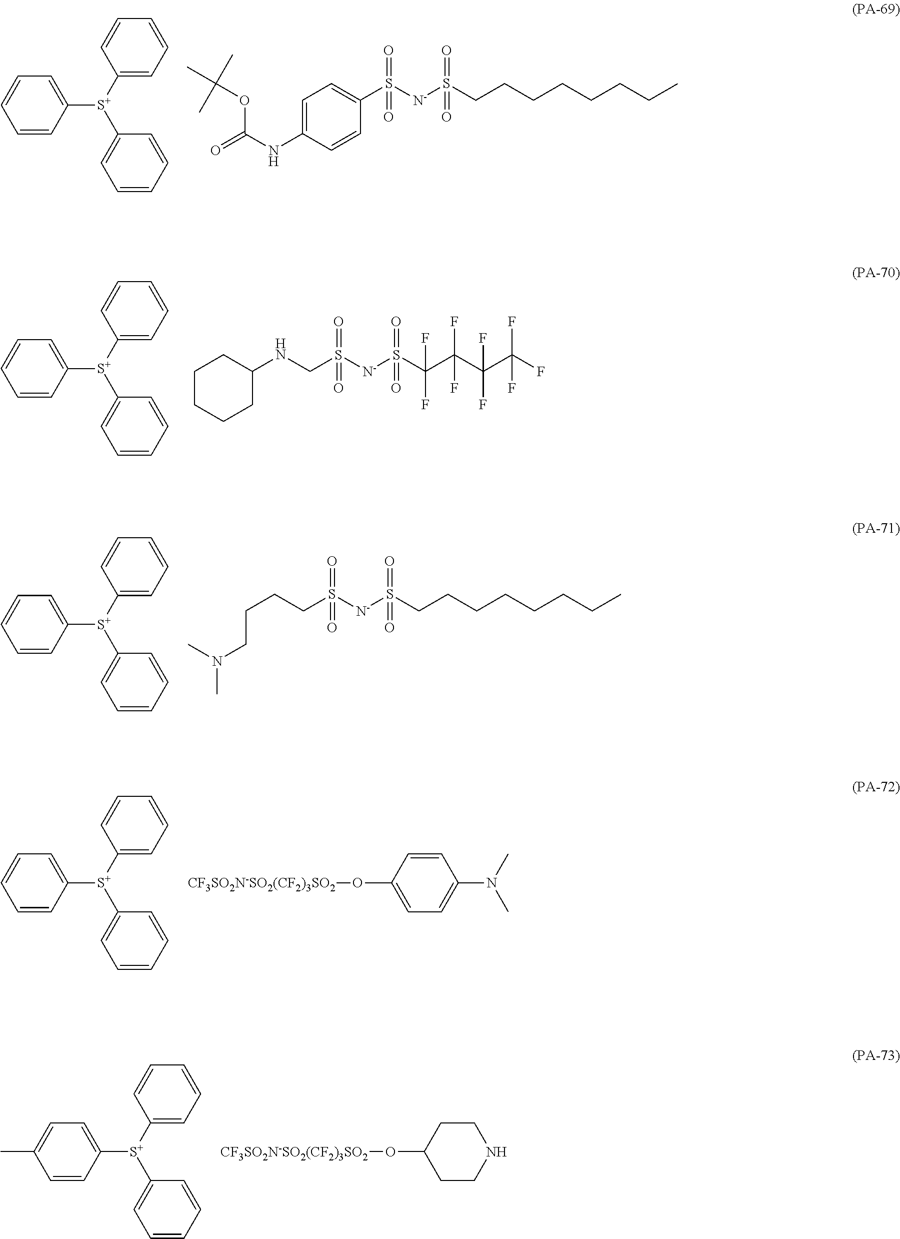

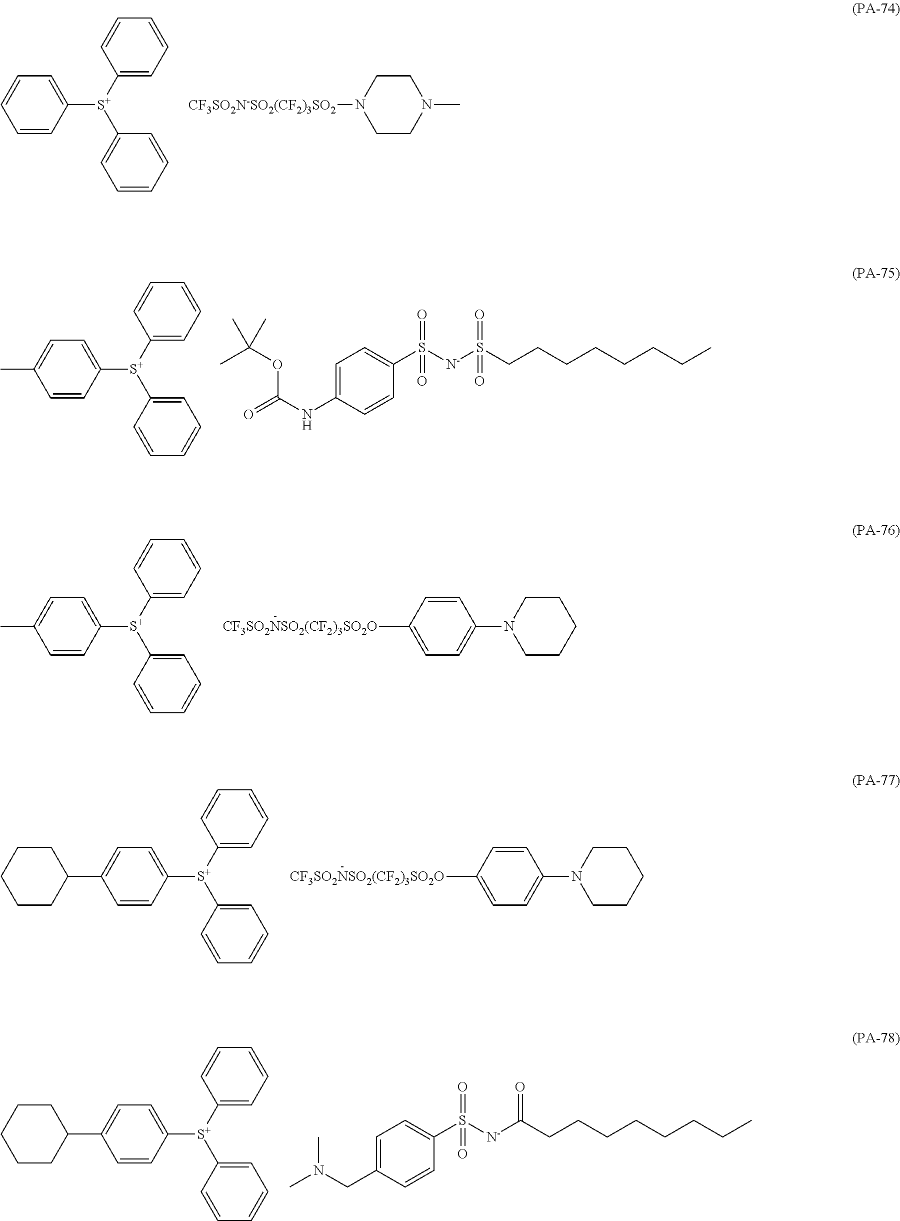

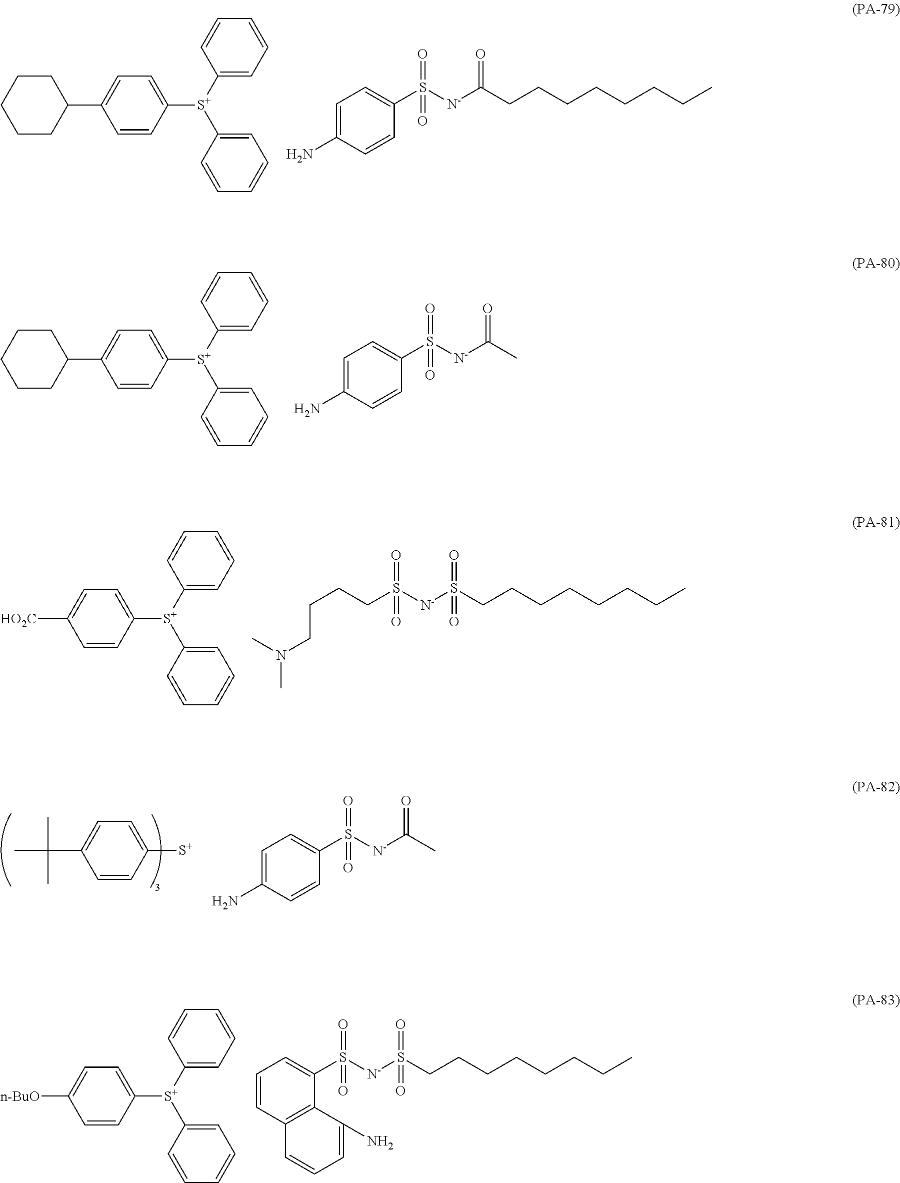

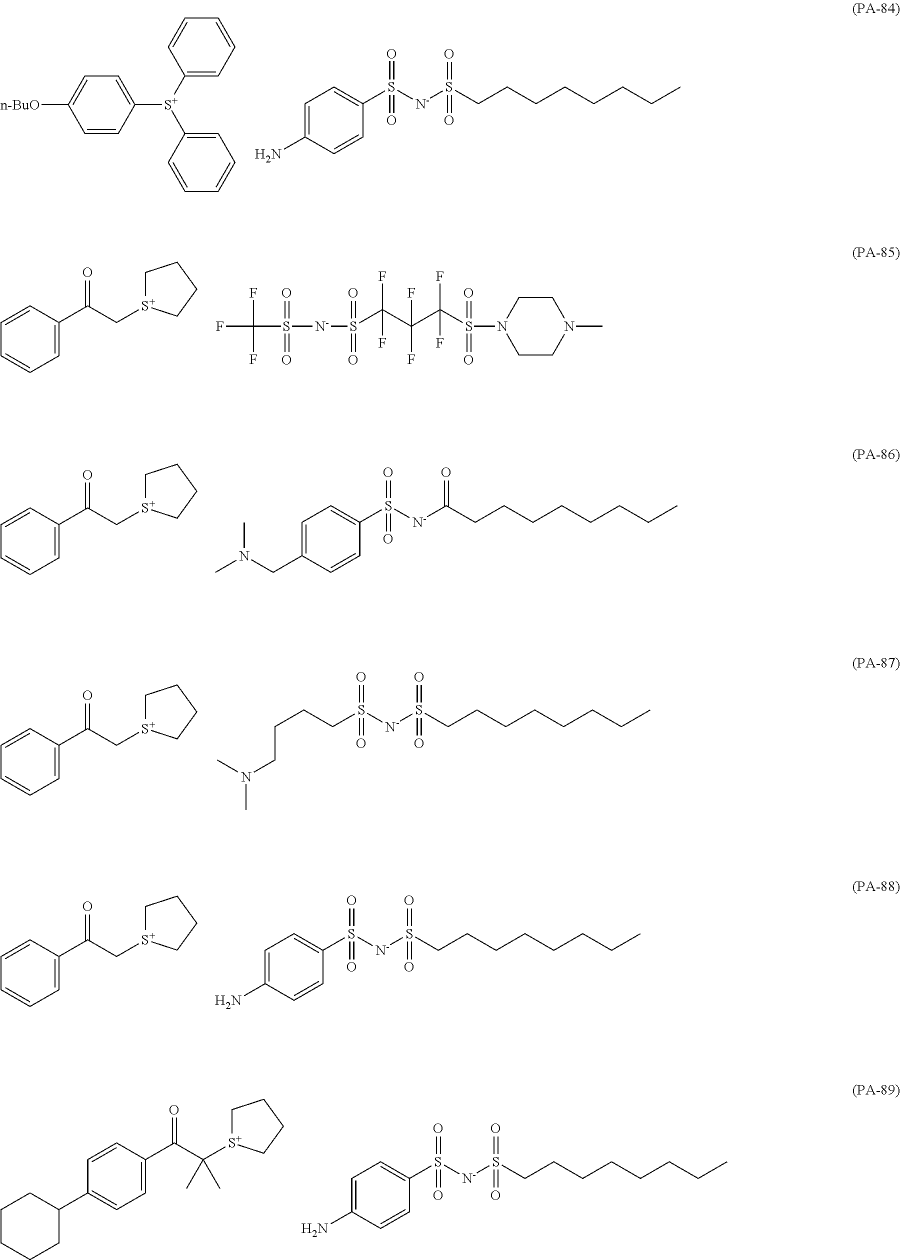

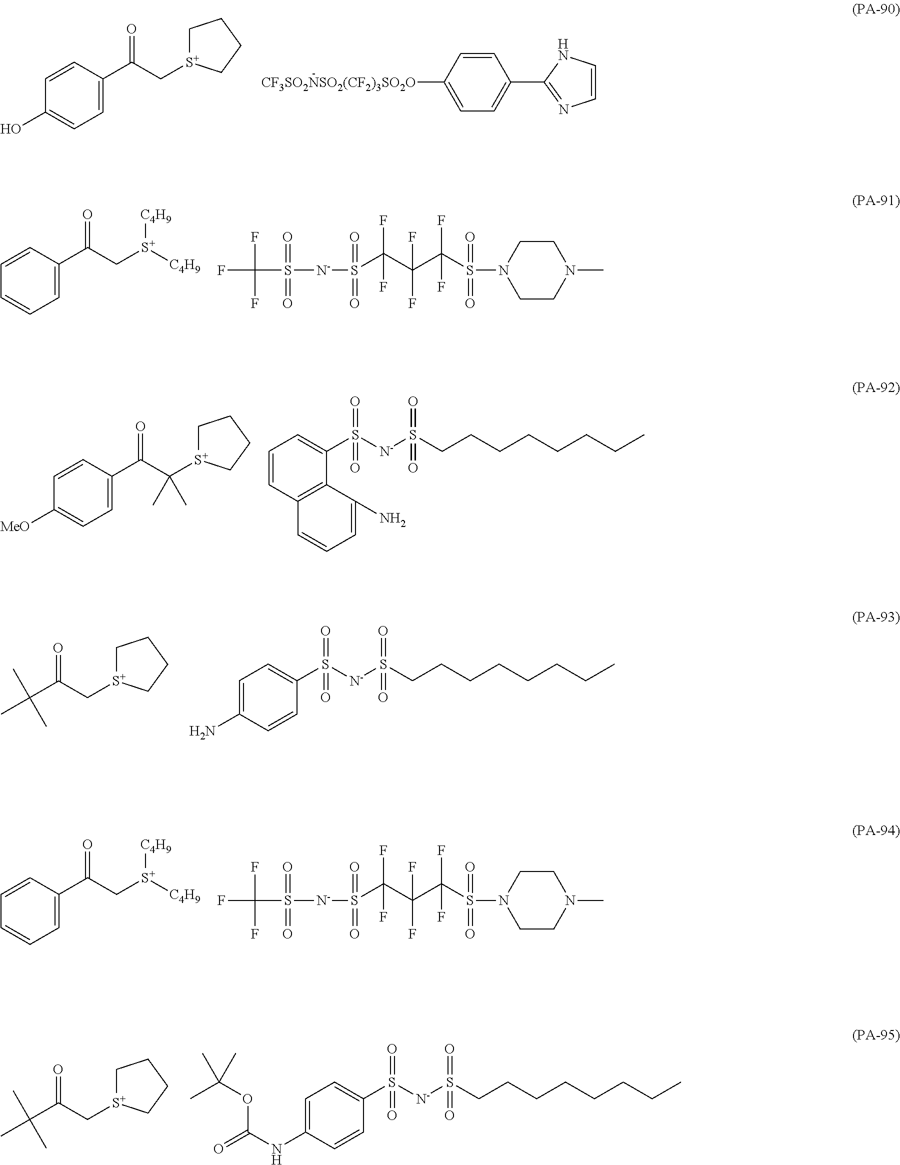

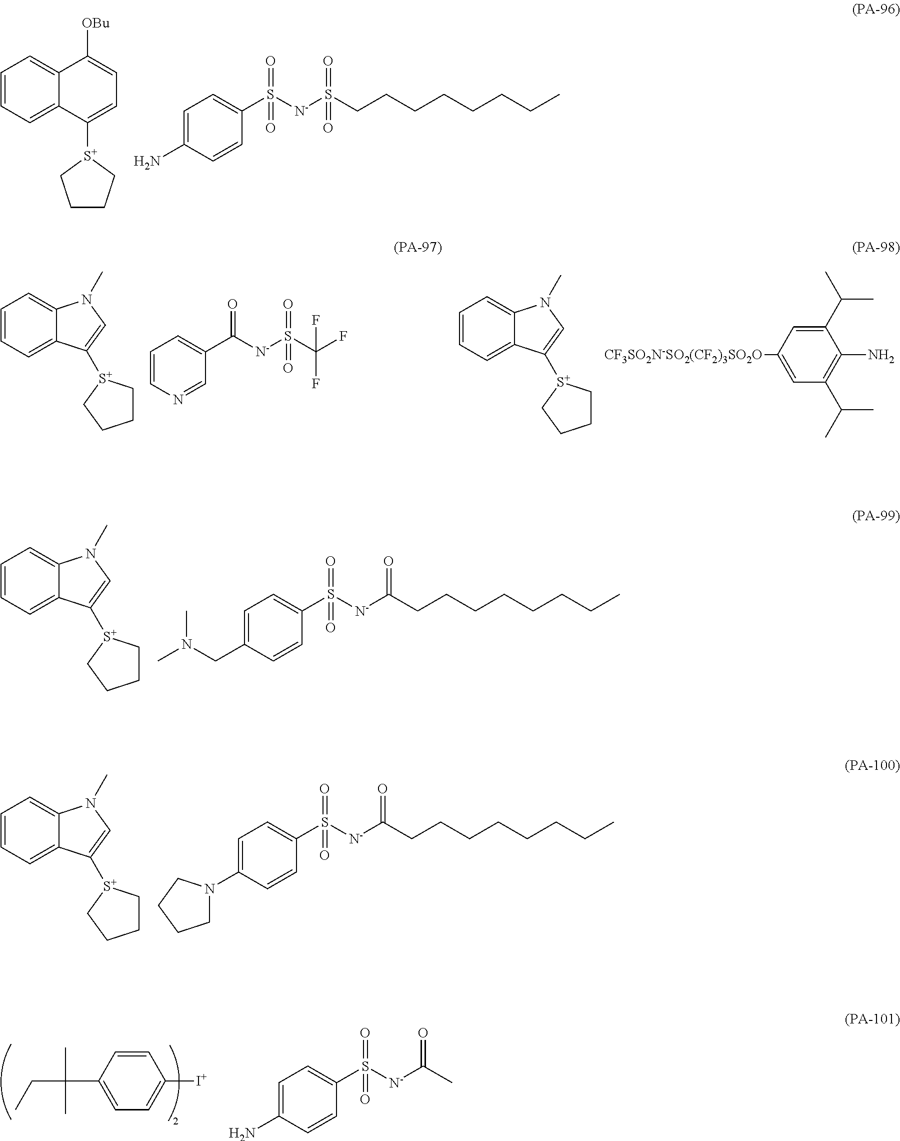

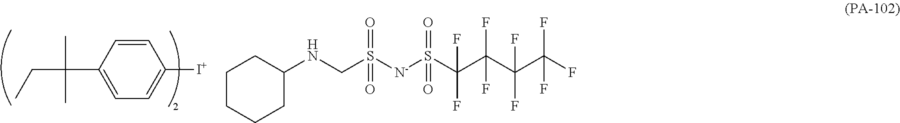

In the present invention, a compound (PA) other than the compound capable of generating a compound represented by formula (PA-1) can be also appropriately selected. For example, a compound that is an ionic compound and has a proton acceptor site in the cation moiety may be used. More specifically, examples of such a compound include a compound represented by the following formula (7):

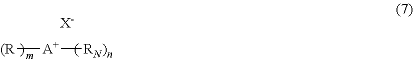

In the formula, A represents a sulfur atom or an iodine atom.

m represents 1 or 2, n represents 1 or 2, provided that when A is a sulfur atom, m+n=3 and when A is an iodine atom, m+n=2.

R represents an aryl group.

R_{N} represents an aryl group substituted with a proton acceptor functional group.

X⁻ represents a counter anion.

Specific examples of X⁻ are the same as those of X⁻ in formula (ZI).

Specific preferred examples of the aryl group of R and R_{N} include a phenyl group.

Specific examples of the proton acceptor functional group contained in R_{N} are the same as those of the proton acceptor functional group described above in formula (PA-1).

In the composition of the present invention, the ratio of the compound (PA) blended in the entire composition is preferably from 0.1 to 10 mass %, more preferably from 1 to 8 mass %, based on the entire solid content of the composition.

Other examples of the compound which can be used in the composition of the present invention include the compounds synthesized in Examples of JP-A-2002-363146 and the compounds described in paragraph 0108 of JP-A-2007-298569.

A photosensitive basic compound may be also used as the basic compound. Examples of the photosensitive basic compound which can be used include the compounds described in JP-T-2003-524799 (the term “JP-T” as used herein means a “published Japanese translation of a PCT patent application”) and J. Photopolym. Sci. & Tech., Vol. 8, pp. 543-553 (1995).

The molecular weight of the basic compound is usually from 100 to 1,500, preferably from 150 to 1,300, more preferably from 200 to 1,000.

One of these basic compounds may be used alone, or two or more kinds thereof may be used in combination.

In the case where the composition of the present invention contains a basic compound, the content thereof is preferably from 0.01 to 8.0 mass %, more preferably from 0.1 to 5.0 mass %, still more preferably from 0.2 to 4.0 mass %, based on the entire solid content of the composition.

The molar ratio of the basic compound to the photo-acid generator is preferably from 0.01 to 10, more preferably from 0.05 to 5, still more preferably from 0.1 to 3.

If this molar ratio is excessively large, there is a case that sensitivity and/or resolution may be reduced. If this molar ratio is excessively small, thinning of the pattern may occur between exposure and heating (post-baking). The molar ratio is more preferably from 0.05 to 5, still more preferably from 0.1 to 3. The photo-acid generator in the molar ratio above is based on the total amount of the repeating unit (B) in the resin and the photo-acid generator which may be further contained in the resin.

### (Surfactant)

The composition of the present invention may further contain a surfactant. The surfactant is preferably a fluorine-containing and/or silicon-containing surfactant.

Examples of the fluorine-containing and/or silicon-containing surfactant include Megaface F176 and Megaface R08 produced by Dainippon Ink & Chemicals, Inc.; PF656 and PF6320 produced by OMNOVA; Troysol S-366 produced by Troy Chemical; Florad FC430 produced by Sumitomo 3M Inc.; and Polysiloxane Polymer KP-341 produced by Shin-Etsu Chemical Co., Ltd.

A surfactant other than the fluorine-containing and/or silicon-containing surfactant may be also used. Examples of this surfactant include a nonionic surfactant such as polyoxyethylene alkyl ethers and polyoxyethylene alkylaryl ethers.

In addition, known surfactants may be appropriately used. Examples of the surfactant which can be used include the surfactants described in paragraph [0273] et seq. of U.S. Patent Application Publication No. 2008/0248425A1.

One kind of a surfactant may be used alone, or two or more kinds of surfactants may be used in combination.

In the case where the composition of the present invention further contains a surfactant, the amount used thereof is preferably from 0.0001 to 2 mass %, more preferably from 0.001 to 1 mass %, based on the entire solid content of the composition.

### (Dye)

The composition of the present invention may further contain a dye.

Preferred examples of the dye include an oil dye and a basic dye. Specific examples thereof include Oil Yellow #101, Oil Yellow #103, Oil Pink #312, Oil Green BG, Oil Blue BOS, Oil Blue #603, Oil Black BY, Oil Black BS, Oil Black T-505 (all produced by Orient Chemical Industries, Ltd.), Crystal Violet (C142555), Methyl Violet (C142535), Rhodamine B (C145170B), Malachite Green (C142000), and Methylene Blue (C152015).

### (Photo-Base Generator)

The composition of the present invention may further contain a photo-base generator. When a photo-base generator is contained, a more excellent pattern can be formed.

Examples of the photo-base generator include the compounds described in JP-A-4-151156, JP-A-4-162040, JP-A-5-197148, JP-A-5-5995, JP-A-6-194834, JP-A-8-146608, JP-A-10-83079 and European Patent No. 622682. Specific preferred examples of the photo-base generator include 2-nitrobenzyl carbamate, 2,5-dinitrobenzylcyclohexyl carbamate, N-cyclohexyl-4-methylphenylsulfonamide and 1,1-dimethyl-2-phenylethyl-N-isopropyl carbamate.

### (Antioxidant)

The composition of the present invention may further contain an antioxidant. When an antioxidant is contained, the organic material can be prevented from oxidation in the presence of oxygen.

Examples of the antioxidant include a phenol-based antioxidant, an antioxidant composed of an organic acid derivative, a sulfur-containing antioxidant, a phosphorus-based antioxidant, an amine-based antioxidant, an antioxidant composed of an amine-aldehyde condensate, and an antioxidant composed of an amine-ketone condensate. Out of these antioxidants, a phenol-based antioxidant or an antioxidant composed of an organic acid derivative is preferably used. When such an antioxidant is used, the function as an antioxidant can be brought out without deteriorating the performance of the composition,

Examples of the phenol-based antioxidant which can be used include substituted phenols, and bis-, tris- and poly-phenols.

Examples of the substituted phenols include 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butylhydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-a-dimethylamino-p-cresol, 6-(4-hydroxy-3,5-di-tert-butylanilino)-2,4-bis-octyl-thio-1,3,5-triazine, n-octadecyl-3-(4′-hydroxy-3′,5′-di-tert-butyl-phenyl)propionate, octylated phenol, aralkyl-substituted phenols, alkylated p-cresol, and hindered phenol.

Examples of the bis-, tris- and poly-phenols include 4,4′-dihydroxydiphenyl, methylenebis(dimethyl-4,6-phenol), 2,2′-methylene-bis-(4-methyl-6-tert-butylphenol), 2,2′-methylene-bis-(4-methyl-6-cyclohexyl-phenol), 2,2′-methylene-bis-(4-ethyl-6-tert-butylphenol), 4,4′-methylene-bis-(2,6-di-tert-butylphenol), 2,2′-methylene-bis-(6-alphamethyl-benzyl-p-cresol), methylene-crosslinked polyhydric alkylphenol, 4,4′-butylidenebis-(3-methyl-6-tert-butylphenol), 1,1-bis-(4-hydroxyphenye-cyclohexane, 2,2′-dihydroxy-3,3′-di-α-methylcyclohexyl)-5,5′-dimethyldiphenylmethane, alkylated bisphenol, hindered bisphenol, 1,3,5-trimethyl-2,4,6-tris(3,5-di-tert-butyl-4-hydroxybenzyl)benzene, tris(2-methyl-4-hydroxy-5-tert-butylphenyl)butane, tetrakis-[methylene-3-(3′,5′-di-tert-butyl-4′-hydroxyphenyl)propionate]methane.

Preferred antioxidants include 2,6-di-tert-butyl-4-methylphenol, 4-hydroxymethyl-2,6-di-tert-butylphenol, 2,2′-methylenebis(4-methyl-6-tert-butylphenol), butylhydroxyanisole, tert-butylhydroquinone, 2,4,5-trihydroxybutyrophenone, nordihydro-guaiaretic acid, propyl gallate, octyl gallate, lauryl gallate, and isopropyl citrate. Among these, 2,6-di-tert-butyl-4-methylphenol, 4-hydroxymethyl-2,6-di-tert-butylphenol, butylhydroxyanisole and tert-butylhydroquinone are more preferred, and 2,6-di-tert-butyl-4-methylphenol and 4-hydroxymethyl-2,6-di-tert-butylphenol are still more preferred.

One kind of an antioxidant may be used alone, or two or more kinds of antioxidants may be used in combination.

In the case where the composition of the present invention contains an antioxidant, the amount added thereof is preferably 1 ppm or more, more preferably 5 ppm or more, still more preferably 10 ppm or more, yet still more preferably 50 ppm or more, even yet still more preferably 100 ppm or more, and most preferably from 100 to 1,000 ppm.

### (Solvent)

The composition of the present invention may further contain a solvent.

As the solvent, an organic solvent is typically used. Examples of the organic solvent include an alkylene glycol monoalkyl ether carboxylate, an alkylene glycol monoalkyl ether, an alkyl lactate, an alkyl alkoxypropionate, a cyclic lactone (preferably having a carbon number of 4 to 10), a monoketone compound (preferably having a carbon number of 4 to 10) which may contain a ring, an alkylene carbonate, an alkyl alkoxyacetate, and an alkyl pyruvate.

Preferred examples of the alkylene glycol monoalkyl ether carboxylate include propylene glycol monomethyl ether acetate (PGMEA, another name: 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of the alkylene glycol monoalkyl ether include propylene glycol monomethyl ether (PGME, another name: 1-methoxy-2-propanol), propylene glycol monoethyl ether, propylene glycol monopropyl ether, propylene glycol monobutyl ether, ethylene glycol monomethyl ether, and ethylene glycol monoethyl ether.

Examples of the alkyl lactate include methyl lactate, ethyl lactate, propyl lactate and butyl lactate.

Examples of the alkyl alkoxypropionate include ethyl 3-ethoxypropionate, methyl 3-methoxypropionate, methyl 3-ethoxypropionate and ethyl 3-methoxypropionate.

Examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

Examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

Examples of the alkylene carbonate include propylene carbonate, vinylene carbonate, ethylene carbonate and butylene carbonate.

Examples of the alkyl alkoxyacetate include 2-methoxyethyl acetate, 2-ethoxyethyl acetate, 2-(2-ethoxyethoxy)ethyl acetate, 3-methoxy-3-methylbutyl acetate and 1-methoxy-2-propyl acetate.

Examples of the alkyl pyruvate include methyl pyruvate, ethyl pyruvate and propyl pyruvate.

As the solvent, a solvent having a boiling point of 130° C. or more at ordinary temperature under atmospheric pressure is preferably used. Specific examples thereof include cyclopentanone, γ-butyrolactone, cyclohexanone, ethyl lactate, ethylene glycol monoethyl ether acetate, PGMEA, ethyl 3-ethoxypropionate, ethyl pyruvate, 2-ethoxyethyl acetate, 2-(2-ethoxyethoxy)ethyl acetate and propylene carbonate.

As for these solvents, one kind of a solvent may be used alone, or two or more kinds of solvents may be used in combination. In the latter case, a mixed solvent of a solvent containing a hydroxyl group and a solvent not containing a hydroxyl group is preferably used.

Examples of the solvent containing a hydroxyl group include ethylene glycol, ethylene glycol monomethyl ether, ethylene glycol monoethyl ether, propylene glycol, PGME, propylene glycol monoethyl ether and ethyl lactate. Among these, PGME and ethyl lactate are preferred.

Examples of the solvent not containing a hydroxyl group include PGMEA, ethyl ethoxypropionate, 2-heptanone, γ-butyrolactone, cyclohexanone, butyl acetate, N-methylpyrrolidone, N,N-dimethylacetamide and dimethylsulfoxide. Among these, propylene glycol monomethyl ether acetate, ethyl ethoxypropionate, 2-heptanone, γ-butyrolactone, cyclohexanone and butyl acetate are preferred, and PGMEA, ethyl ethoxypropionate and 2-heptanone are more preferred.

In the case of using a mixed solvent of a solvent containing a hydroxyl group and a solvent not containing a hydroxyl group, the mass ratio therebetween is preferably from 1/99 to 99/1, more preferably from 10/90 to 90/10, still more preferably from 20/80 to 60/40.

Incidentally, when a mixed solvent containing 50 mass % or more of a hydroxyl group-free solvent is used, particularly excellent coating uniformity can be achieved. Also, the solvent is preferably a mixed solvent of PGMEA and one or more kinds of other solvents.

The content of the solvent in the composition of the present invention may be appropriately adjusted according to the desired film thickness or the like, but the composition is generally prepared such that the entire solid content concentration of the composition becomes from 0.5 to 30 mass %, preferably from 1.0 to 20 mass %, more preferably from 1.5 to 10 mass %.

### <Pattern Forming Method>

The present invention relates to a resist film formed using the above-described composition of the present invention.

Also, the pattern forming method of the present invention comprises a step of exposing and developing the resist film above.

The composition of the present invention is typically used as follows. That is, the composition of the present invention is typically coated on a support such as substrate to form a film.

The thickness of the film is preferably from 0.02 to 0.1 μm. The method for coating the composition on a substrate is preferably spin coating, and the spinning speed is preferably from 1,000 to 3,000 rpm.

For example, the composition is coated on such a substrate (e.g., silicon/silicon dioxide-coated substrate, silicon nitride and chromium-deposited quartz substrate) as used in the production of a precision integrated circuit device, an imprint mold or the like, by using a spinner, a coater or the like. Thereafter, the coating is dried to obtain an actinic ray-sensitive or radiation-sensitive film (hereinafter, sometimes referred to as a “resist film”). Incidentally, a known antireflection film may be previously provided by coating.

Subsequently, the resist film is irradiated with an actinic ray or radiation, then preferably baked (usually at 80 to 150° C., preferably at 90 to 130° C.), and developed. By performing baking, a more excellent pattern can be obtained.

Examples of the actinic ray or radiation include infrared light, visible light, ultraviolet light, far ultraviolet light, X-ray and electron beam. An actinic ray or radiation having, for example, a wavelength of 250 nm or less, particularly 220 nm or less, is preferred. Such an actinic ray or radiation includes, for example, KrF excimer laser (248 nm), ArF excimer laser (193 nm), F₂ excimer laser (157 nm), X-ray and electron beam. The actinic ray or radiation is preferably, for example, KrF excimer laser, electron beam, X-ray or EUV light, more preferably electron beam, X-ray or EUV light.

That is, the present invention also relates to an actinic ray-sensitive or radiation-sensitive resin composition for KrF excimer laser, electron beam, X-ray or EUV light (preferably electron beam, X-ray or EUV light).

In the development step, an alkali developer is usually used.

Examples of the alkali developer include an alkaline aqueous solution containing inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, or cyclic amines such as pyrrole and piperidine.

In the alkali developer, alcohols and a surfactant may be added in an appropriate amount.

The concentration of the alkali developer is usually from 0.1 to 20 mass %. The pH of the alkali developer is usually from 10.0 to 15.0.

Also, an imprint mold may be produced using the composition of the present invention. For details, please refer to, for example, Japanese Patent 4,109,085, JP-A-2008-162101, and “Yoshihiko Hirai (compiler), Nanoimprint no Kiso to Gijutsu Kaihatsu•Oyo Tenkai-Nanoimprint no Kiban Gijutsu to Saishin no Gijutsu Tenkai (Basic and Technology Expansion•Application Development of Nanoimprint-Substrate Technology of Nanoimprint and Latest Technology Expansion), Frontier Shuppan”.

### EXAMPLES

The present invention is described in greater detail below, but the contents of the present invention are not limited thereto.

### <Resin>

Resins P-1 to P-48 illustrated above were synthesized as follows.

### Synthesis Example 1

### Resin P-14

Resin P-14 was synthesized according to the following scheme.

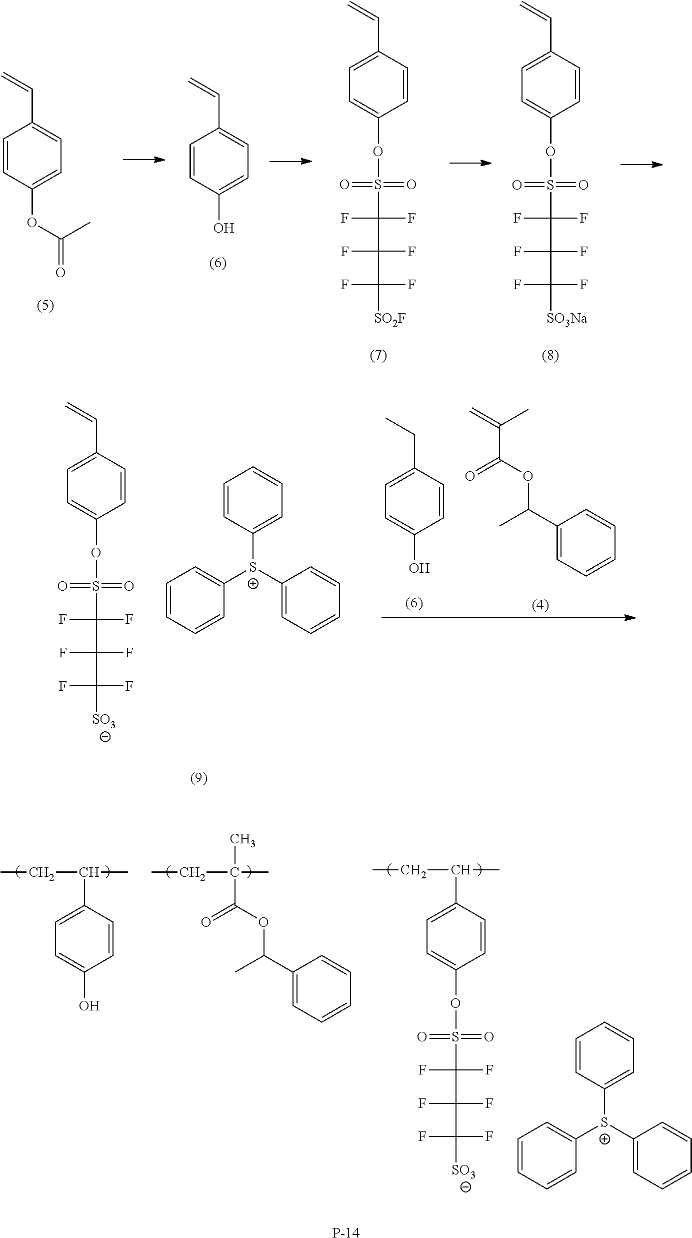

### <Synthesis of Compound (9)>

Compound (5) (100.00 g) was dissolved in 400 g of ethyl acetate. The obtained solution was cooled to 0° C., and 47.60 g of sodium methoxide (a 28 mass % methanol solution) was added dropwise over 30 minutes. This mixture was stirred at room temperature over 5 hours and to the resulting reaction solution, ethyl acetate was added. The organic layer was washed with distilled water three times and dried over anhydrous sodium sulfate, and the solvent was removed by distillation. In this way, 131.70 g of Compound (6) (a 54 mass % ethyl acetate solution) was obtained.

Ethyl acetate (56.00 g) was added to 18.52 g of Compound (6) (a 54% ethyl acetate solution) and thereto, 31.58 g of 1,1,2,2,3,3-hexafluoropropane-1,3-disulfonyl difluoride was added. The system was cooled to 0° C., and a solution obtained by dissolving 12.63 g of triethylamine in 25.00 g of ethyl acetate was added dropwise over 30 minutes. The resulting mixture was stirred over 4 hours while maintaining the liquid temperature at 0° C., and ethyl acetate was added thereto. Thereafter, the organic layer was washed with saturated brine three times and dried over anhydrous sodium sulfate, and the solvent was removed by distillation. In this way, 32.90 g of Compound (7) was obtained.

Compound (7) (35.00 g) was dissolved in 315 g of methanol, and the resulting solution was cooled to 0° C. Subsequently, 245 g of an aqueous 1 N sodium hydroxide solution was added thereto, and the mixture was stirred at room temperature for 2 hours. The solvent was removed by distillation, and ethyl acetate was added to the residue. Thereafter, the organic layer was washed with saturated brine three times and dried over anhydrous sodium sulfate, and the solvent was removed by distillation. In this way, 34.46 g of Compound (8) was obtained.

Compound (8) (28.25 g) was dissolved in 254.25 g of methanol, and 23.34 g of triphenylsulfonium bromide was added thereto. The mixture was stirred at room temperature for 3 hours, and the solvent was removed by distillation. Subsequently, distilled water was added to the residue, and the mixture was extracted with chloroform three times. The obtained organic layer was washed with distilled water three times, and the solvent was removed by distillation. In this way, 42.07 g of Compound (9) was obtained.

### <Synthesis of Resin (P-14)>

p-Hydroxystyrene (6) (a 53.1 mass % propylene glycol monomethyl ether solution) (12.45 g), 6.66 g of Compound (4), 6.77 g of Compound (9) and 1.61 g of polymerization initiator V-601 (produced by Wako Pure Chemical Industries, Ltd.) were dissolved in 32.73 g of propylene glycol monomethyl ether (PGME). Subsequently, 8.18 g of PGME was charged in a reaction vessel and in a nitrogen gas atmosphere, the solution obtained above was added dropwise to the system at 85° C. over 2 hours. The reaction solution was heated with stirring over 4 hours and then allowed to cool to room temperature.

The reaction solution was diluted by adding 33 g of acetone, and the resulting diluted solution was added dropwise in 1,000 g of hexane/ethyl acetate=8/2 (by mass) to precipitate a polymer. After filtration, the solid collected by filtration was spray-washed using 250 g of hexane/ethyl acetate=8/2 (by mass). The obtained solid was dissolved in 33 g of acetone, and the resulting solution was added dropwise in 600 g of methanol/distilled water=1/9 (by mass) to precipitate a polymer. After filtration, the solid collected by filtration was spray-washed using 150 g of methanol/distilled water=1/9 (by mass). Thereafter, the washed solid was dried under reduced pressure to obtain 11.31 g of Resin P-14.

With respect to Resin P-14, the weight average molecular weight (Mw) and the polydispersity (Mw/Mn) were measured using GPC (produced by Tosoh Corp., HLC-8120; Tsk gel Multipore HXL-M). The results obtained are shown in Table 1 below. In this GPC measurement, THF was used as the solvent.

### Synthesis Example 2

### Other Resins

Each of Resins P-1 to P-13 and P-15 to P-55 was synthesized in the same manner as in Synthesis Example 1. Also, these resins were evaluated in the same manner as in Synthesis Example 1. The results obtained are shown in Table 1 below.

In Table 1 below, the weight average molecular weight, compositional ratio (by mol) and polydispersity of each of Resins P-1 to P-55 are shown together.

TABLE 1

| | Weight Average | | | | | | |
|---|---|---|---|---|---|---|---|
| | Molecular Weight | Compositional Ratio | | | | | Polydispersity |
| P-1 | 8000 | 60 | 30 | 10 | — | — | 1.55 |
| P-2 | 14000 | 65 | 25 | 10 | — | — | 1.43 |
| P-3 | 10000 | 60 | 25 | 15 | — | — | 1.50 |
| P-4 | 15000 | 60 | 30 | 10 | — | — | 1.45 |
| P-5 | 13000 | 65 | 30 | 5 | — | — | 1.36 |
| P-6 | 10000 | 55 | 40 | 5 | — | — | 1.54 |
| P-7 | 10000 | 62 | 35 | 3 | — | — | 1.57 |
| P-8 | 10000 | 65 | 25 | 10 | — | — | 1.63 |
| P-9 | 12000 | 60 | 30 | 10 | — | — | 1.48 |
| P-10 | 8000 | 65 | 28 | 7 | — | — | 1.44 |
| P-11 | 10000 | 70 | 20 | 10 | — | — | 1.51 |
| P-12 | 16000 | 75 | 15 | 10 | — | — | 1.50 |
| P-13 | 12000 | 60 | 30 | 10 | — | — | 1.49 |
| P-14 | 11000 | 55 | 35 | 10 | — | — | 1.47 |
| P-15 | 10000 | 80 | 15 | 5 | — | — | 1.52 |
| P-16 | 9000 | 60 | 25 | 15 | — | — | 1.62 |
| P-17 | 7000 | 70 | 23 | 7 | — | — | 1.61 |
| P-18 | 8000 | 60 | 30 | 10 | — | — | 1.64 |
| P-19 | 5000 | 60 | 35 | 5 | — | — | 1.52 |
| P-20 | 13000 | 50 | 20 | 20 | 10 | — | 1.53 |
| P-21 | 8000 | 55 | 15 | 15 | 15 | — | 1.47 |
| P-22 | 9000 | 50 | 35 | 8 | 7 | — | 1.35 |
| P-23 | 10000 | 60 | 20 | 13 | 7 | — | 1.54 |
| P-24 | 8000 | 40 | 20 | 20 | 20 | — | 1.65 |
| P-25 | 7000 | 50 | 20 | 20 | 10 | — | 1.64 |
| P-26 | 17000 | 52 | 20 | 20 | 8 | — | 1.53 |
| P-27 | 10000 | 50 | 20 | 20 | 10 | — | 1.50 |
| P-28 | 9000 | 50 | 30 | 10 | 10 | — | 1.45 |
| P-29 | 6000 | 50 | 10 | 30 | 10 | — | 1.38 |
| P-30 | 5000 | 30 | 15 | 20 | 20 | 15 | 1.63 |
| P-31 | 18000 | 35 | 20 | 30 | 15 | — | 1.56 |
| P-32 | 10000 | 50 | 25 | 20 | 5 | — | 1.52 |
| P-33 | 8000 | 60 | 30 | 10 | — | — | 1.48 |
| P-34 | 9000 | 80 | 15 | 5 | — | — | 1.55 |
| P-35 | 13000 | 75 | 22 | 3 | — | — | 1.57 |
| P-36 | 20000 | 67 | 25 | 8 | — | — | 1.62 |
| P-37 | 15000 | 55 | 30 | 15 | — | — | 1.51 |
| P-38 | 7000 | 60 | 25 | 15 | — | — | 1.42 |
| P-39 | 12000 | 70 | 20 | 10 | — | — | 1.55 |
| P-40 | 8000 | 75 | 20 | 5 | — | — | 1.45 |
| P-41 | 11000 | 70 | 20 | 10 | — | — | 1.54 |
| P-42 | 7000 | 65 | 25 | 10 | — | — | 1.49 |
| P-43 | 13000 | 70 | 20 | 10 | — | — | 1.53 |
| P-44 | 12000 | 70 | 22 | 8 | — | — | 1.44 |
| P-45 | 8000 | 65 | 25 | 10 | — | — | 1.61 |
| P-46 | 10000 | 70 | 20 | 10 | — | — | 1.44 |
| P-47 | 6000 | 65 | 20 | 15 | — | — | 1.48 |
| P-48 | 15000 | 72 | 20 | 8 | — | — | 1.51 |
| P-49 | 12000 | 50 | 30 | 8 | 12 | — | 1.58 |
| P-50 | 15000 | 45 | 30 | 15 | 10 | — | 1.42 |
| P-51 | 8000 | 40 | 35 | 10 | 15 | — | 1.45 |
| P-52 | 18000 | 45 | 42 | 3 | 10 | — | 1.60 |
| P-53 | 6500 | 30 | 50 | 20 | — | — | 1.55 |
| P-54 | 10000 | 55 | 25 | 20 | — | — | 1.44 |
| P-55 | 5000 | 45 | 30 | 5 | 20 | — | 1.49 |

Comparative Compounds C-1 and C-2 shown below were prepared.

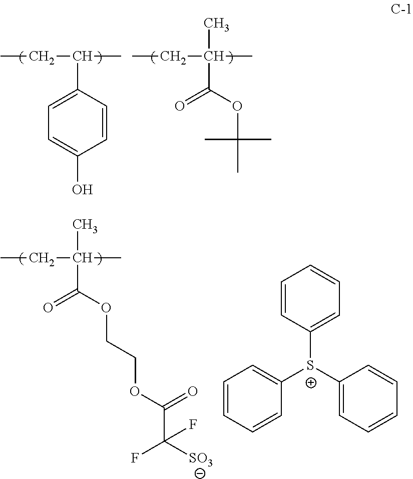

Compositional molar ratio: 45/45/10

Weight average molecular weight: 10,000, Polydispersity: 1.53

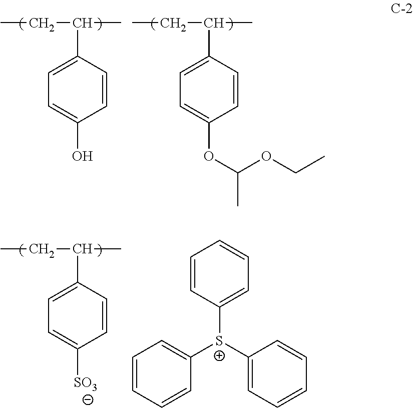

Compositional molar ratio: 50/40/10

Weight average molecular weight: 12,000, Polydispersity: 1.45

### <Photo-Acid Generator>

Any of B-1 to B-120 illustrated above was used as the photo-acid generator.

### <Basic Compound>

Any of N-1 to N-9 shown below was used as the basic compound. Incidentally, N-7 comes under the compound (PA).

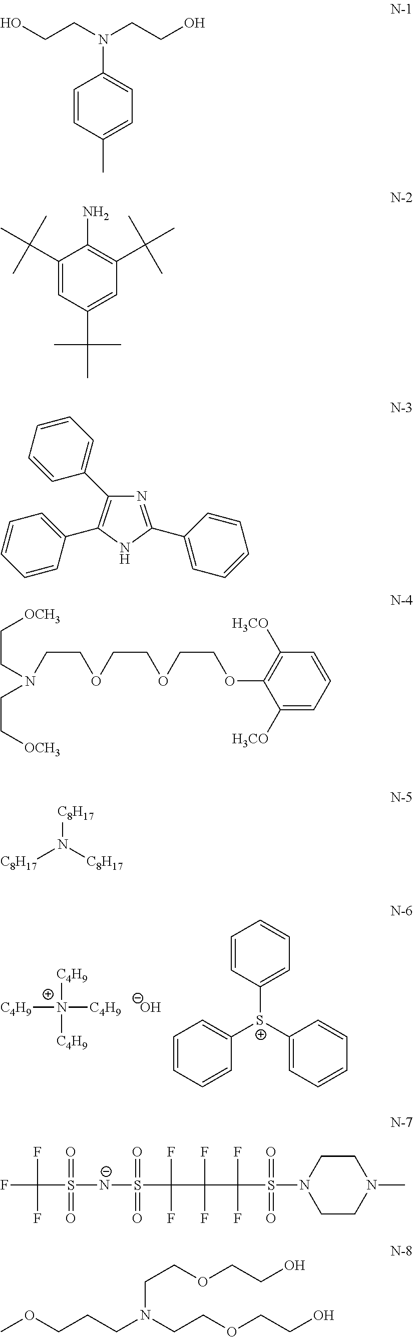

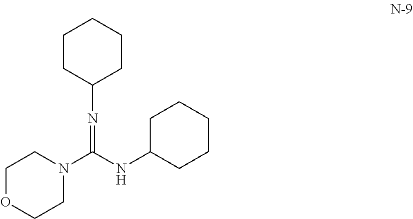

### Synthesis Example 3

### Compound N-7

Compound N-7 was synthesized based on [0354] of JP-A-2006-330098.

### <Surfactant>

Any of W-1 to W-4 shown below was used as the surfactant.

W-1: Megaface R08 (produced by Dainippon Ink & Chemicals, Inc.; fluorine-containing)
W-2: Polysiloxane Polymer KP-341 (produced by Shin-Etsu Chemical Co., Ltd.; silicon-containing)
W-3: Troysol S-366 (produced by Troy Chemical; fluorine-containing)
W-4: PF6320 (produced by OMNOVA; fluorine-containing)

### <Solvent>

Any appropriate mixture of S-1 to S-4 shown below was used as the solvent.

### S-1: PGMEA (b.p.=146° C.)

### S-2: PGME (b.p.=120° C.)

S-3: Methyl lactate (b.p.=145° C.)

### S-4: Cyclohexanone (b.p.=157° C.)

### <Evaluation of Resist (EB)>

The components shown in Tables 2 and 3 below were dissolved in the solvent shown in the same Tables to prepare a solution having a solid content concentration of 3.0 mass %, and this solution was filtered through a polytetrafluoroethylene filter having a pore size of 0.1 μm, whereby positive resist solutions were obtained.

The numerical value of “mass %” shown in Tables 2 and 3 is a value based on the entire solid content excluding the surfactant of the composition. Incidentally, the content of the surfactant is 0.01 mass % based on the entire solid content excluding the surfactant of the composition.

The positive resist solution obtained above was coated on a hexamethyldisilazane-treated silicon substrate by using a spin coater and dried by heating on a hot plate at 110° C. over 90 seconds to obtain a resist film having an average thickness of 100 nm.

### [Sensitivity, Pattern Profile, Roughness Characteristics and Resolution of Isolated Pattern]

This resist film was irradiated with electron beam by using an electron beam irradiation apparatus (HL750, manufactured by Hitachi, Ltd., accelerating voltage: 50 keV). Immediately after the irradiation, the film was baked on a hot plate at 130° C. over 90 seconds, then developed with an aqueous tetramethylammonium hydroxide solution having a concentration of 2.38 mass % at 23° C. for 60 seconds, rinsed with pure water for 30 seconds, and dried. In this way, a line-and-space pattern (line:space=1:1) or an isolated pattern (line:space=1:>100) was formed.

### (Sensitivity)

The cross-sectional profile of the obtained line-and-space pattern was observed using a scanning electron microscope (S-4800, manufactured by Hitachi, Ltd.), and the minimum irradiation energy when resolving a line having a line width of 100 nm was determined. This value was shown as “Sensitivity (μC/cm²)”.

### (Pattern Profile)

The cross-sectional profile of the 100-nm line pattern (line:space=1:1) at the irradiation dose giving the sensitivity above was observed using a scanning electron microscope (S-4800, manufactured by Hitachi, Ltd.), and the profile was evaluated on a 2-stage scale, that is, “rectangular” and “tapered”.

### (Roughness Characteristics: Line Edge Roughness (LER))

The 100-nm line pattern (line:space=1:1) above was observed using a scanning electron microscope (S-9260, manufactured by Hitachi Ltd.), and the distance between the actual edge and the reference line where the edge should be present was measured at 30 points at regular intervals included in the portion of 50 μm in the longitudinal direction of the pattern. The standard deviation of the distance was determined, and 3a was computed. This 36 was shown as “LER (nm)”.

### (Resolution of Isolated Pattern; Resolving Power)

The limiting resolution (the minimum line width when the line and the space were separated and resolved) of the isolated pattern (line:space=1:>100) at the irradiation dose giving the sensitivity above was determined. This value was shown as “Resolution (nm)”.

### [Etching Resistance]

A positive resist film having a thickness of 200 nm was formed on a wafer, and this film was subjected to plasma etching under the condition of 23° C. over 30 seconds by using a mixed gas of C₄F₆ (20 mL/min) and O₂ (40 mL/min). Thereafter, the residual film amount was determined, and the etching rate was computed. The etching resistance was evaluated according to the following criteria.

### (Criteria)

A (Good): The etching rate is less than 15 Å/sec.

B (Insufficient): The etching rate is 15 Å/sec or more.

These evaluation results are shown in Tables 2 and 3 below.

TABLE 2

| | | | | | Evaluation Results | | | | |
|---|---|---|---|---|---|---|---|---|---|
| | Resist Composition | | | | | | | Resolution of | |
| | Resin (P) | Solvent | Basic Compound | Surfactant | Sensitivity | Pattern | LER | Isolated Pattern | Etching |
| | (98 mass %) | (mass ratio) | (2 mass %) | (0.01 mass %) | (μC/cm²) | Profile | (nm) | (nm) | Resistance |
| Example 1 | P-1 | S-1/S-2 (60/40) | N-4 | W-2 | 24 | rectangular | 5.3 | 50.0 | A |
| Example 2 | P-2 | S-1/S-2 (70/30) | N-7 | W-1 | 24 | rectangular | 5.6 | 50.0 | A |
| Example 3 | P-3 | S-4/S-2 (60/40) | N-1 | W-2 | 17 | rectangular | 4.0 | 37.5 | A |
| Example 4 | P-44 | S-1/S-2 (70/30) | N-3/N-5 | W-2 | 29 | rectangular | 5.4 | 50.0 | A |
| | | | (1 mass %/ | | | | | | |
| | | | 1 mass %) | | | | | | |
| Example 5 | P-5 | S-1/S-2 (60/40) | N-2 | W-1 | 34 | rectangular | 5.5 | 50.0 | A |
| Example 6 | P-6 | S-1/S-2 (60/40) | N-5 | None | 34 | rectangular | 5.6 | 50.0 | A |
| Example 7 | P-7 | S-1/S-2 (80/20) | N-1 | W-4 | 38 | rectangular | 4.9 | 50.0 | A |
| Example 8 | P-8 | S-1/S-2 (70/30) | N-3 | W-1 | 24 | rectangular | 5.3 | 50.0 | A |
| Example 9 | P-9 | S-1/S-2 (60/40) | N-3 | W-3 | 24 | rectangular | 5.5 | 50.0 | A |
| Example 10 | P-10 | S-1/S-2 (80/20) | N-4 | W-3 | 30 | rectangular | 5.4 | 50.0 | A |
| Example 11 | P-11 | S-1/S-3 (60/40) | N-5 | W-4 | 24 | rectangular | 5.6 | 50.0 | A |
| Example 12 | P-45 | S-1/S-2 (50/50) | N-3 | W-2 | 24 | rectangular | 5.6 | 50.0 | A |
| Example 13 | P-13 | S-1/S-2 (60/40) | N-2 | W-2 | 24 | rectangular | 5.4 | 50.0 | A |
| Example 14 | P-48 | S-1/S-2 (80/20) | N-4 | W-4 | 29 | rectangular | 5.3 | 50.0 | A |
| Example 15 | P-40 | S-1/S-2 (60/40) | N-1 | W-3 | 35 | rectangular | 5.9 | 62.5 | A |
| Example 16 | P-16 | S-1/S-2 (70/30) | N-6 | W-1 | 20 | rectangular | 5.9 | 62.5 | A |
| Example 17 | P-17/P-47 | S-4/S-2 (70/30) | N-5 | W-2 | 30 | rectangular | 5.6 | 50.0 | A |
| | (49 mass %/ | | | | | | | | |
| | 49 mass %) | | | | | | | | |
| Example 1 8 | P-18 | S-1/S-2 (50/50) | N-6 | W-4 | 23 | rectangular | 4.8 | 50.0 | A |
| Example 19 | P-19 | S-1/S-2 (70/30) | N-6 | W-2 | 35 | rectangular | 5.8 | 62.5 | A |
| Example 20 | P-20 | S-1 (100) | N-5 | W-1 | 24 | rectangular | 5.4 | 50.0 | A |
| Example 21 | P-21 | S-1/S-2 (80/20) | N-1 | W-1 | 19 | Rectangular | 5.3 | 50.0 | A |
| Example 22 | P-22 | S-1/S-2 (60/40) | N-5 | W-3 | 30 | rectangular | 5.3 | 50.0 | A |
| Example 23* | P-23 | S-4/S-2 (80/20) | N-6 | W-1 | 21 | rectangular | 5.8 | 62.5 | A |
| Example 24 | P-24 | S-1/S-2 (80/20) | N-4 | W-1 | 15 | rectangular | 4.1 | 37.5 | A |
| Example 25 | P-25 | S-1/S-3 (80/20) | N-3 | W-1 | 23 | rectangular | 5.0 | 50.0 | A |

Example 23*: resin: 88 mass %, photo-acid generator B-17: 10 mass %, basic compound: 2 mass %, surfactant: 0.01 mass %.

TABLE 3

| | | | | | Evaluation Results | | | | |
|---|---|---|---|---|---|---|---|---|---|
| | Resist Composition | | | | | | | Resolution of | |
| | Resin (P) | Solvent | Basic Compound | Surfactant | Sensitivity | Pattern | LER | Isolated Pattern | Etching |
| | (98 mass %) | (mass ratio) | (2 mass %) | (0.01 mass %) | (μC/cm²) | Profile | (nm) | (nm) | Resistance |
| Example 26 | P-26 | S-4/S-2 (50/50) | N-5 | W-2 | 29 | rectangular | 5.3 | 50.0 | A |
| Example 27 | P-27 | S-1/S-2 (80/20) | N-3 | W-4 | 24 | rectangular | 5.4 | 50.0 | A |
| Example 28 | P-28 | S-1/S-2 (50/50) | N-2 | W-4 | 24 | rectangular | 5.6 | 50.0 | A |
| Example 29 | P-29 | S-1/S-2 (70/30) | N-2 | W-3 | 25 | rectangular | 5.9 | 62.5 | A |
| Example 30 | P-30 | S-2 (100) | N-1 | W-1 | 19 | rectangular | 5.5 | 50.0 | A |
| Example 31 | P-31 | S-1/S-4 (50/50) | N-2 | W-1 | 17 | rectangular | 3.9 | 37.5 | A |
| Example 32 | P-32 | S-4/S-2 (60/40) | N-5 | W-2 | 33 | rectangular | 4.9 | 50.0 | A |
| Example 33 | P-41 | S-1/S-2 (80/20) | N-7 | W-3 | 22 | rectangular | 4.1 | 37.5 | A |
| Example 34 | P-47 | S-3/S-2 (80/20) | N-4 | W-1 | 17 | rectangular | 3.9 | 37.5 | A |
| Example 35 | P-35 | S-3 (100) | N-4 | W-2 | 39 | rectangular | 5.5 | 50.0 | A |
| Example 36 | P-36 | S-4/S-2 (70/30) | N-1 | W-4 | 29 | rectangular | 5.3 | 50.0 | A |
| Example 37 | P-37 | S-3/S-2 (70/30) | N-6 | W-3 | 18 | rectangular | 4.8 | 50.0 | A |
| Example 38 | P-38 | S-4 (100) | N-4 | W-1 | 19 | rectangular | 5.4 | 50.0 | A |
| Example 39 | P-46 | S-1/S-3 (70/30) | N-6 | W-2 | 22 | rectangular | 3.8 | 37.5 | A |
| Example 40 | P-15 | S-1/S-2 (50/50) | N-3 | W-3 | 33 | rectangular | 4.7 | 50.0 | A |
| Example 41 | P-34 | S-1/S-2 (50/50) | N-3 | W-3 | 32 | rectangular | 4.0 | 37.5 | A |
| Example 42 | P-33 | S-1/S-2 (60/40) | N-5 | W-4 | 25 | rectangular | 5.9 | 62.5 | A |
| Example 43 | P-42 | S-1/S-2 (60/40) | N-5 | W-4 | 24 | rectangular | 5.5 | 50.0 | A |
| Example 44 | P-14 | S-1/S-2 (70/30) | N-6 | W-3 | 24 | rectangular | 5.6 | 50.0 | A |
| Example 45 | P-43 | S-1/S-2 (70/30) | N-6 | W-3 | 23 | rectangular | 4.9 | 50.0 | A |
| Example 46 | P-39 | S-1/S-2 (70/30) | N-6 | W-3 | 23 | rectangular | 5.0 | 50.0 | A |
| Example 47 | P-4 | S-1/S-2 (70/30) | N-6 | W-3 | 22 | rectangular | 4.1 | 37.5 | A |
| Example 48 | P-12 | S-1/S-2 (70/30) | N-6 | W-3 | 21 | rectangular | 3.6 | 37.5 | A |
| Example 49 | P-49 | S-4/S-2 (60/40) | N-8 | W-1 | 22 | rectangular | 4.8 | 50.0 | A |
| Example 50 | P-50 | S-1/S-2 (80/20) | N-9 | W-1 | 24 | rectangular | 5.3 | 50.0 | A |
| Example 51 | P-51 | S-1/S-2 (60/40) | N-9 | W-4 | 19 | rectangular | 5.4 | 50.0 | A |
| Example 52 | P-52 | S-1/S-3 (90/10) | N-3 | W-2 | 24 | rectangular | 5.6 | 50.0 | A |
| Example 53 | P-53 | S-1 (100) | N-7 | W-3 | 15 | rectangular | 5.8 | 62.5 | A |
| Example 54 | P-54 | S-1/S-2 (50/50) | N-3 | W-4 | 15 | rectangular | 5.0 | 50.0 | A |
| Example 55 | P-55 | S-1/S-2 (80/20) | N-4 | W-3 | 15 | rectangular | 5.5 | 50.0 | A |
| Comparative | C-1 | S-1/S-2 (60/40) | N-3 | W-3 | 53 | Taper | 8.5 | 100.0 | B |
| Example 1 | | | | | | | | | |
| Comparative | C-2 | S-1/S-2 (80/20) | N-3 | W-4 | 55 | taper | 8.2 | 100.0 | B |
| Example 2 | | | | | | | | | |

As seen in Tables 2 and 3, the compositions of Examples were excellent in all of sensitivity, pattern profile, LER, resolution of isolated pattern and etching resistance compared with the compositions of Comparative Examples.

### <Evaluation of Resist (EUV)>

The components shown in Table 4 below were dissolved in the solvent shown in the same Table to prepare a solution having a solid content concentration of 3.0 mass %, and this solution was filtered through a polytetrafluoroethylene filter having a pore size of 0.1 μm, whereby positive resist solutions were obtained.

The numerical value of “mass %” shown in Table 4 is a value based on the entire solid content excluding the surfactant of the composition. Incidentally, the content of the surfactant is 0.01 mass % based on the entire solid content excluding the surfactant of the composition.

The positive resist solution obtained above was coated on a hexamethyldisilazane-treated silicon substrate by using a spin coater and dried by heating on a hot plate at 120° C. over 90 seconds to obtain a resist film having an average thickness of 100 nm.

### [Sensitivity, Pattern Profile and Roughness Characteristics]

This resist film was irradiated with EUV light by using an EUV exposure apparatus. Immediately after the irradiation, the film was heated on a hot plate at 130° C. over 90 seconds, then developed with an aqueous tetramethylammonium hydroxide solution having a concentration of 2.38 mass % at 23° C. for 60 seconds, rinsed with pure water for 30 seconds, and dried. In this way, a line-and-space pattern (line:space=1:1) was formed.

### (Sensitivity)

The cross-sectional profile of the obtained line-and-space pattern was observed using a scanning electron microscope (S-4800, manufactured by Hitachi, Ltd.), and the minimum irradiation energy when resolving a line having a line width of 100 nm was determined. This value was shown as “Sensitivity (mJ/cm²)”.

### (Pattern Profile)

The cross-sectional profile of the 100-nm line pattern (line:space=1:1) at the irradiation dose giving the sensitivity above was observed using a scanning electron microscope (S-4800, manufactured by Hitachi, Ltd.), and the profile was evaluated on a 2-stage scale, that is, “rectangular” and “tapered”.

### (Roughness Characteristics: LER)

The 100-nm line pattern (line:space=1:1) above was observed using a scanning electron microscope (S-9260, manufactured by Hitachi Ltd.), and the distance between the actual edge and the reference line where the edge should be present was measured at 30 points at regular intervals included in the portion of 50 μm in the longitudinal direction of the pattern. The standard deviation of the distance was determined, and 3a was computed. This 3σ was shown as “LER (nm)”.

These evaluation results are shown in Table 4 below.

TABLE 4

| | Resist Composition | | | | | | |
|---|---|---|---|---|---|---|---|
| | Resin | | Basic | | Evaluation Results | | |
| | (98 | Solvent | Compound | Surfactant | Sensitivity | Pattern | LER |
| | mass %) | (mass ratio) | (2 mass %) | (0.01 mass %) | (mJ/cm²) | Profile | (nm) |
| Example 56 | P-9 | S-1/S-2 | N-3 | W-3 | 25 | rectangular | 4.8 |
| | | (60/40) | | | | | |
| Example 57 | P-27 | S-1/S-2 | N-3 | W-4 | 24 | rectangular | 5.0 |
| | | (80/20) | | | | | |
| Example 58 | P-30 | S-2 | N-1 | W-1 | 20 | rectangular | 4.8 |
| | | (100) | | | | | |
| Example 59 | P-14 | S-1/S-2 | N-6 | W-3 | 23 | rectangular | 5.1 |
| | | (70/30) | | | | | |
| Example 60 | P-47 | S-3/S-2 | N-4 | W-1 | 21 | rectangular | 4.4 |
| | | (80/20) | | | | | |
| Example 61 | P-51 | S-1/S-2 | N-9 | W-4 | 21 | rectangular | 4.9 |
| | | (60/40) | | | | | |
| Example 62 | P-52 | S-1/S-3 | N-3 | W-2 | 24 | rectangular | 4.8 |
| | | (90/10) | | | | | |
| Comparative | C-1 | S-1/S-2 | N-3 | W-3 | 39 | taper | 8.0 |
| Example 3 | | (60/40) | | | | | |
| Comparative | C-2 | S-1/S-2 | N-3 | W-4 | 35 | taper | 8.4 |
| Example 4 | | (80/20) | | | | | |

As seen in Table 4, the compositions of Examples were excellent in all of sensitivity, pattern profile and LER compared with the compositions of Comparative Examples.

The entire disclosure of each and every foreign patent application from which the benefit of foreign priority has been claimed in the present application is incorporated herein by reference, as if fully set forth.

What is claimed is:

1. An actinic ray-sensitive or radiation-sensitive resin composition containing a resin having (A) a repeating unit represented by the following formula (I) and (B) a repeating unit capable of generating an acid upon irradiation with an actinic ray or radiation: 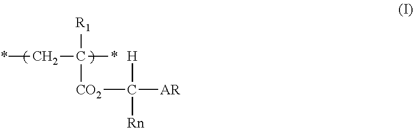
wherein AR represents an aryl group, Rn represents an alkyl group, a cycloalkyl group or an aryl group, Rn and AR may combine with each other to form a non-aromatic ring, and
R₁ represents a hydrogen atom, an alkyl group, a cycloalkyl group, a halogen atom, a cyano group or an alkyloxycarbonyl group.

2. The actinic ray-sensitive or radiation-sensitive resin composition as claimed in claim 1, wherein in formula (I), Rn and AR are combined with each other to form a non-aromatic ring.

3. The actinic ray-sensitive or radiation-sensitive resin composition as claimed in claim 1, wherein the repeating unit (A) represented by formula (I) contains two or more aromatic rings.

4. The actinic ray-sensitive or radiation-sensitive resin composition as claimed in claim 1, wherein AR in formula (I) contains two or more aromatic rings.

5. The actinic ray-sensitive or radiation-sensitive resin composition as claimed in claim 1, wherein the repeating unit (B) is at least one selected from the group consisting of repeating units represented by the following formulae (B1), (B2) and (B3): 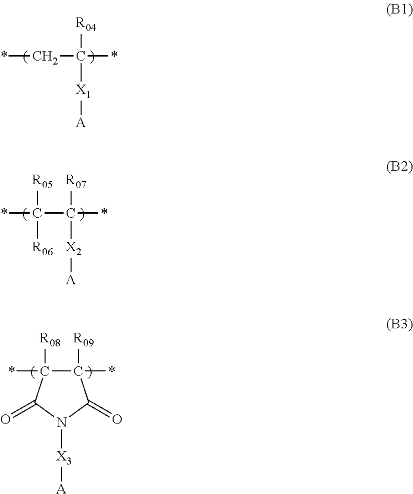
wherein A represents a structural moiety capable of decomposing upon irradiation with an actinic ray or radiation to generate an acid anion,
each of R₀₄, R₀₅ and R₀₇ to R₀₉ independently represents a hydrogen atom, an alkyl group, a cycloalkyl group, a cyano group or an alkoxycarbonyl group,
R₀₆ represents a cyano group, a carboxy group, —CO—OR₂₅ or —CO—N(R₂₆)(R₂₇), R₂₅ represents an alkyl group, a cycloalkyl group, an alkenyl group, a cycloalkenyl group, an aryl group or an aralkyl group, R₂₆ and R₂₇ may combine with each other to form a ring together with the nitrogen atom, each of R₂₆ and R₂₇ independently represents a hydrogen atom, an alkyl group, a cycloalkyl group, an alkenyl group, a cycloalkenyl group, an aryl group or an aralkyl group,
each of X₁ to X₃ independently represents a single bond, an arylene group, an alkylene group, a cycloalkylene group, —O—, —SO₂—, —CO—, —N(R₃₃)— or a divalent linking group formed by combining a plurality of these members, and R₃₃ represents a hydrogen atom, an alkyl group, a cycloalkyl group, an alkenyl group, a cycloakenyl group, an aryl group or an aralkyl group.

6. The actinic ray-sensitive or radiation-sensitive resin composition as claimed in claim 5, wherein the A is an ionic structural moiety having a sulfonium salt structure or an iodonium salt structure.

7. The actinic ray-sensitive or radiation-sensitive resin composition as claimed in claim 1, wherein the resin further contains at least either one of a repeating unit represented by the following formula (A1) and a repeating unit represented by formula (A2): 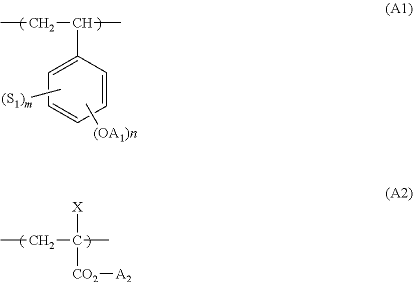
wherein in formula (A1),
m represents an integer of 0 to 4,
n represents an integer of 1 to 5 satisfying the relationship of m+n≦5,
S₁ represents a substituent (excluding hydrogen atom) and when m≧2, each S₁ may be the same as or different from every other S₁, and
A₁ represents a hydrogen atom or a group capable of leaving by the action of an acid and when n≧2, each A₁ may be the same as or different from every other A₁; and
in formula (A2),
X represents a hydrogen atom, an alkyl group, a hydroxyl group, an alkoxy group, a halogen atom, a cyano group, a nitro group, an acyl group, an acyloxy group, a cycloalkyl group, a cycloalkyloxy group, an aryl group, a carboxy group, an alkyloxycarbonyl group, an alkylcarbonyloxy group or an aralkyl group, and
A₂ represents a group capable of leaving by the action of an acid.

8. The actinic ray-sensitive or radiation-sensitive resin composition as claimed in claim 1, which is for a KrF excimer laser, an electron beam, an X-ray or EUV light.

9. A resist film formed using the actinic ray-sensitive or radiation-sensitive resin composition claimed in claim 1.

10. A pattern forming method comprising exposing and developing the resist film claimed in claim 9.
